(19) United States
(12) Patent Application Publication
(10) Pub. No.: US 2023/0098353 A1
(43) Pub. Date: Mar. 30, 2023

(54) ORGANIC ELECTROLUMINESCENT DEVICE AND DISPLAY APPARATUS

(71) Applicant: Kunshan New Flat Panel Display Technology Center Co., Ltd., Kunshan (CN)

(72) Inventors: Guomeng LI, Kunshan (CN); Zhaoyang XI, Kunshan (CN); Xiaoyu GAO, Kunshan (CN); Mengzhen LI, Kunshan (CN); Lei SUN, Kunshan (CN); Chao XU, Kunshan (CN)

(73) Assignee: Kunshan New Flat Panel Display Technology Center Co., Ltd., Kunshan (CN)

(21) Appl. No.: 17/965,144

(22) Filed: Oct. 13, 2022

Related U.S. Application Data
(63) Continuation of application No. PCT/CN2021/101705, filed on Jun. 23, 2021.

(30) Foreign Application Priority Data
Aug. 14, 2020 (CN) 202010819644.9

(51) Int. Cl. H01L 51/50; H01L 51/00

(52) U.S. Cl. CPC H01L 51/5004; H01L 51/5028; H01L 51/008; H01L 51/0067; H01L 51/0072; H01L 51/0064; H01L 51/0071; H01L 51/0073; H01L 51/005; H01L 51/0094; H01L 51/0074; H01L 2251/552

(57) ABSTRACT

An organic electroluminescent device and a display apparatus. The organic electroluminescent device includes a first electrode, a second electrode and an organic layer located between the first electrode and the second electrode. The organic layer includes a light-emitting layer. The light-emitting layer contains a host material, a thermally activated delayed fluorescence sensitizer and a fluorescent dye. The energy level relationship between the host material and the thermally activated delayed fluorescence sensitizer is LUMOₕₒₛₜ≥LUMO_{sensitizer}, while HOMO_{sensitizer}≥HOMOₕₒₛₜ.

### CROSS-REFERENCE TO RELATED APPLICATION

This is a continuation of International Patent Application No. PCT/CN2021/101705, filed on Jun. 23, 2021, which claims priority to a Chinese patent application No. 202010819644.9 filed on Aug. 14, 2020, disclosure of which is incorporated herein by reference in its entirety.

### TECHNICAL FIELD

The present disclosure relates to the field of organic electroluminescent technologies and, in particular, to an organic electroluminescent device and a display apparatus.

### BACKGROUND

Thermally activated sensitized fluorescence (TASF) means that when a thermally activated delayed fluorescence (TADF) material is used as a sensitizer, the energy of a host material is transferred to the TADF material, and then the triplet energy of the host material is returned to the singlet state through a reverse intersystem crossing (RISC) process, thereby transferring the energy to a doped fluorescent dye to emit light. In this manner, a complete energy transfer from the host to dye molecules can be achieved so that traditional fluorescent doped dyes can exceed an internal quantum efficiency limit of 25%.

However, in a TASF luminescent device, there is often a serious problem of dye carrier trapping, and the device has a high operating voltage and a low service life.

### SUMMARY

The present disclosure provides an organic electroluminescent device to reduce the operating voltage of the device, to prolong the service life of the device, and to improve the problem of efficiency roll-off of the device. The present disclosure also provides a display apparatus including the organic electroluminescent device.

In a first aspect, an embodiment of the present disclosure provides an organic electroluminescent device. The organic electroluminescent device includes a first electrode, a second electrode and an organic layer located between the first electrode and the second electrode.

The organic layer includes a light-emitting layer. The light-emitting layer contains a host material, a thermally activated delayed fluorescence sensitizer and a fluorescent dye.

The energy level relationship between the host material and the thermally activated delayed fluorescence sensitizer is LUMOₕₒₛₜ≥LUMO_{sensitizer}>HOMO_{sensitizer}≥HOMOₕₒₛₜ.

In an embodiment, the energy level relationship between the host material and the thermally activated delayed fluorescence sensitizer is LUMOₕₒₛₜ>LUMO_{sensitizer}>HOMO_{sensitizer}>HOMOₕₒₛₜ.

In an embodiment, 1 eV >|LUMOₕₒₛₜ−LUMO_{sensitizer}|>0.1 eV.

In an embodiment, 1 eV >|HOMO_{sensitizer}−HOMOₕₒₛₜ|>0.1 eV.

In an embodiment, the energy level relationship between the thermally activated delayed fluorescence sensitizer and the fluorescent dye is LUMO_{dye}>LUMO_{sensitizer}>HOMO_{dye}>HOMO_{sensitizer}, or LUMO_{sensitizer}>LUMO_{dye}>HOMO_{sensitizer}>HOMO_{dye}.

In an embodiment, the energy level relationship between the thermally activated delayed fluorescence sensitizer and the fluorescent dye is LUMO_{dye}>LUMO_{sensitizer}>HOMO_{dye}>HOMO_{sensitizer}, and 1 eV >|LUMO_{sensitizer}−LUMO_{dye}|>0.1 eV.

In an embodiment, the energy level relationship between the thermally activated delayed fluorescence sensitizer and the fluorescent dye is LUMO_{sensitizer}>LUMO_{dye}>HOMO_{sensitizer}>HOMO_{dye}, and 1 eV >|HOMO_{dye}−HOMO_{sensitizer}|>0.1 eV.

In an embodiment, the energy level relationship between the host material and the fluorescent dye is LUMO_{dye} >LUMOₕₒₛₜ >HOMO_{dye} >HOMOₕₒₛₜ, or LUMOₕₒₛₜ >LUMO_{dye} >HOMOₕₒₛₜ >HOMO_{dye}.

In an embodiment, the energy level relationship between the host material and the fluorescent dye is LUMO_{dye}>LUMOₕₒₛₜ>HOMO_{dye} >HOMOₕₒₛₜ, and 1 eV >|LUMOₕₒₛₜ−LUMO_{dye}|>0.1 eV.

Alternatively, the energy level relationship between the host material and the fluorescent dye is LUMOₕₒₛₜ>LUMO_{dye}>HOMOₕₒₛₜ>HOMO_{dye}, and 1 eV >|HOMO_{dye}−HOMOₕₒₛₜ|>0.1 eV.

In an embodiment, the fluorescent dye is selected from any one of compounds F-1 to F-30.

In an embodiment, the thermally activated delayed fluorescence sensitizer is selected from any one or a combination of at least two of compounds TDE1 to TDE45.

In an embodiment, the host material is selected from any one or a combination of at least two of compounds TDH-1 to TDH-30.

In a second aspect, an embodiment of the present disclosure provides a display apparatus. The display apparatus includes the organic electroluminescent device in the first aspect.

An embodiment of the present disclosure provides an organic electroluminescent device. In the organic electroluminescent device, the energy level relationship between the host material and the sensitizer is optimized so that the range of Lowest Occupied Molecular Orbital (LUMO) energy level to Highest Occupied Molecular Orbital (HOMO) energy level of the host material completely covers the range of LUMO energy level to HOMO energy level of the sensitizer. The energy is transferred from the host material to the sensitizer through such energy level matching. With the technical solution in the embodiments of the present disclosure, the operating voltage of the device can be effectively reduced, and the service life of the device can be improved.

### BRIEF DESCRIPTION OF DRAWINGS

FIG. 1 is a diagram illustrating an energy level relationship between a host material, a sensitizer and a dye according to an embodiment of the present disclosure.

FIG. 2 is a diagram illustrating an energy level relationship between a host material, a sensitizer and a dye according to an embodiment of the present disclosure.

FIG. 3 is a diagram illustrating an energy level relationship between a host material, a sensitizer and a dye according to embodiment two of the present disclosure.

FIG. 4 is a diagram illustrating an energy level relationship between a host material, a sensitizer and a dye according to comparative embodiment one.

FIG. 5 is a diagram illustrating the structure of an organic electroluminescent device according to embodiment one of the present disclosure.

FIG. 6 is a luminance-voltage graph according to embodiment one, embodiment two and comparative embodiment one of the present disclosure.

### DETAILED DESCRIPTION

For a better understanding of the present disclosure, embodiments of the present disclosure are listed below. It is to be understood by those skilled in the art that the embodiments described herein are used for a better understanding of the present disclosure and are not to be construed as limitations to the present disclosure.

Currently, in a TASF luminescent device, there is often a serious problem of dye carrier trapping, resulting in a higher voltage, a serious efficiency roll-off and a low service life of the device. Research by the applicant has found that one of the main reasons for this phenomenon is the mismatch of energy levels in the light-emitting layer of the device, and there are problems in the energy transfer modes of a host material, a sensitizer and a dye.

In view of the above, an embodiment of the present disclosure provides an organic electroluminescent device. The organic electroluminescent device includes a first electrode, a second electrode and an organic layer located between the first electrode and the second electrode.

The organic layer includes a light-emitting layer (EML). The light-emitting layer contains a host material, a thermally activated delayed fluorescence sensitizer and a fluorescent dye.

The energy level relationship between the host material and the thermally activated delayed fluorescence sensitizer is LUMOₕₒₛₜ≥LUMO_{sensitizer}>HOMO_{sensitizer}≥HOMOₕₒₛₜ.

In embodiments of the present disclosure, LUMOₕₒₛₜ denotes the LUMO energy level of a host material, and HOMO_{sensitizer} denotes the HOMO energy level of a sensitizer. The LUMO energy level refers to the energy level of the lowest unoccupied molecular orbital, and the HOMO energy level refers to the energy level of the highest occupied molecular orbital. The same representation manner has the same meaning, and will not be described again.

An embodiment of the present disclosure provides an organic electroluminescent device. In the organic electroluminescent device, the energy level relationship between the host material and the sensitizer is optimized so that the range of LUMO energy level to HOMO energy level of the host material completely covers the range of LUMO energy level to HOMO energy level of the sensitizer. The energy is completely transferred from the host material to the sensitizer through such energy level matching. With the technical solution in the embodiment of the present disclosure, the operating voltage of the device can be effectively reduced, and the service life of the device can be improved.

In an alternative embodiment, the energy level relationship between the host material and the thermally activated delayed fluorescence sensitizer is LUMOₕₒₛₜ>LUMO_{sensitizer}>HOMO_{sensitizer}>HOMOₕₒₛₜ.

Further, in an alternative embodiment, 1 eV >|LUMOₕₒₛₜ−LUMO_{sensitizer}|>0.1 eV. In an embodiment, the absolute value of the LUMO energy level difference between the host material and the sensitizer is 0.2 eV, 0.3 eV, 0.4 eV, 0.5 eV, 0.6 eV, 0.7 eV, 0.8 eV, 0.9 eV, etcetera.

In an embodiment of the present disclosure, the absolute value of the LUMO energy level difference between the host material and the sensitizer is within the preceding range. When the absolute value of the energy level difference is greater than 0.1 eV, the energy of the host material can be better transferred to the sensitizer. When the absolute value of the energy level difference is greater than 1 eV, the energy transfer loss is serious. Therefore, the absolute value of the energy level difference is preferably less than 1 eV.

In an alternative embodiment, 1 eV >|HOMO_{sensitizer}−HOMOₕₒₛₜ>|0.1 eV. In an embodiment, the absolute value of the HOMO energy level difference between the host material and the sensitizer is 0.2 eV, 0.3 eV, 0.4 eV, 0.5 eV, 0.6 eV, 0.7 eV, 0.8 eV, 0.9 eV, and etcetera.

In an embodiment of the present disclosure, the absolute value of the HOMO energy level difference between the host material and the sensitizer is within the preceding range. When the absolute value of the energy level difference is greater than 0.1 eV, the energy of the host material can be better transferred to the sensitizer. When the absolute value of the energy level difference is greater than 1 eV, the energy transfer loss is serious. Therefore, the absolute value of the energy level difference is preferably less than 1 eV.

In an alternative embodiment, the energy level relationship between the thermally activated delayed fluorescence sensitizer and the fluorescent dye is LUMO_{dye}>LUMO_{sensitizer}>HOMO_{dye}>HOMO_{sensitizer}, or LUMO_{sensitizer}>LUMO_{dye}>HOMO_{sensitizer}>HOMO_{dye}.

In an embodiment of the present disclosure, the dye and the sensitizer are further optimized to have the preceding energy level relationship so that the energy level of the dye is not covered by the energy levels of the host material and the sensitizer at the same time. Thus, the problems of the charge carrier trapping of the device and recombination of excitons on the dye, which result in an increase in the operating voltage and a decrease in the service life of the device, are avoided, thereby improving the performance of the device.

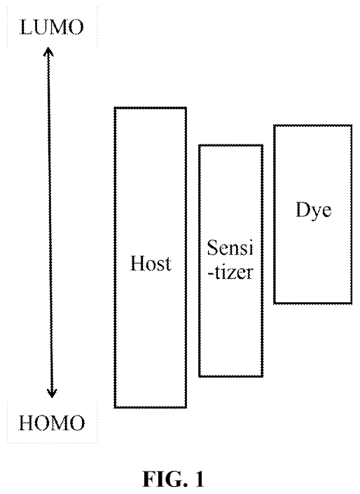

In an alternative embodiment, the relationship between the LUMO energy levels and the HOMO energy levels of the host material, the sensitizer and the dye is shown in FIG. 1. The range from the LUMO energy level to the HOMO energy level of the host material covers the range from the LUMO energy level to the HOMO energy level of the sensitizer. Moreover, the range from the LUMO energy level to the HOMO energy level of the dye is not covered by the range from the LUMO energy level to the HOMO energy level of the sensitizer, and the two ranges are staggered, that is, LUMO_{dye} >LUMO_{sensitizer}>HOMO_{dye}>HOMO_{sensitizer}. In this manner, the energy can be completely transferred from the host material to the sensitizer, and the problems of charge carrier trapping in the device and recombination of excitons on the dye are avoided, thereby effectively reducing the operating voltage of the device and improving the service life of the device. The length of rectangles in the FIG. 1 does not represent the specific energy level, but only represents the magnitude relationship between the energy levels of different materials.

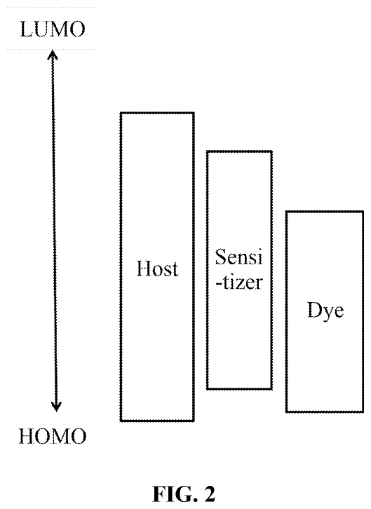

In an alternative embodiment, the relationship between the LUMO energy levels and the HOMO energy levels of the host material, the sensitizer and the dye is shown in FIG. 2. The range from the LUMO energy level to the HOMO energy level of the host material covers the range from the LUMO energy level to the HOMO energy level of the sensitizer. Moreover, the range from the LUMO energy level to the HOMO energy level of the dye is not covered by the range from the LUMO energy level to the HOMO energy level of the sensitizer, that is, LUMO_{sensitizer}>LUMO_{dye}>HOMO_{sensitizer}>HOMO_{dye}. In this manner, the energy can be completely transferred from the host material to the sensitizer, and the problems of charge carrier trapping in the device and recombination of excitons on the dye are avoided, thereby effectively reducing the operating voltage of the device and improving the service life of the device.

In an alternative embodiment, the energy level relationship between the thermally activated delayed fluorescence sensitizer and the fluorescent dye is LUMO_{dye}>LUMO_{sensitizer}>HOMO_{dye}>HOMO_{sensitizer}, and 1 eV >|LUMO_{sensitizer}−LUMO_{dye}|>0.1 eV. In an embodiment, the absolute value of the LUMO energy level difference between the fluorescent dye and the sensitizer is 0.2 eV, 0.3 eV, 0.4 eV, 0.5 eV, 0.6 eV, 0.7 eV, 0.8 eV, 0.9 eV, etcetera.

In another alternative embodiment, the energy level relationship between the thermally activated delayed fluorescence sensitizer and the fluorescent dye is LUMO_{sensitizer}>LUMO_{dye}>HOMO_{sensitizer}>HOMO_{dye}, and 1 eV >|HOMO_{dye}−HOMO_{sensitizer}>0.1 eV. In an embodiment, the absolute value of the HOMO energy level difference between the fluorescent dye and the sensitizer is 0.2 eV, 0.3 eV, 0.4 eV, 0.5 eV, 0.6 eV, 0.7 eV, 0.8 eV, 0.9 eV, etcetera.

In an embodiment of the present disclosure, the absolute value of the LUMO energy level difference or the absolute value of the HOMO energy level difference between the fluorescent dye and the sensitizer is within the preceding range. In this range, the problem of charge carrier trapping can be further improved, thereby improving the performance of the device.

In an alternative embodiment, the energy level relationship between the host material and the fluorescent dye is LUMO_{dye} >LUMOₕₒₛₜ>HOMO_{dye}>HOMOₕₒₛₜ, or LUMOₕₒₛₜ>LUMO_{dye}>HOMOₕₒₛₜ>HOMO_{dye}.

In an embodiment of the present disclosure, the dye and the host material are further optimized to have the preceding energy level relationship so that the range from the LUMO energy level to the HOMO energy level of the dye can be neither covered by the range from the LUMO energy level to the HOMO energy level of the sensitizer nor covered by the range from the LUMO energy level to the HOMO energy level of the host material. The problems of the charge carrier trapping of the device and recombination of excitons on the dye, which result in an increase in the operating voltage and a decrease in the service life of the device, are avoided, thereby improving the performance of the device.

In an alternative embodiment, the energy level relationship between the host material and the fluorescent dye is LUMO_{dye}>LUMOₕₒₛₜ>HOMO_{dye}>HOMOₕₒₛₜ, and 1 eV >|LUMOₕₒₛₜ−LUMO_{dye}|>0.1 eV. In an embodiment, the absolute value of the LUMO energy level difference between the fluorescent dye and the host material is 0.2 eV, 0.3 eV, 0.4 eV, 0.5 eV, 0.6 eV, 0.7 eV, 0.8 eV, 0.9 eV, etcetera.

In another alternative embodiment, the energy level relationship between the host material and the fluorescent dye is LUMOₕₒₛₜ>LUMO_{dye}>HOMOₕₒₛₜ>HOMO_{dye}, and 1 eV >|HOMO_{dye}−HOMOₕₒₛₜ|>0.1 eV. In an embodiment, the absolute value of the HOMO energy level difference between the fluorescent dye and the host material is 0.2 eV, 0.3 eV, 0.4 eV, 0.5 eV, 0.6 eV, 0.7 eV, 0.8 eV, 0.9 eV, etcetera.

In an embodiment of the present disclosure, the absolute value of the LUMO energy level difference or the absolute value of the HOMO energy level difference between the fluorescent dye and the host material is within the preceding range. In this range, the problem of charge carrier trapping can be further improved, thereby improving the performance of the device.

In an alternative embodiment, the energy level relationship between the host material, the thermally activated delayed fluorescence sensitizer and the fluorescent dye is LUMOₕₒₛₜ>LUMO_{sensitizer}>HOMO_{sensitizer}>HOMOₕₒₛₜ, LUMO_{dye}>LUMO_{sensitizer}>HOMO_{dye}>HOMO_{sensitizer}, and LUMO_{dye}>LUMOₕₒₛₜ>HOMO_{dye}>HOMOₕₒₛₜ.

In an alternative embodiment, the energy level relationship between the host material, the thermally activated delayed fluorescence sensitizer and the fluorescent dye is LUMOₕₒₛₜ>LUMO_{sensitizer}>HOMO_{sensitizer}>HOMOₕₒₛₜ, LUMO_{sensitizer}>LUMO_{dye}>HOMO_{sensitizer}>HOMO_{dye}, and LUMOₕₒₛₜ>LUMO_{dye}>HOMOₕₒₛₜ>HOMO_{dye}.

In an alternative embodiment, the fluorescent dye is selected from any of compounds F-1 to F-30:

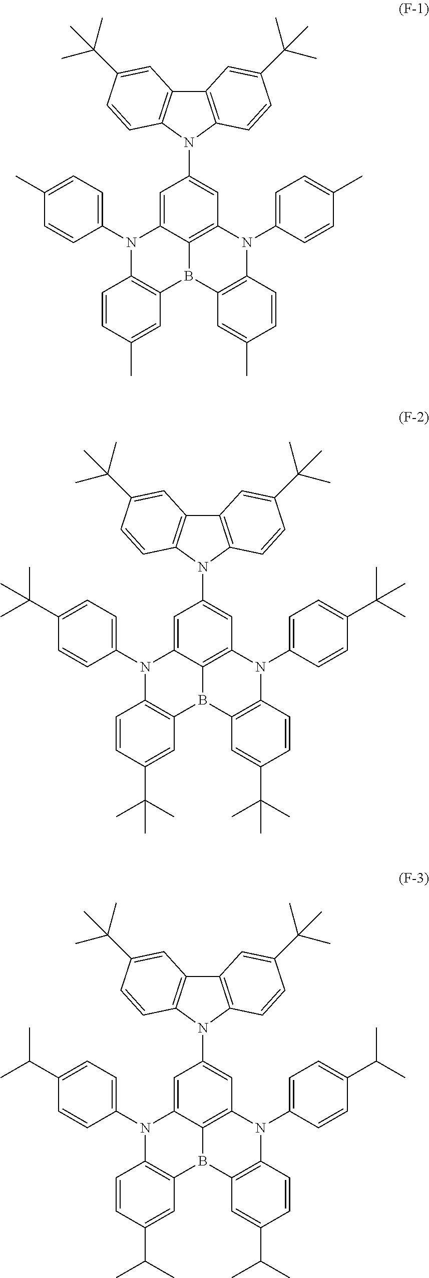

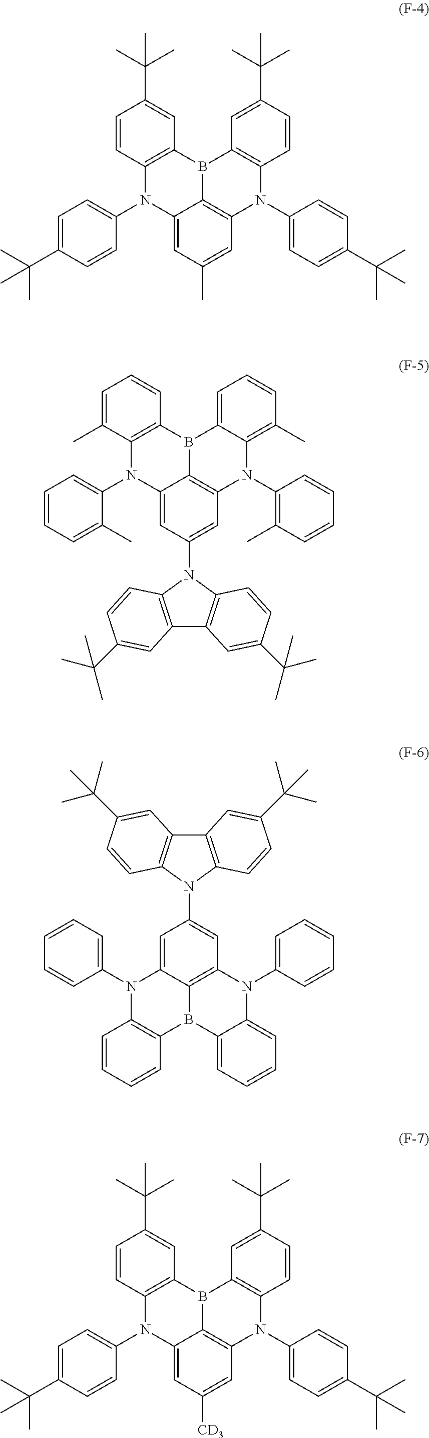

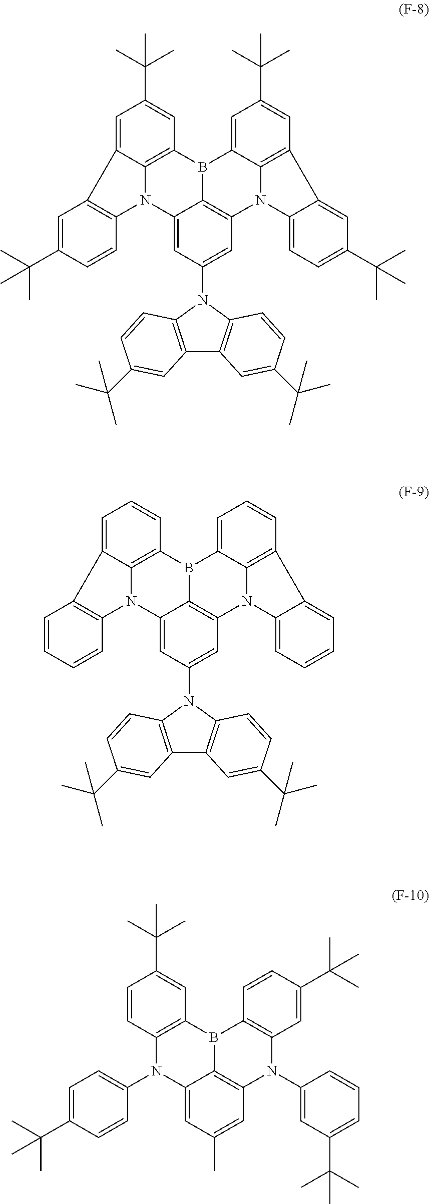

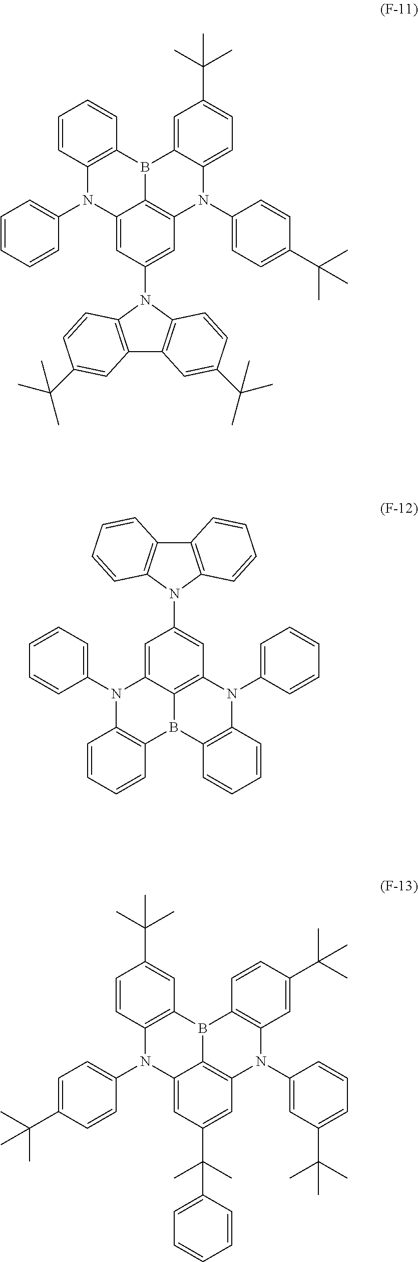

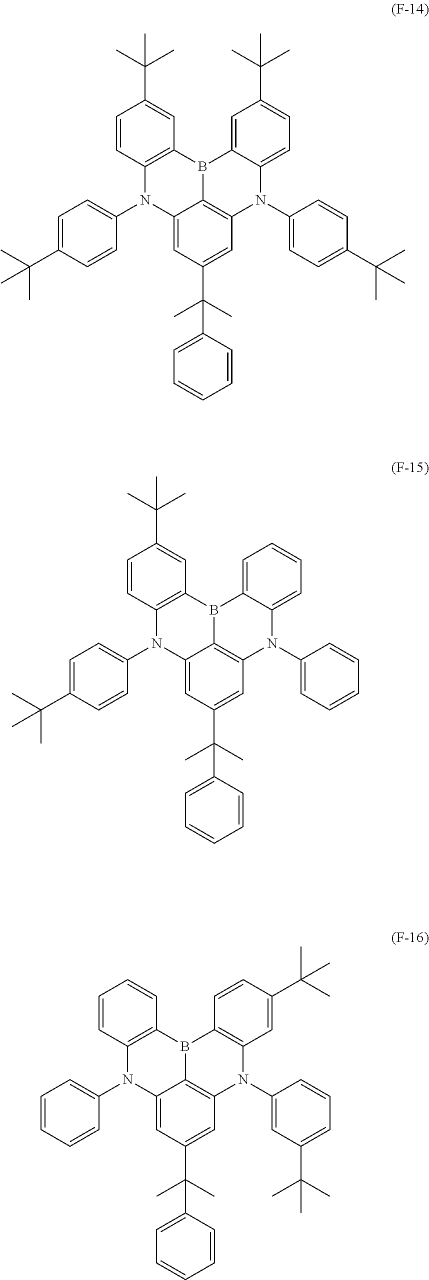

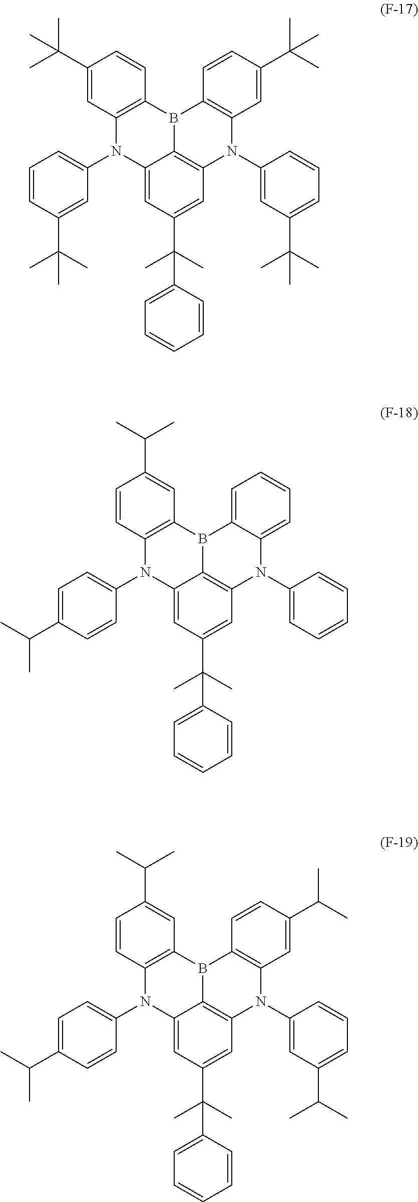

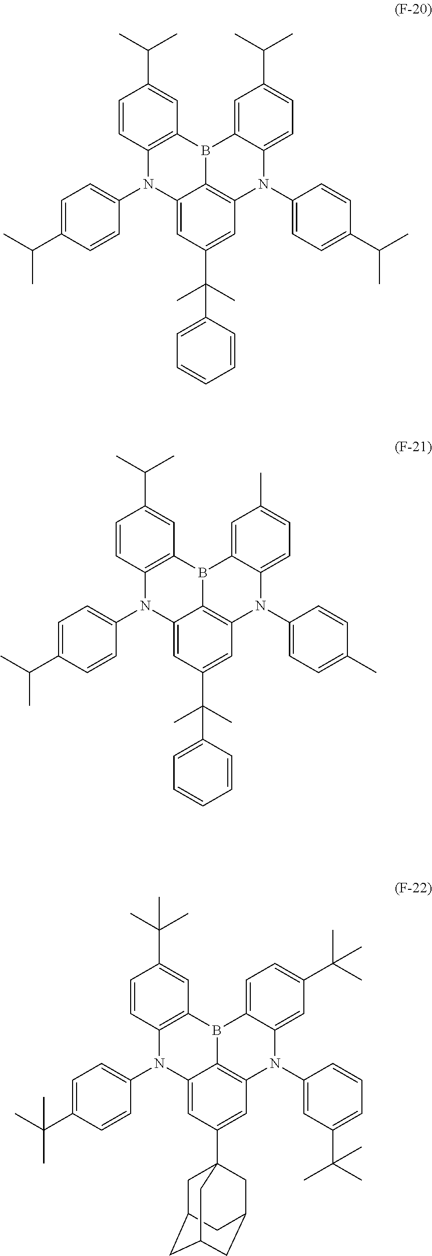

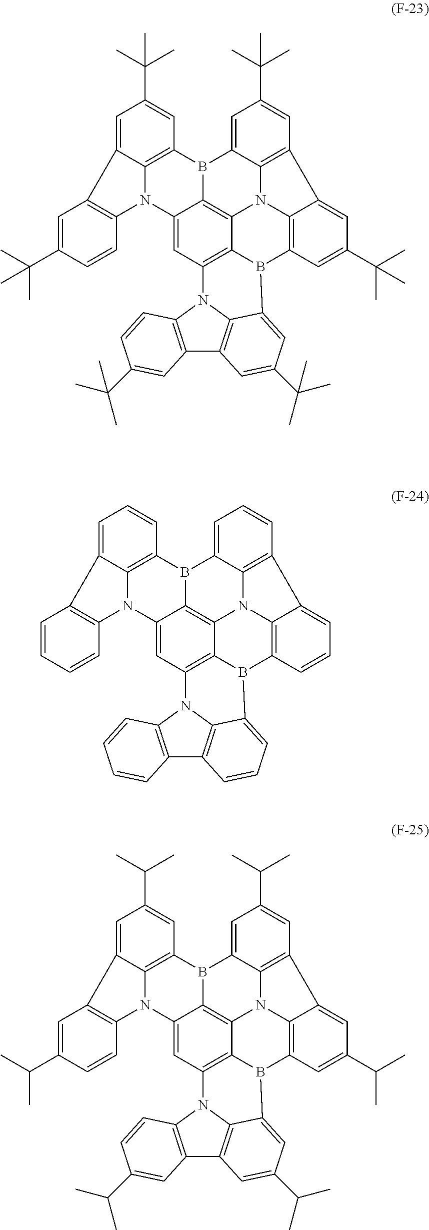

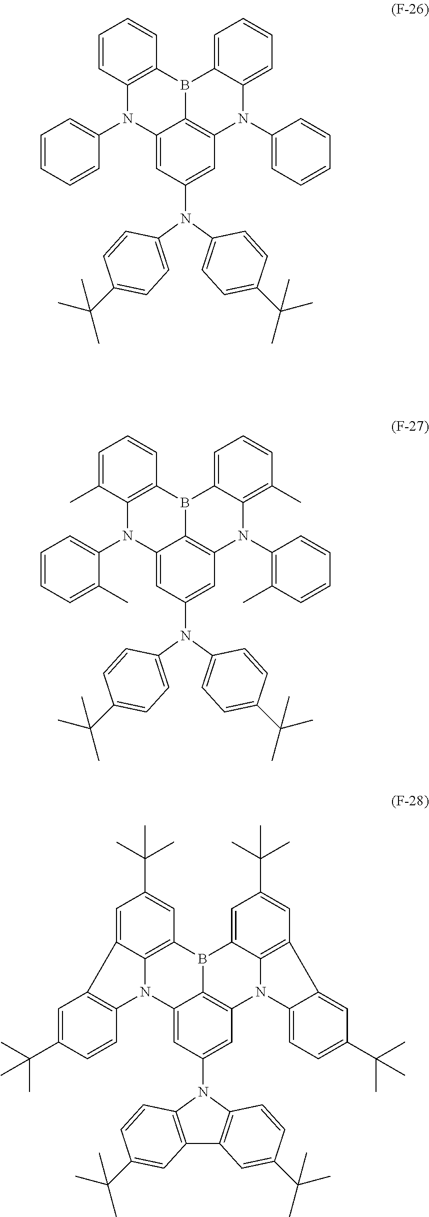 [SMILES: CC(C)(C)c1ccc(N(c2ccc(C(C)(C)C)cc2)c2cc3c4c(c2)N(c2ccccc2)c2ccccc2B4c2ccccc2N3c2ccccc2)cc1 ; Cc1ccccc1N1c2cc(N(c3ccc(C(C)(C)C)cc3)c3ccc(C(C)(C)C)cc3)cc3c2B(c2cccc(C)c21)c1cccc(C)c1N3c1ccccc1C ; CC(C)(C)c1ccc2c(c1)c1cc(C(C)(C)C)ccc1n2-c1cc2c3c(c1)-n1c4ccc(C(C)(C)C)cc4c4cc(C(C)(C)C)cc(c41)B3c1cc(C(C)(C)C)cc3c4cc(C(C)(C)C)ccc4n-2c13]

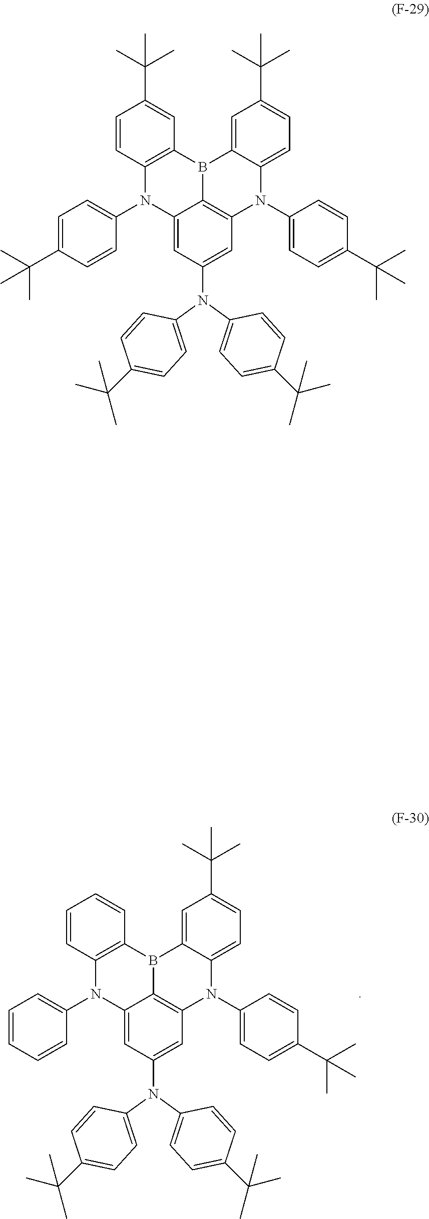 [SMILES: CC(C)(C)c1ccc(N(c2ccc(C(C)(C)C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)cc1 ; CC(C)(C)c1ccc(N(c2ccc(C(C)(C)C)cc2)c2cc3c4c(c2)N(c2ccc(C(C)(C)C)cc2)c2ccc(C(C)(C)C)cc2B4c2ccccc2N3c2ccccc2)cc1]

In an alternative embodiment, the thermally activated delayed fluorescence sensitizer is selected from one or a combination of at least two of compounds TDE1 to TDE45 (for example, a combination of TDE1 and TDE6, or a combination of TDE6, TDE32 and TDE23):

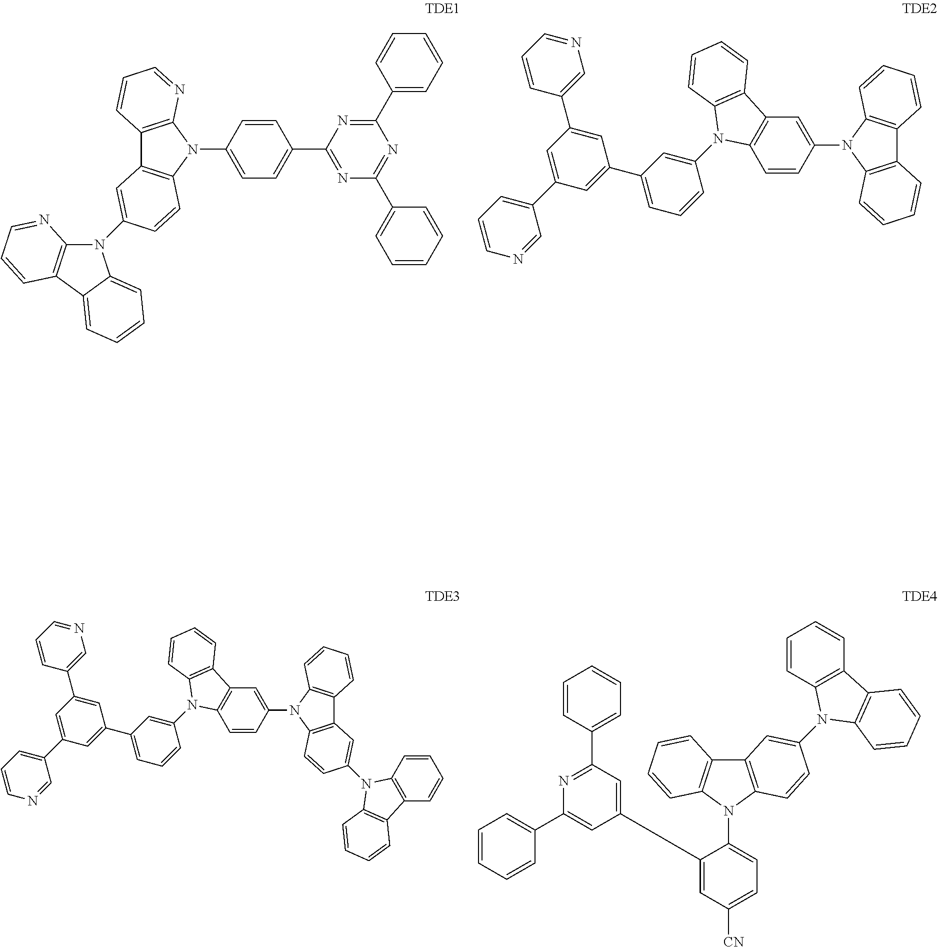

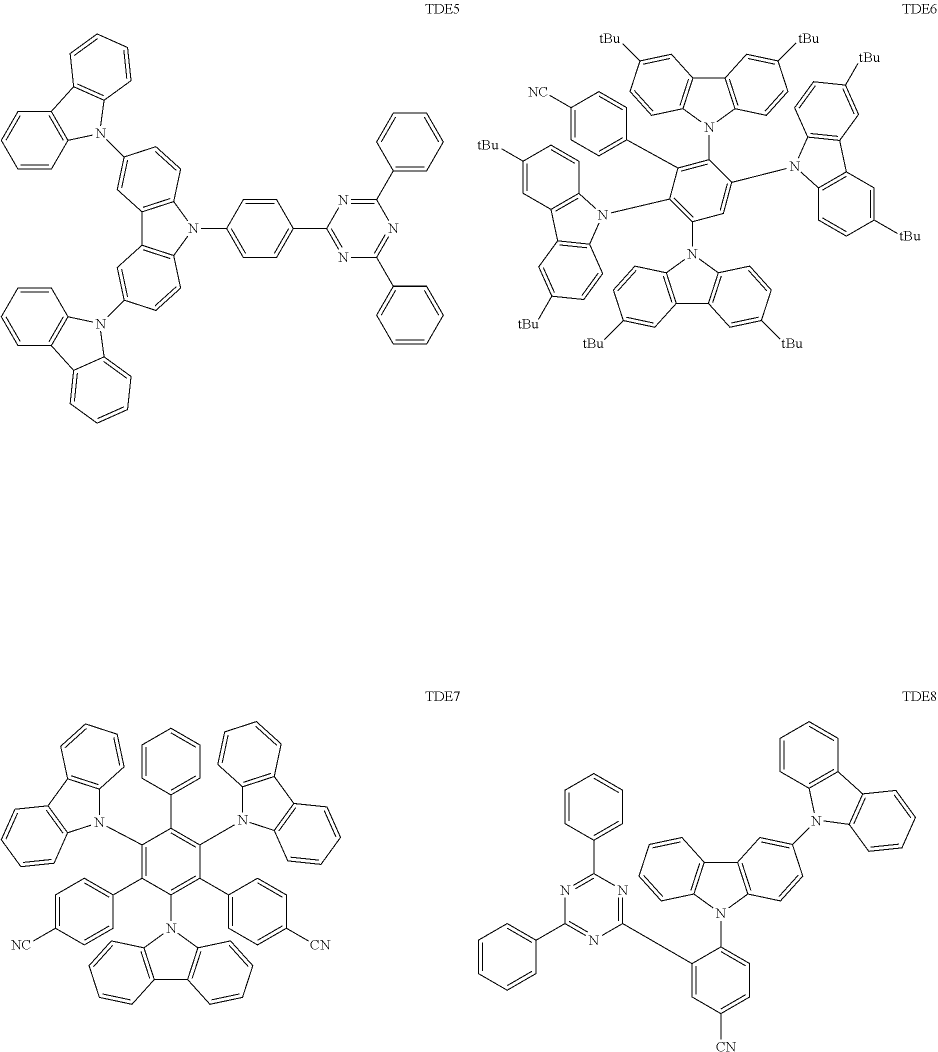

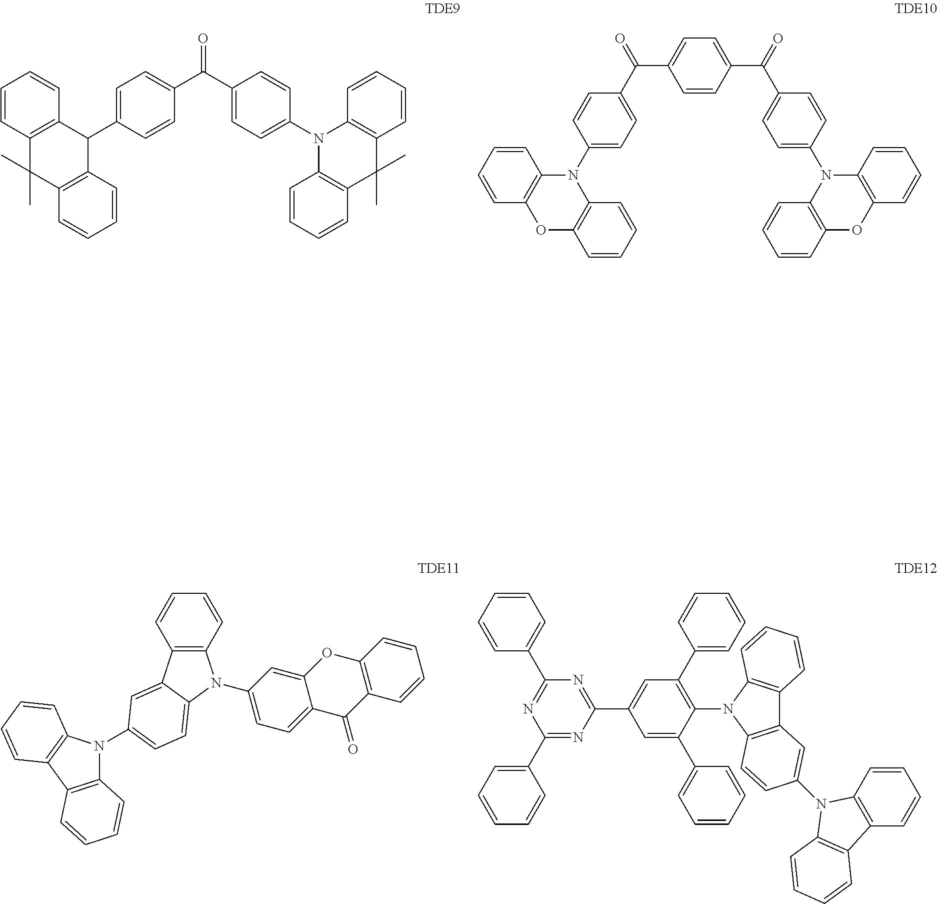 [SMILES: CC1(C)c2ccccc2C(c2ccc(C(=O)c3ccc(N4c5ccccc5C(C)(C)c5ccccc54)cc3)cc2)c2ccccc21 ; O=C(c1ccc(C(=O)c2ccc(N3c4ccccc4Oc4ccccc43)cc2)cc1)c1ccc(N2c3ccccc3Oc3ccccc32)cc1 ; O=c1c2ccccc2oc2cc(-n3c4ccccc4c4cc(-n5c6ccccc6c6ccccc65)ccc43)ccc12 ; c1ccc(-c2nc(-c3ccccc3)nc(-c3cc(-c4ccccc4)c(-n4c5ccccc5c5cc(-n6c7ccccc7c7ccccc76)ccc54)c(-c4ccccc4)c3)n2)cc1]

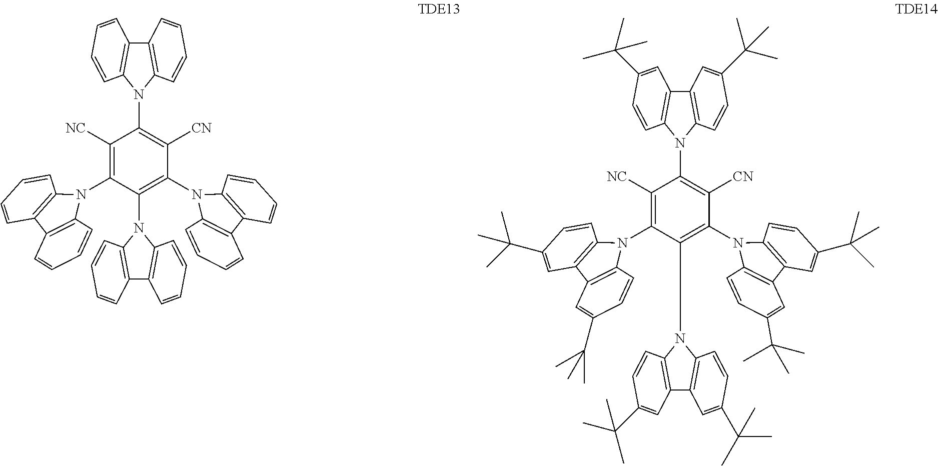 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21 ; CC(C)(C)c1ccc2c(c1)c1cc(C(C)(C)C)ccc1n2-c1c(C#N)c(-n2c3ccc(C(C)(C)C)cc3c3cc(C(C)(C)C)ccc32)c(-n2c3ccc(C(C)(C)C)cc3c3cc(C(C)(C)C)ccc32)c(-n2c3ccc(C(C)(C)C)cc3c3cc(C(C)(C)C)ccc32)c1C#N]

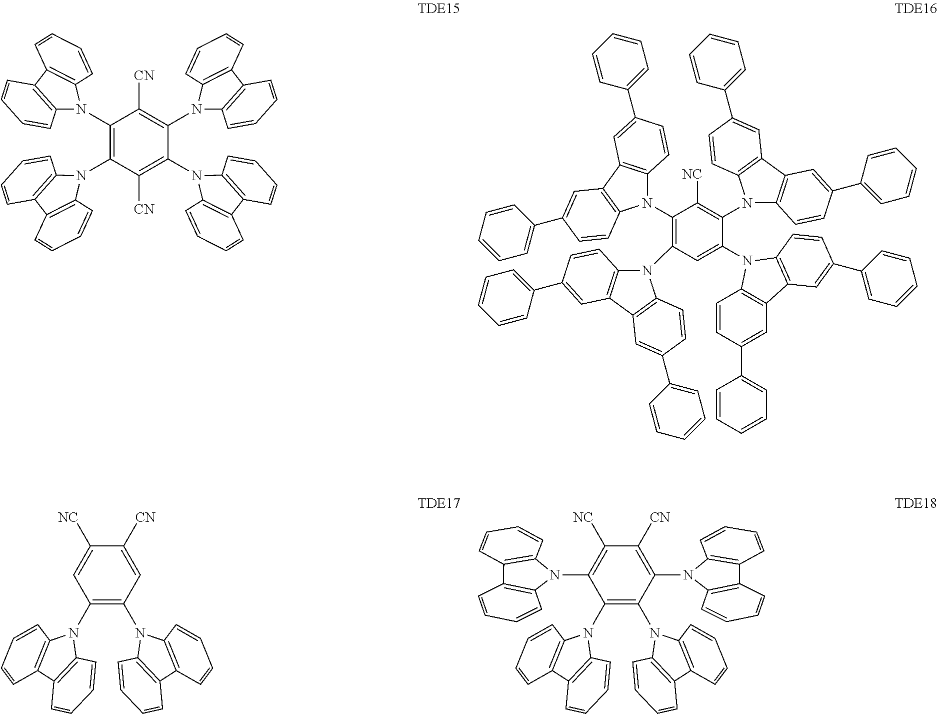 [SMILES: N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21 ; N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)cc(-n2c3ccc(-c4ccccc4)cc3c3cc(-c4ccccc4)ccc32)c1-n1c2ccc(-c3ccccc3)cc2c2cc(-c3ccccc3)ccc21 ; N#Cc1cc(-n2c3ccccc3c3ccccc32)c(-n2c3ccccc3c3ccccc32)cc1C#N ; N#Cc1c(C#N)c(-n2c3ccccc3c3ccccc32)c(-n2c3ccccc3c3ccccc32)c(-n2c3ccccc3c3ccccc32)c1-n1c2ccccc2c2ccccc21]

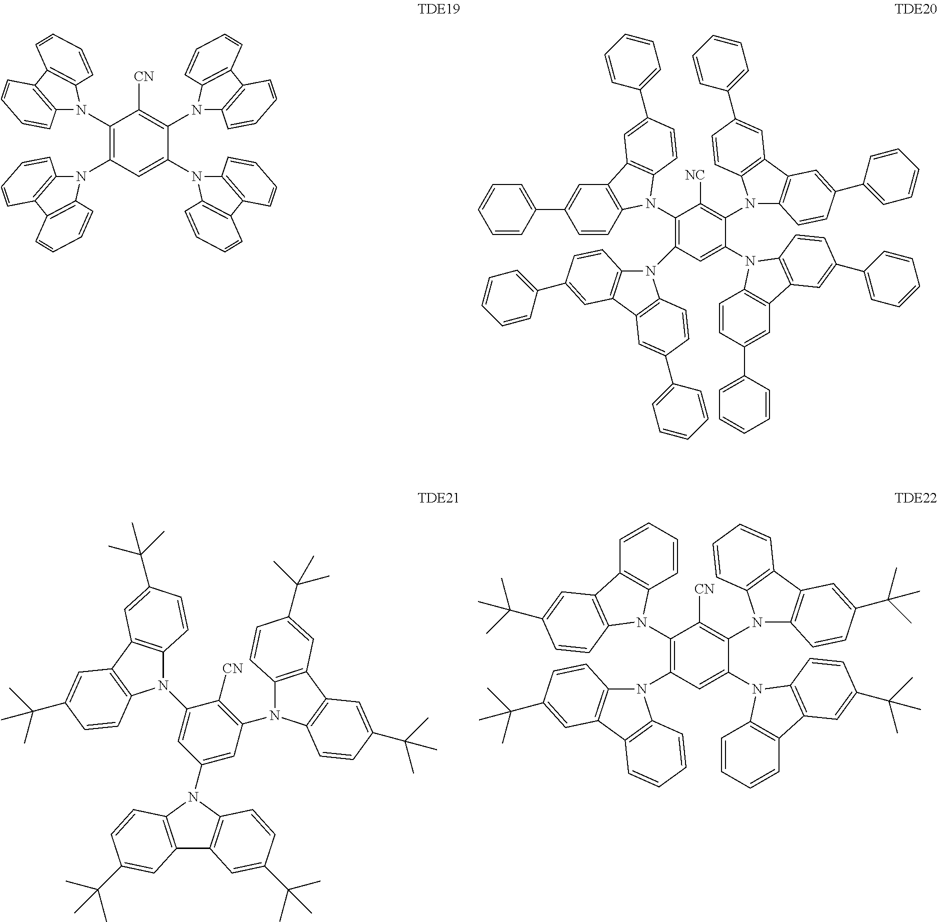

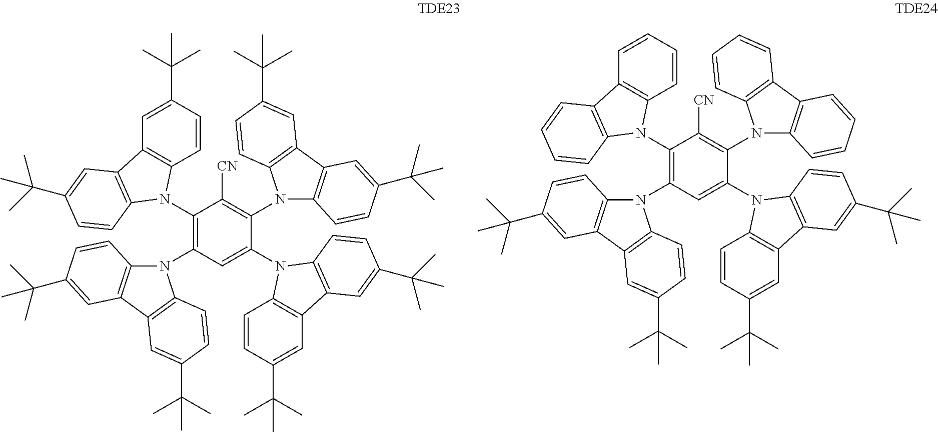 [SMILES: CC(C)(C)c1ccc2c(c1)c1cc(C(C)(C)C)ccc1n2-c1cc(-n2c3ccc(C(C)(C)C)cc3c3cc(C(C)(C)C)ccc32)c(-n2c3ccc(C(C)(C)C)cc3c3cc(C(C)(C)C)ccc32)c(C#N)c1-n1c2ccc(C(C)(C)C)cc2c2cc(C(C)(C)C)ccc21 ; CC(C)(C)c1ccc2c(c1)c1cc(C(C)(C)C)ccc1n2-c1cc(-n2c3ccc(C(C)(C)C)cc3c3cc(C(C)(C)C)ccc32)c(-n2c3ccccc3c3ccccc32)c(C#N)c1-n1c2ccccc2c2ccccc21]

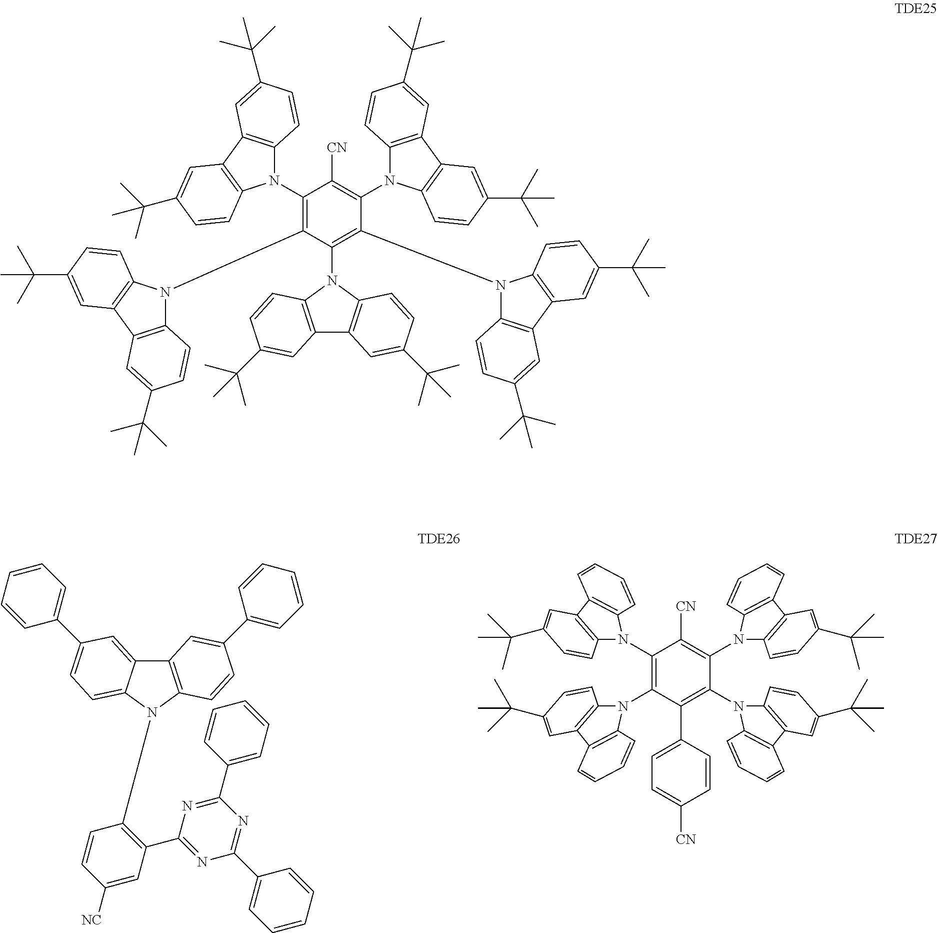

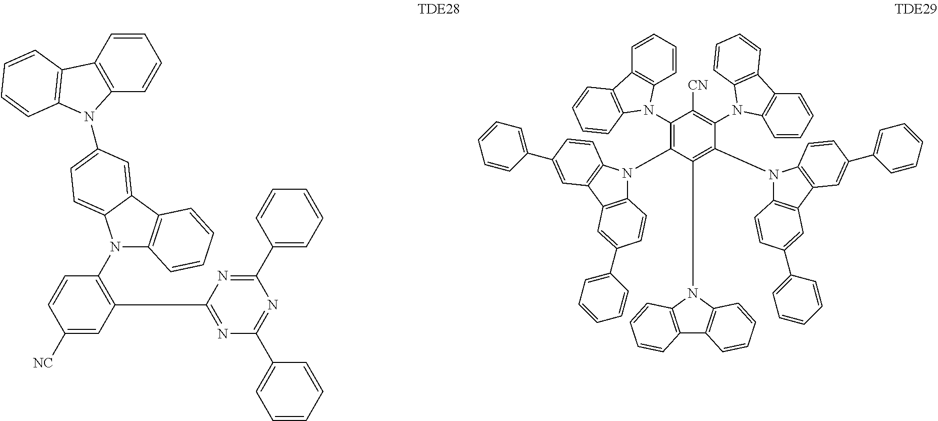 [SMILES: N#Cc1ccc(-n2c3ccccc3c3cc(-n4c5ccccc5c5ccccc54)ccc32)c(-c2nc(-c3ccccc3)nc(-c3ccccc3)n2)c1 ; N#Cc1c(-n2c3ccccc3c3ccccc32)c(-n2c3ccc(-c4ccccc4)cc3c3cc(-c4ccccc4)ccc32)c(-n2c3ccccc3c3ccccc32)c(-n2c3ccc(-c4ccccc4)cc3c3cc(-c4ccccc4)ccc32)c1-n1c2ccccc2c2ccccc21]

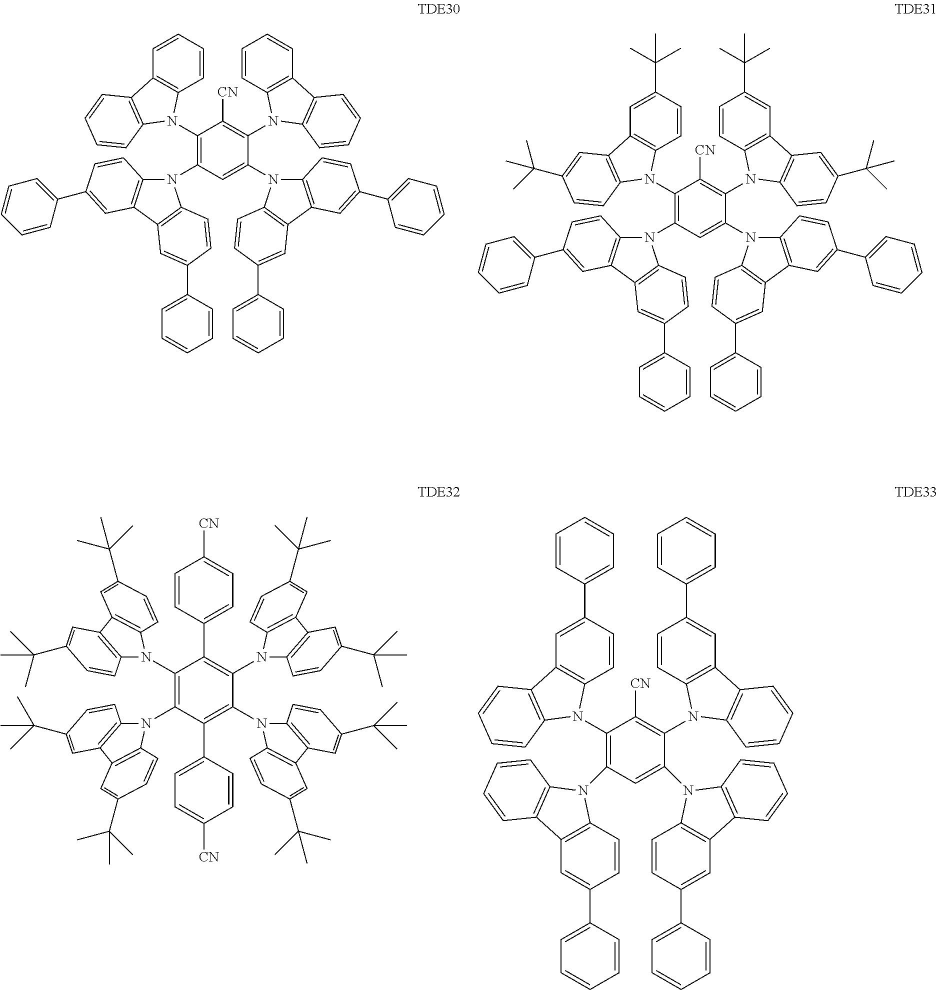

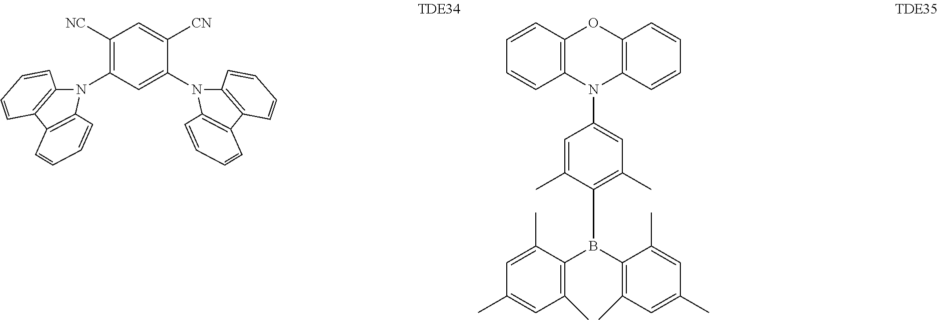

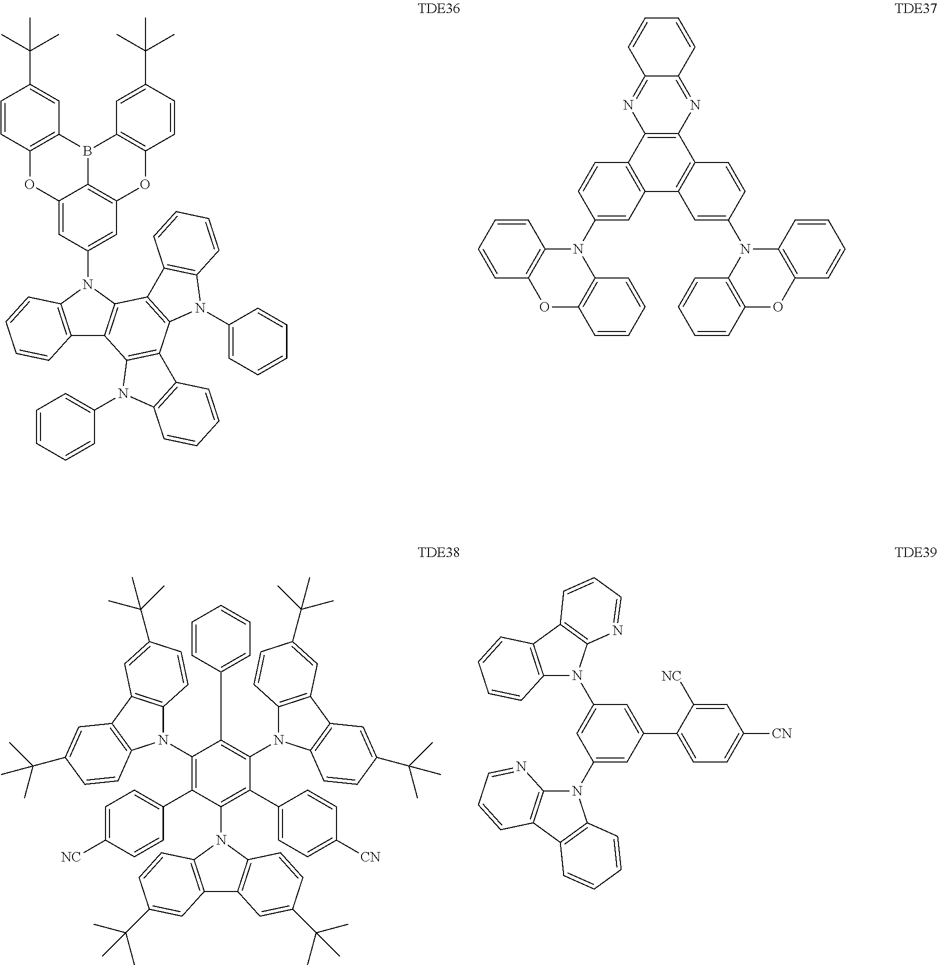 [SMILES: CC(C)(C)c1ccc2c(c1)B1c3cc(C(C)(C)C)ccc3Oc3cc(-n4c5ccccc5c5c6c(c7ccccc7n6-c6ccccc6)c6c(c7ccccc7n6-c6ccccc6)c54)cc(c31)O2 ; c1ccc2c(c1)Oc1ccccc1N2c1ccc2c(c1)c1cc(N3c4ccccc4Oc4ccccc43)ccc1c1nc3ccccc3nc21 ; CC(C)(C)c1ccc2c(c1)c1cc(C(C)(C)C)ccc1n2-c1c(-c2ccccc2)c(-n2c3ccc(C(C)(C)C)cc3c3cc(C(C)(C)C)ccc32)c(-c2ccc(C#N)cc2)c(-n2c3ccc(C(C)(C)C)cc3c3cc(C(C)(C)C)ccc32)c1-c1ccc(C#N)cc1 ; N#Cc1ccc(-c2cc(-n3c4ccccc4c4cccnc43)cc(-n3c4ccccc4c4cccnc43)c2)c(C#N)c1]

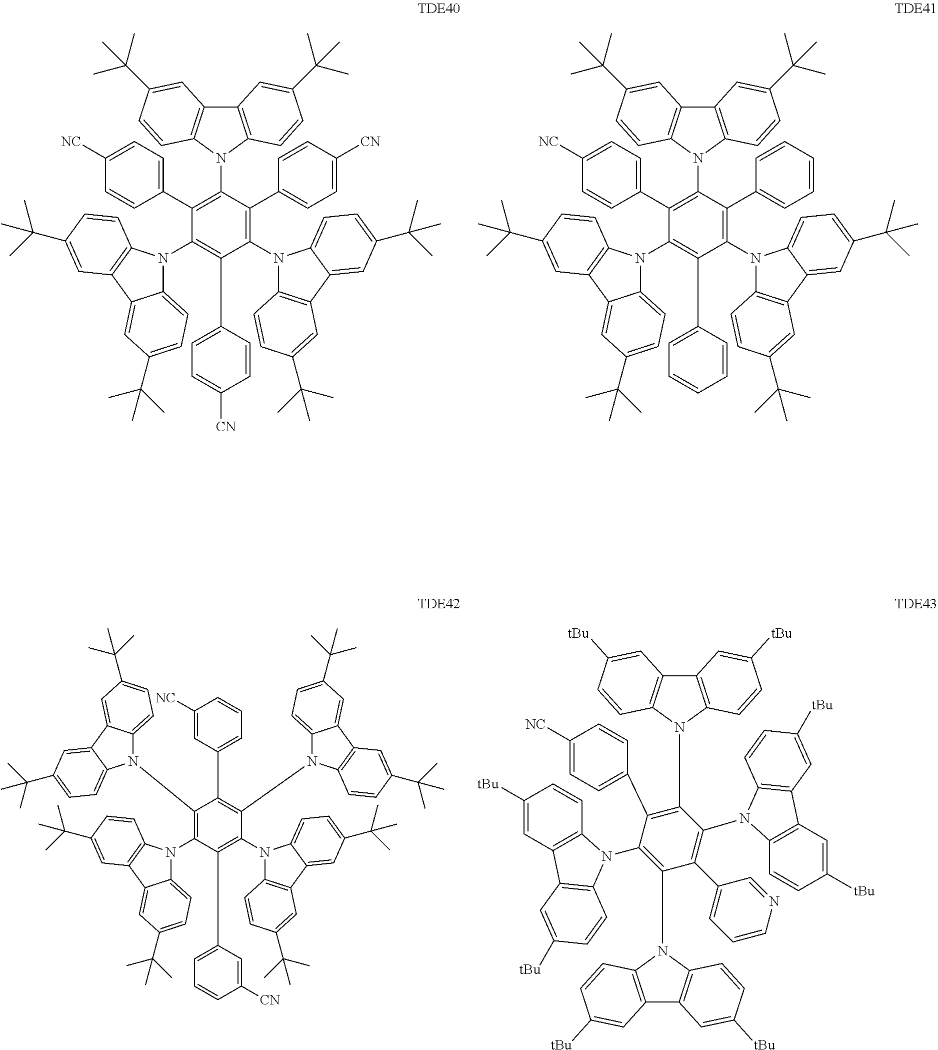

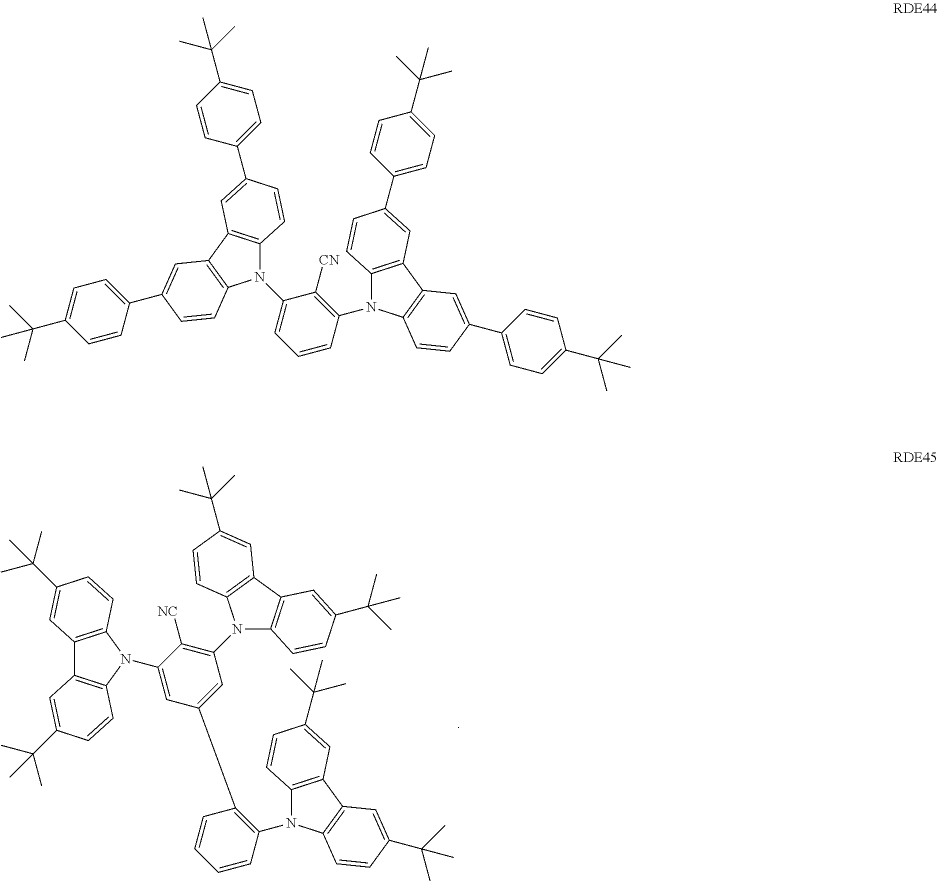

In an alternative embodiment, the host material is selected from any one or a combination of at least two of compounds TDH-1 to TDH-30 (for example, a combination of TDH-3 and TDH-20, or a combination of TDH-32, TDH-20 and TDH-5):

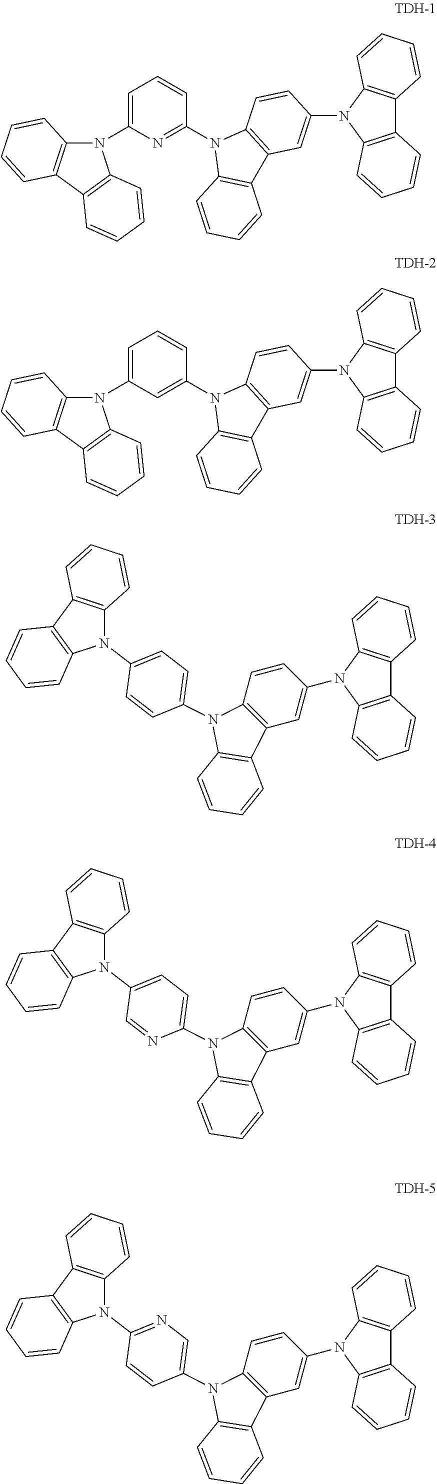 [SMILES: c1cc(-n2c3ccccc3c3ccccc32)nc(-n2c3ccccc3c3cc(-n4c5ccccc5c5ccccc54)ccc32)c1 ; c1cc(-n2c3ccccc3c3ccccc32)cc(-n2c3ccccc3c3cc(-n4c5ccccc5c5ccccc54)ccc32)c1 ; c1ccc2c(c1)c1ccccc1n2-c1ccc(-n2c3ccccc3c3cc(-n4c5ccccc5c5ccccc54)ccc32)cc1 ; c1ccc2c(c1)c1ccccc1n2-c1ccc(-n2c3ccccc3c3cc(-n4c5ccccc5c5ccccc54)ccc32)nc1 ; c1ccc2c(c1)c1ccccc1n2-c1ccc2c(c1)c1ccccc1n2-c1ccc(-n2c3ccccc3c3ccccc32)nc1]

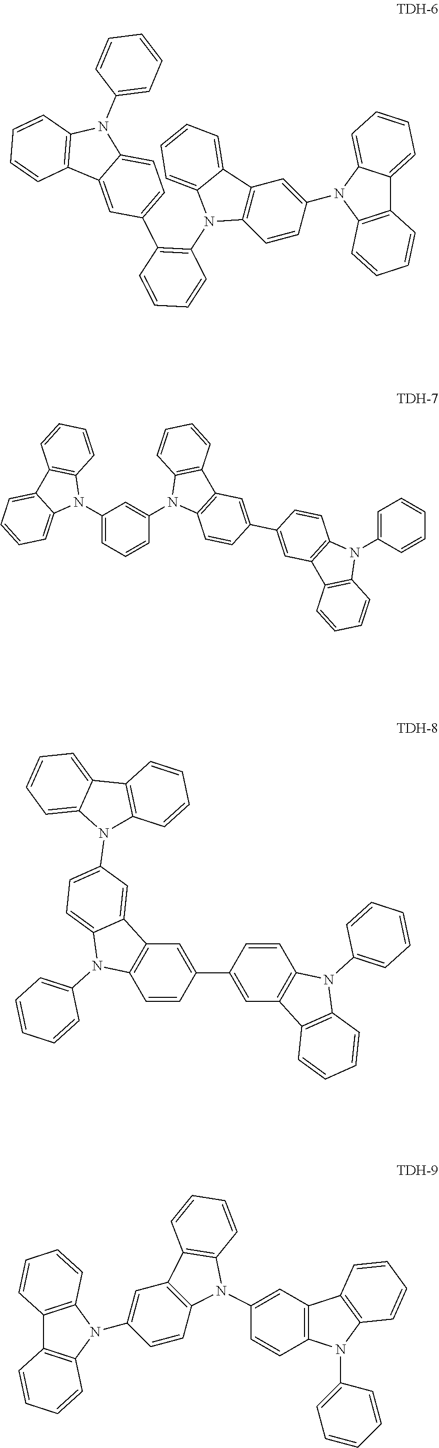 [SMILES: c1ccc(-n2c3ccccc3c3cc(-c4ccccc4-n4c5ccccc5c5cc(-n6c7ccccc7c7ccccc76)ccc54)ccc32)cc1 ; c1ccc(-n2c3ccccc3c3cc(-c4ccc5c(c4)c4ccccc4n5-c4cccc(-n5c6ccccc6c6ccccc65)c4)ccc32)cc1 ; c1ccc(-n2c3ccccc3c3cc(-c4ccc5c(c4)c4cc(-n6c7ccccc7c7ccccc76)ccc4n5-c4ccccc4)ccc32)cc1 ; c1ccc(-n2c3ccccc3c3cc(-n4c5ccccc5c5cc(-n6c7ccccc7c7ccccc76)ccc54)ccc32)cc1]

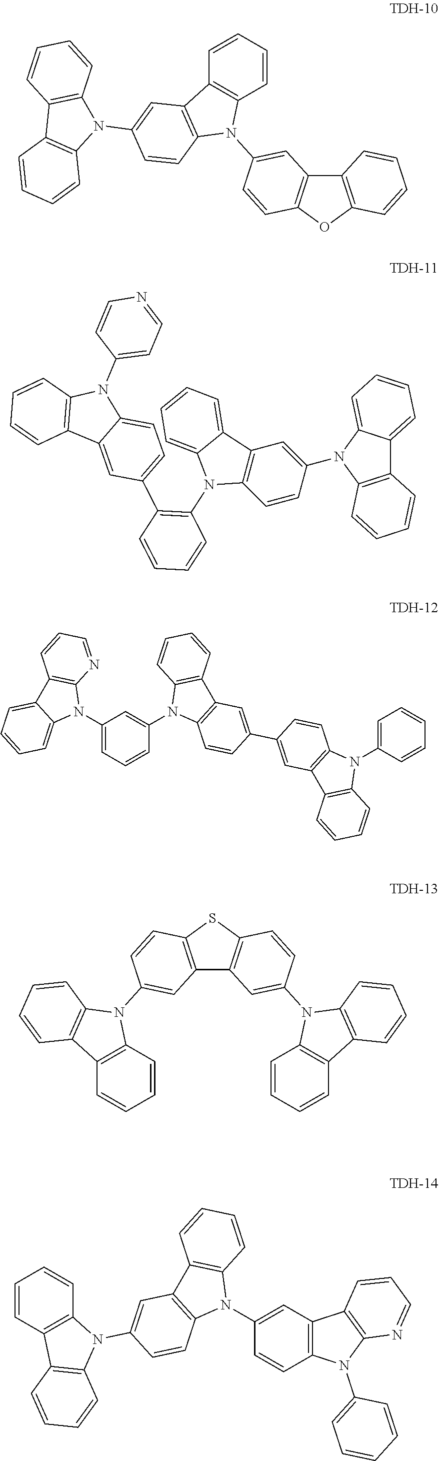 [SMILES: c1ccc2c(c1)oc1ccc(-n3c4ccccc4c4cc(-n5c6ccccc6c6ccccc65)ccc43)cc12 ; c1ccc(-n2c3ccccc3c3cc(-n4c5ccccc5c5ccccc54)ccc32)c(-c2ccc3c(c2)c2ccccc2n3-c2ccncc2)c1 ; c1ccc(-n2c3ccccc3c3cc(-c4ccc5c(c4)c4ccccc4n5-c4cccc(-n5c6ccccc6c6cccnc65)c4)ccc32)cc1 ; c1ccc2c(c1)c1ccccc1n2-c1ccc2sc3ccc(-n4c5ccccc5c5ccccc54)cc3c2c1 ; c1ccc(-n2c3ccc(-n4c5ccccc5c5cc(-n6c7ccccc7c7ccccc76)ccc54)cc3c3cccnc32)cc1]

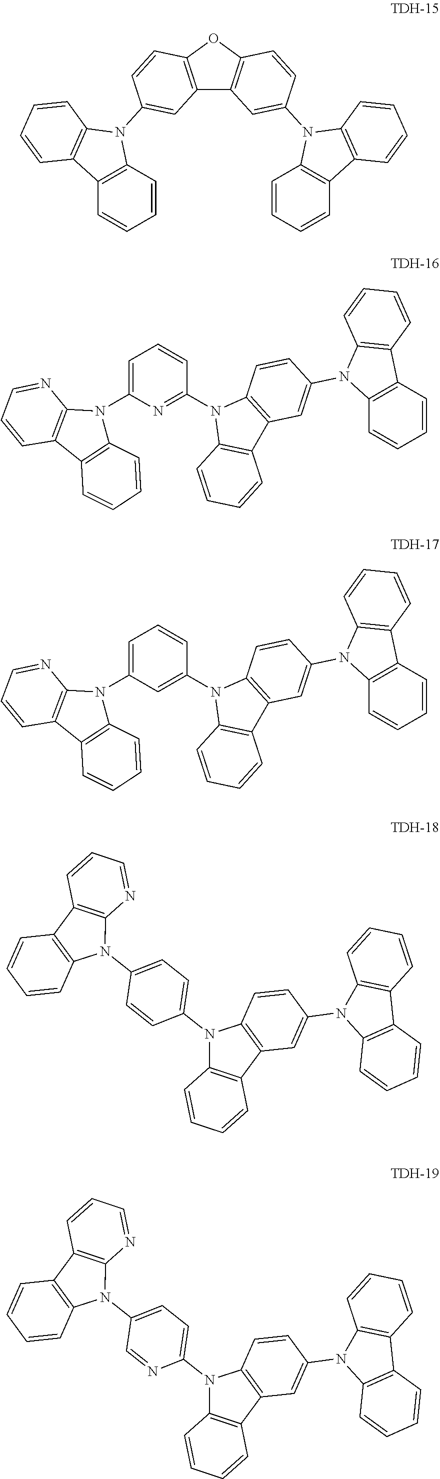 [SMILES: c1ccc2c(c1)c1ccccc1n2-c1ccc2oc3ccc(-n4c5ccccc5c5ccccc54)cc3c2c1 ; c1cc(-n2c3ccccc3c3cc(-n4c5ccccc5c5ccccc54)ccc32)nc(-n2c3ccccc3c3cccnc32)c1 ; c1cc(-n2c3ccccc3c3cc(-n4c5ccccc5c5ccccc54)ccc32)cc(-n2c3ccccc3c3cccnc32)c1 ; c1ccc2c(c1)c1ccccc1n2-c1ccc2c(c1)c1ccccc1n2-c1ccc(-n2c3ccccc3c3cccnc32)cc1 ; c1ccc2c(c1)c1ccccc1n2-c1ccc2c(c1)c1ccccc1n2-c1ccc(-n2c3ccccc3c3cccnc32)cn1]

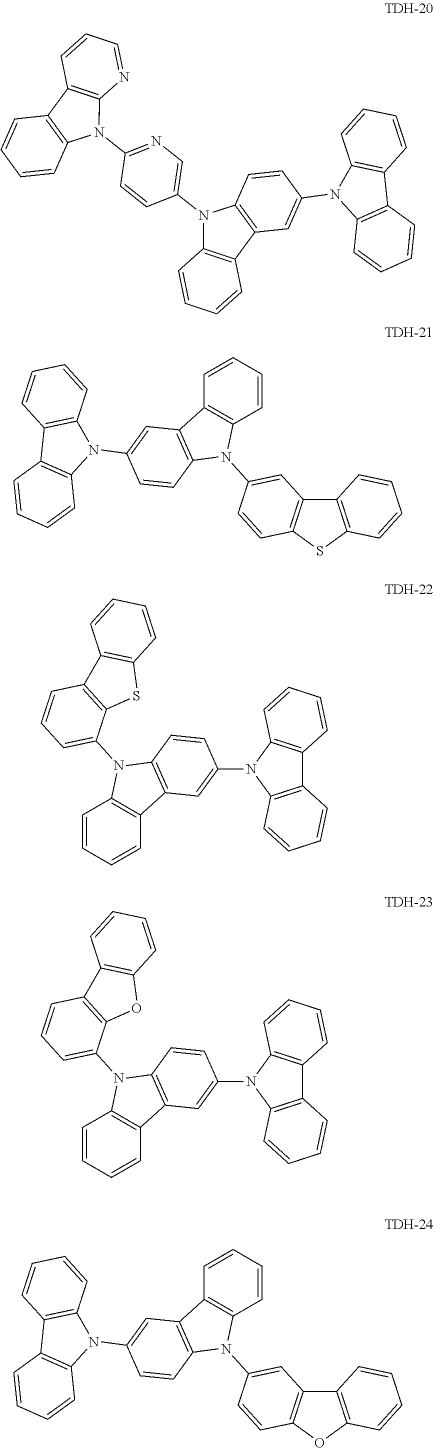

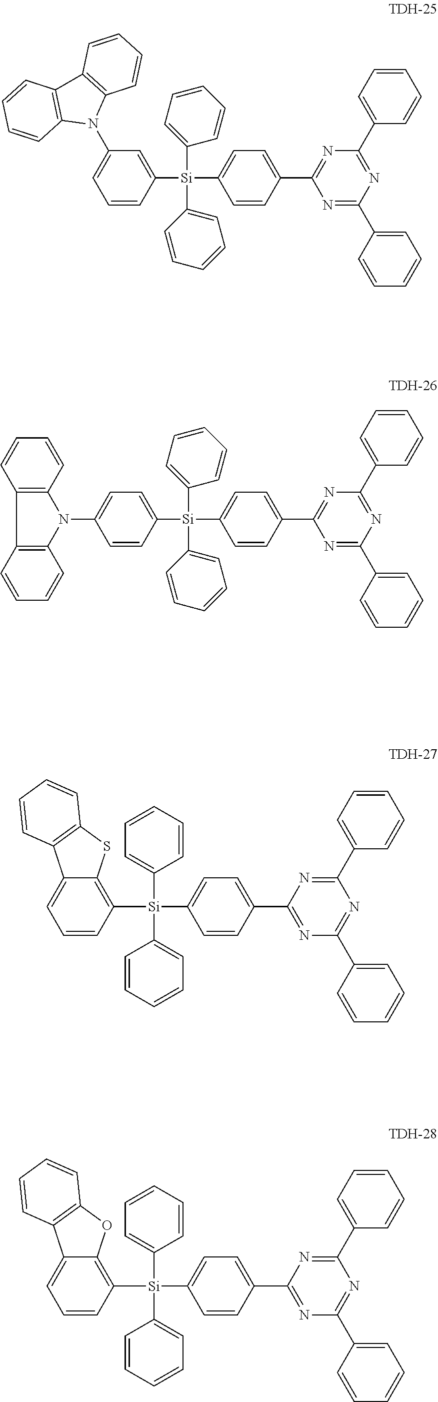 [SMILES: c1ccc(-c2nc(-c3ccccc3)nc(-c3ccc([Si](c4ccccc4)(c4ccccc4)c4cccc(-n5c6ccccc6c6ccccc65)c4)cc3)n2)cc1 ; c1ccc(-c2nc(-c3ccccc3)nc(-c3ccc([Si](c4ccccc4)(c4ccccc4)c4ccc(-n5c6ccccc6c6ccccc65)cc4)cc3)n2)cc1 ; c1ccc(-c2nc(-c3ccccc3)nc(-c3ccc([Si](c4ccccc4)(c4ccccc4)c4cccc5c4sc4ccccc45)cc3)n2)cc1 ; c1ccc(-c2nc(-c3ccccc3)nc(-c3ccc([Si](c4ccccc4)(c4ccccc4)c4cccc5c4oc4ccccc45)cc3)n2)cc1]

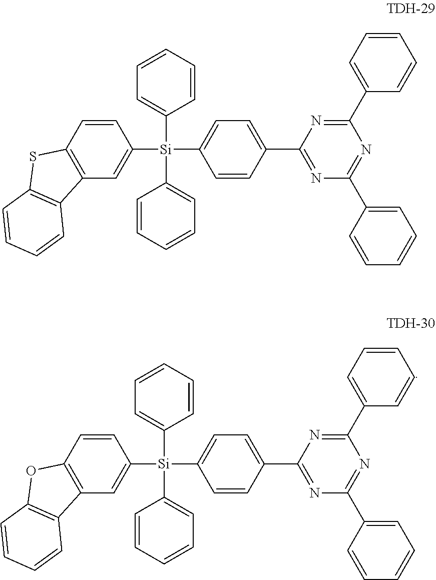 [SMILES: c1ccc(-c2nc(-c3ccccc3)nc(-c3ccc([Si](c4ccccc4)(c4ccccc4)c4ccc5sc6ccccc6c5c4)cc3)n2)cc1 ; c1ccc(-c2nc(-c3ccccc3)nc(-c3ccc([Si](c4ccccc4)(c4ccccc4)c4ccc5oc6ccccc6c5c4)cc3)n2)cc1]

In the embodiments of the present disclosure, unless the comparison of absolute values is specified, the magnitude relationship between energy levels refers to a magnitude relationship between actual values. For example, it is considered that the LUMO energy level with a value of −1.7 eV is higher than the LUMO energy level with a value of −2.2 eV, that is, −1.7 eV >−2.2 eV in the LUMO energy level, which may also be referred to as that the LUMO energy level with a value of −1.7 eV is shallower than the LUMO energy level with a value of −2.2 eV.

For example, it is considered that the HOMO energy level with a value of −4.9 eV is higher than the HOMO energy level with a value of −5.5 eV, that is, −4.9 eV >−5.5 eV in the HOMO energy level, which may also be referred to as that the HOMO energy level with a value of −4.9 eV is shallower than the HOMO energy level with a value of −5.5 eV.

In an alternative embodiment, the mass of the dye accounts for 0.1 wt %-20 wt % (which may simply be referred to as a doping concentration) of the total mass of the light-emitting layer, for example, 2 wt %, 4 wt %, 6 wt %, 8 wt %, 10 wt %, 12 wt %, 14 wt %, 15 wt %, 16 wt %, 18 wt %, 20 wt %, etcetera. Excessive doping concentration of the dye can lead to obvious charge carrier trapping on the dye, easily cause the aggregation-caused quenching of the dye and thus affects the service life and voltage of the device. Too low doping concentration of the dye can lead to incomplete energy transfer from the host material and sensitizer to the dye and thus affects the efficiency and service life of the device. The use of the preferred specific doping concentration of the dye in the embodiment of the present disclosure can ensure complete energy transfer from the host material and the sensitizer to the dye and avoid obvious charge carrier trapping on the dye, which is more conducive to improving the performance of the device.

In an alternative embodiment, the thickness of the light-emitting layer is 1 nm-100 nm, for example, 10 nm, 20 nm, 30 nm, 40 nm, 50 nm, 60 nm, 70 nm, 80 nm, 90 nm, etcetera.

In an embodiment of the present disclosure, the thickness of the light-emitting layer is optimized to adjust the recombination position of the excitons so that the excitons can be recombined on the light-emitting layer of the device better, thereby further improving the performance of the device.

In an optional embodiment, the organic layer further includes any one or a combination of at least two of a hole injection layer, a hole transport layer, a hole blocking layer, an electron transport layer and an electron injection layer.

The hole transport region, the electron transport region and the cathode in an embodiment of the present disclosure are described below.

The hole transport region is located between the anode and the light-emitting layer. The hole transport region may be a hole transport layer (HTL) with a single-layer structure and includes a single-layer hole transport layer containing only one compound and a single-layer hole transport layer containing multiple compounds. The hole transport region may also be a multi-layer structure including at least two of a hole injection layer (HIL), a hole transport layer (HTL) and an electron blocking layer (EBL). The HIL is located between the anode and the HTL, and the EBL is located between the HTL and the light-emitting layer.

The material of the hole transport region may be selected from, but is not limited to, phthalocyanine derivatives such as CuPc, conductive polymers, polymers containing conductive dopants such as poly (p-phenylene vinylene), polyaniline/dodecyl benzenesulfonic acid (PANI/DBSA), poly (3,4-ethylenedioxythiophene)/poly (sodium 4-styrenesulfonate) (PEDOT/PSS), polyaniline/camphorsulfonic acid (PANI/CSA) or polyaniline/poly (sodium 4-styrenesulfonate) (PANI/PSS), or aromatic amine derivatives. The aromatic amine derivatives are compounds HT-1 to HT-51 as shown below or any combination thereof (for example, a combination of HT-3 and HT-23 or a combination of HT-6, HT-5 and HT-12).

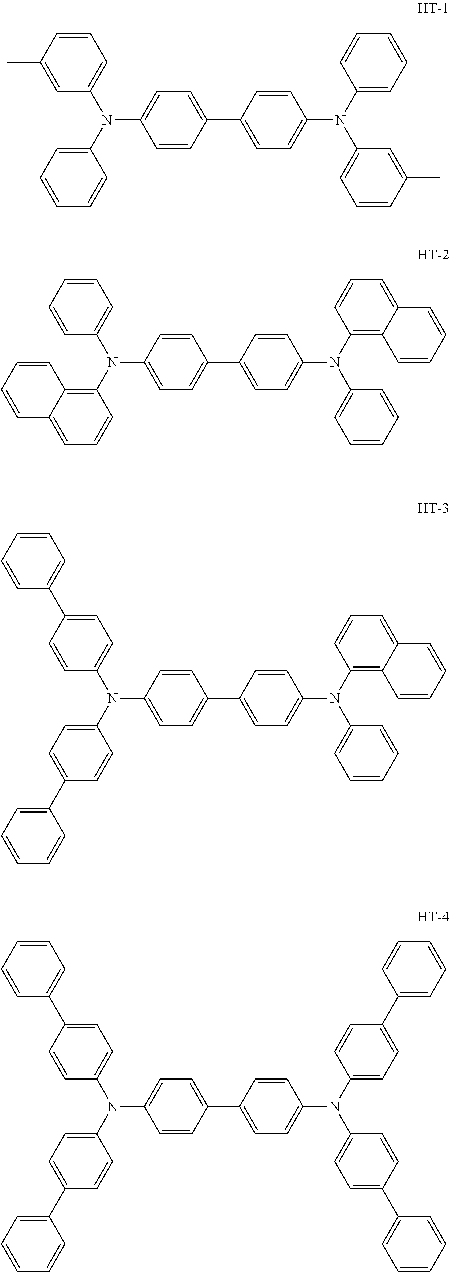

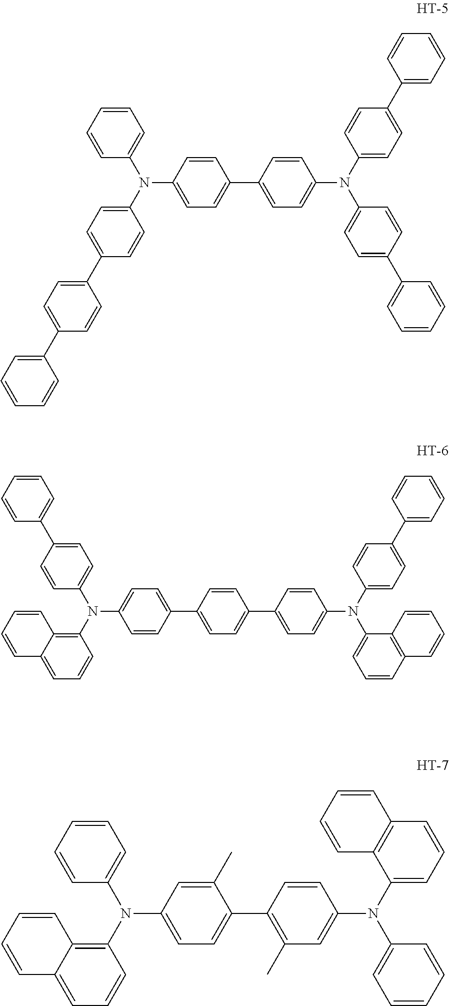 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(N(c3ccc(-c4ccc(-c5ccc(N(c6ccc(-c7ccccc7)cc6)c6cccc7ccccc67)cc5)cc4)cc3)c3cccc4ccccc34)cc2)cc1 ; Cc1cc(N(c2ccccc2)c2cccc3ccccc23)ccc1-c1ccc(N(c2ccccc2)c2cccc3ccccc23)cc1C]

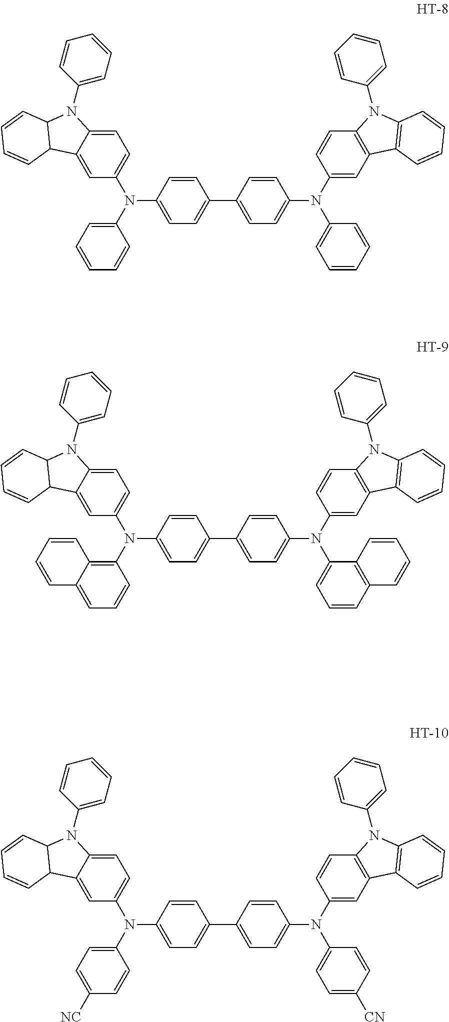 [SMILES: C1=CC2c3cc(N(c4ccccc4)c4ccc(-c5ccc(N(c6ccccc6)c6ccc7c(c6)c6ccccc6n7-c6ccccc6)cc5)cc4)ccc3N(c3ccccc3)C2C=C1 ; C1=CC2c3cc(N(c4ccc(-c5ccc(N(c6ccc7c(c6)c6ccccc6n7-c6ccccc6)c6cccc7ccccc67)cc5)cc4)c4cccc5ccccc45)ccc3N(c3ccccc3)C2C=C1 ; N#Cc1ccc(N(c2ccc(-c3ccc(N(c4ccc(C#N)cc4)c4ccc5c(c4)c4ccccc4n5-c4ccccc4)cc3)cc2)c2ccc3c(c2)C2C=CC=CC2N3c2ccccc2)cc1]

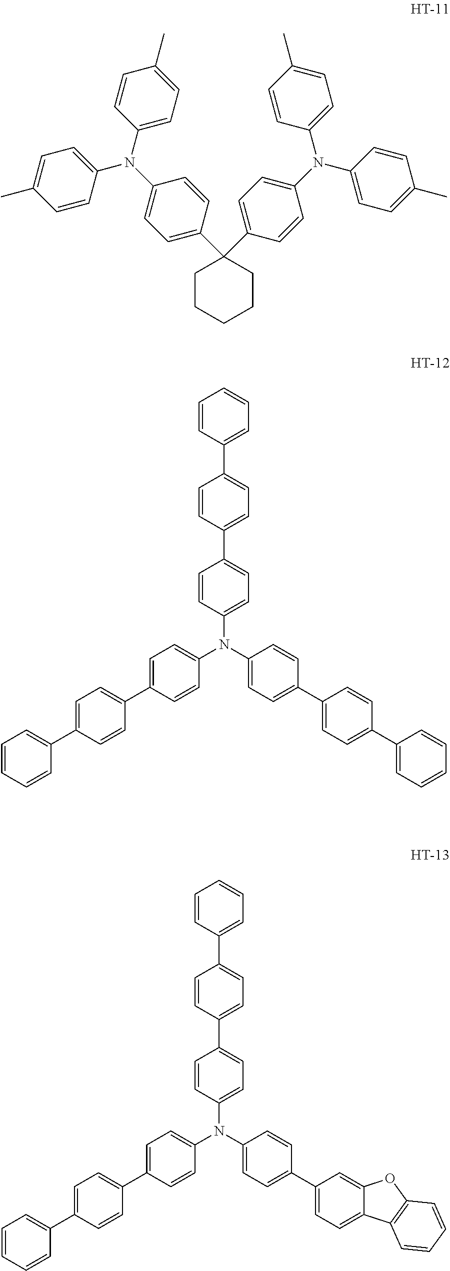

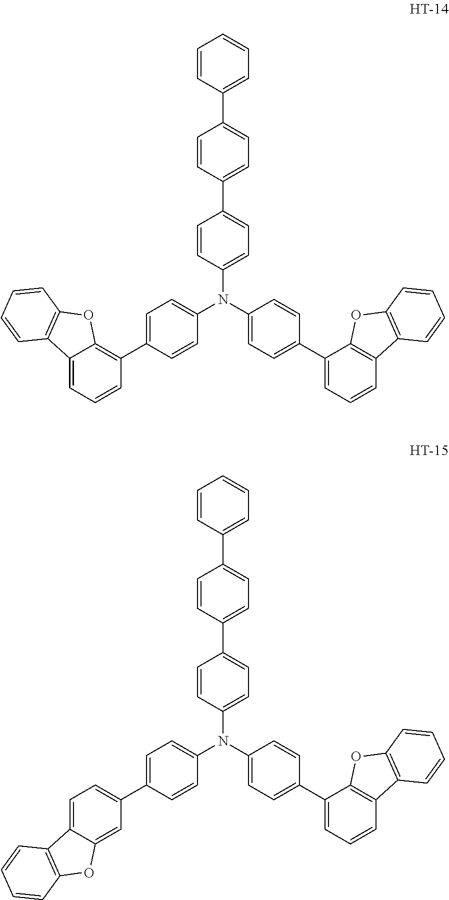 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(-c3ccc(N(c4ccc(-c5ccc6c(c5)oc5ccccc56)cc4)c4ccc(-c5cccc6c5oc5ccccc56)cc4)cc3)cc2)cc1]

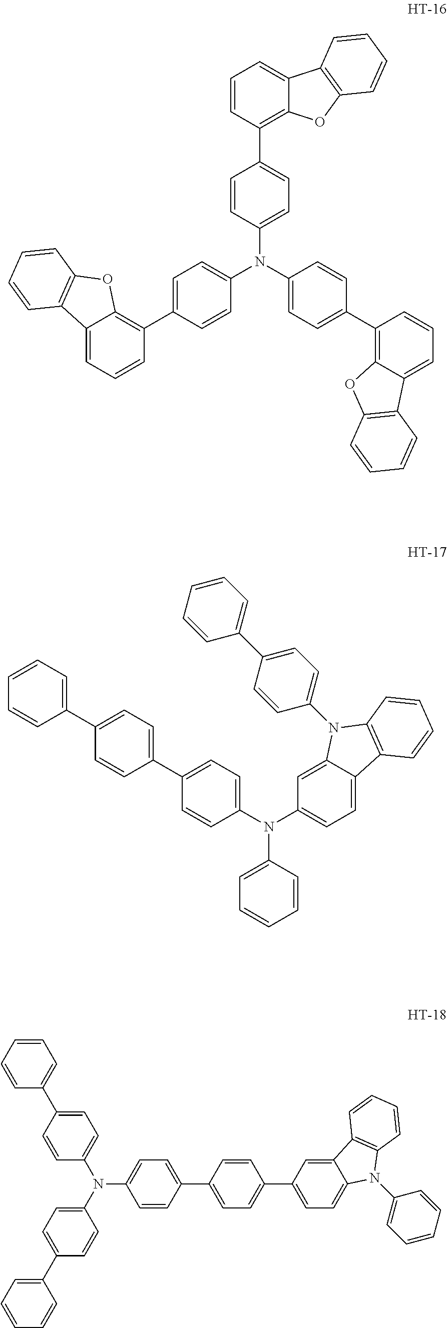 [SMILES: c1ccc2c(c1)oc1c(-c3ccc(N(c4ccc(-c5cccc6c5oc5ccccc56)cc4)c4ccc(-c5cccc6c5oc5ccccc56)cc4)cc3)cccc12 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1]

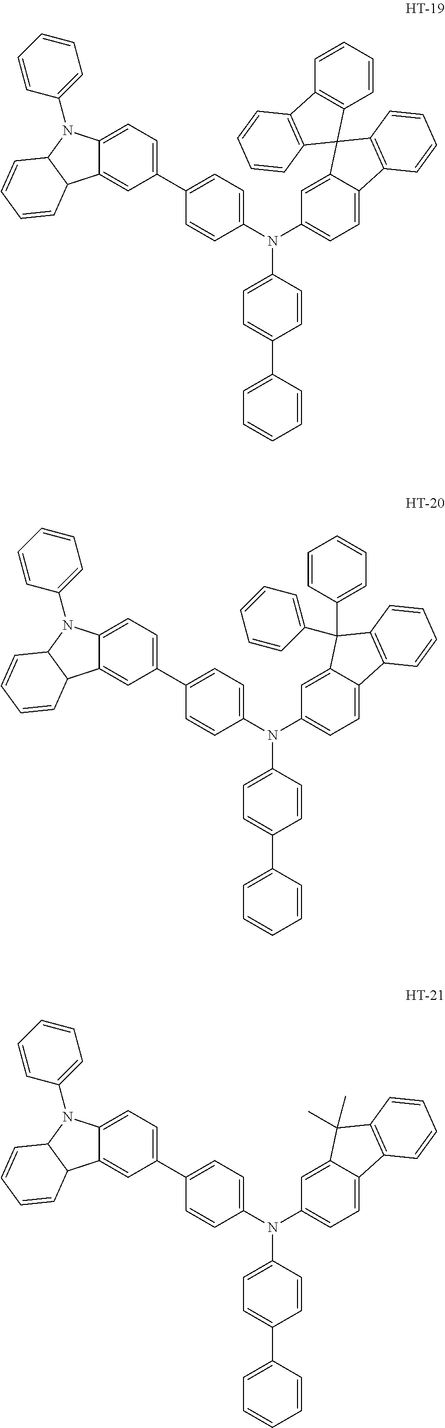 [SMILES: C1=CC2c3cc(-c4ccc(N(c5ccc(-c6ccccc6)cc5)c5ccc6c(c5)C5(c7ccccc7-c7ccccc75)c5ccccc5-6)cc4)ccc3N(c3ccccc3)C2C=C1 ; C1=CC2c3cc(-c4ccc(N(c5ccc(-c6ccccc6)cc5)c5ccc6c(c5)C(c5ccccc5)(c5ccccc5)c5ccccc5-6)cc4)ccc3N(c3ccccc3)C2C=C1 ; CC1(C)c2ccccc2-c2ccc(N(c3ccc(-c4ccccc4)cc3)c3ccc(-c4ccc5c(c4)C4C=CC=CC4N5c4ccccc4)cc3)cc21]

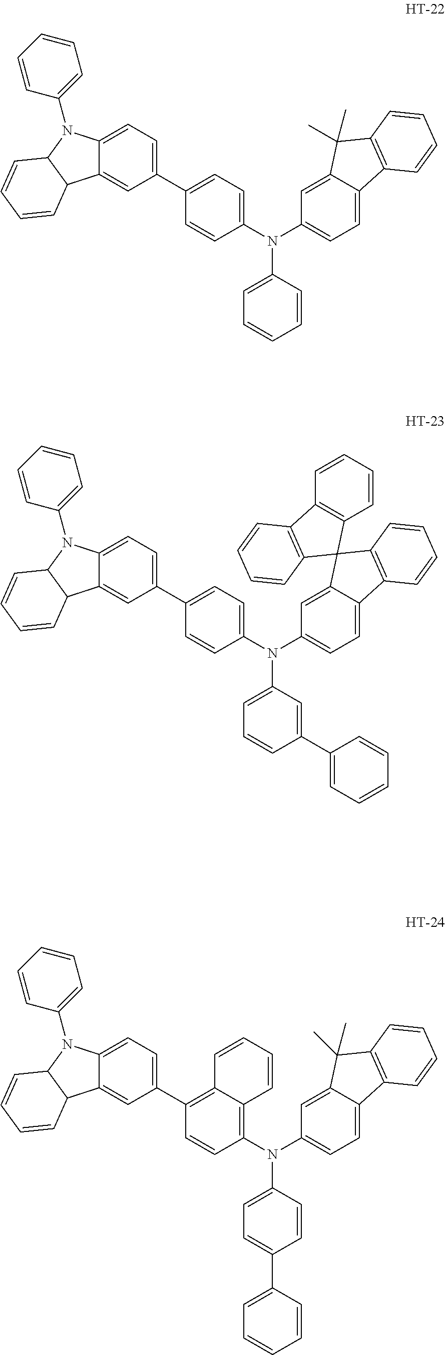 [SMILES: CC1(C)c2ccccc2-c2ccc(N(c3ccccc3)c3ccc(-c4ccc5c(c4)C4C=CC=CC4N5c4ccccc4)cc3)cc21 ; C1=CC2c3cc(-c4ccc(N(c5cccc(-c6ccccc6)c5)c5ccc6c(c5)C5(c7ccccc7-c7ccccc75)c5ccccc5-6)cc4)ccc3N(c3ccccc3)C2C=C1 ; CC1(C)c2ccccc2-c2ccc(N(c3ccc(-c4ccccc4)cc3)c3ccc(-c4ccc5c(c4)C4C=CC=CC4N5c4ccccc4)c4ccccc34)cc21]

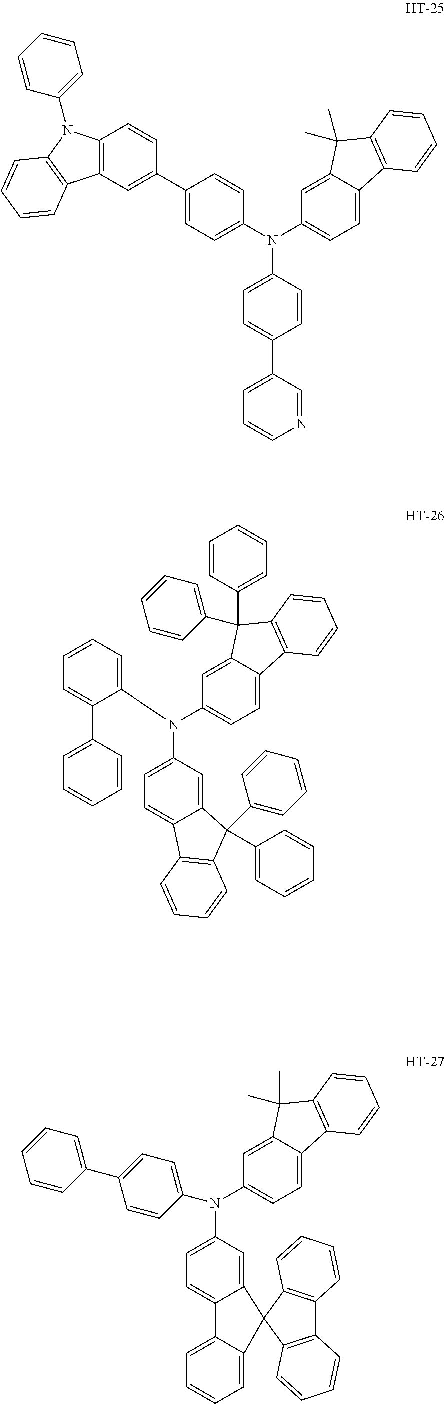 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21]

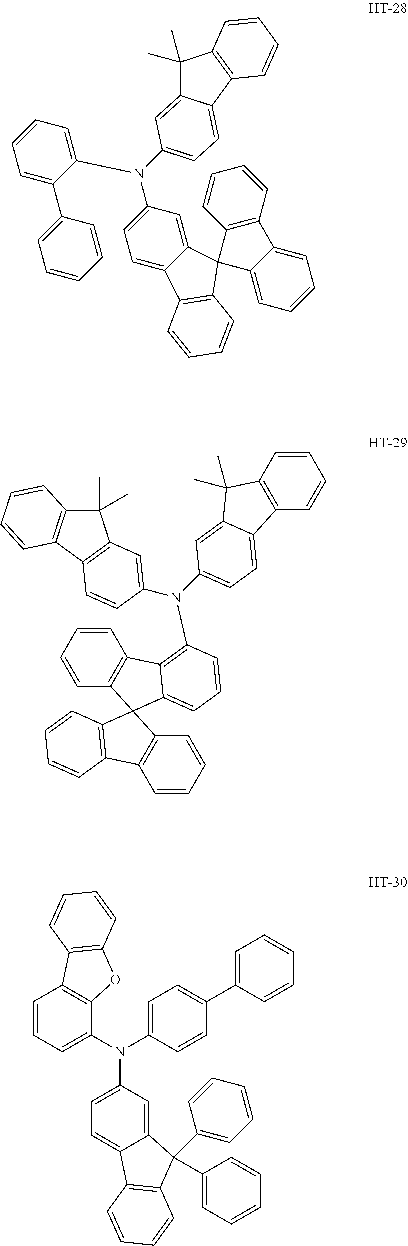 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21 ; c1ccc(-c2ccc(N(c3ccc4c(c3)C(c3ccccc3)(c3ccccc3)c3ccccc3-4)c3cccc4c3oc3ccccc34)cc2)cc1]

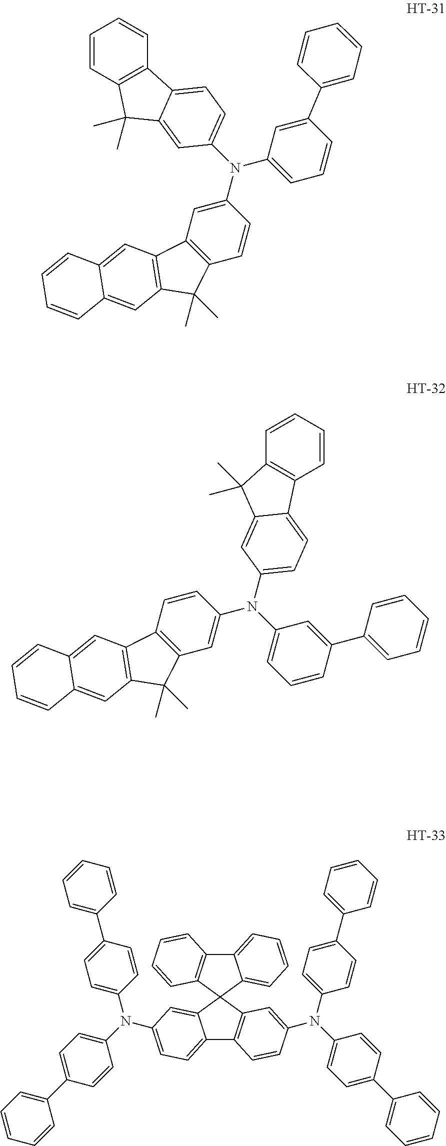 [SMILES: CC1(C)c2ccccc2-c2ccc(N(c3cccc(-c4ccccc4)c3)c3ccc4c(c3)-c3cc5ccccc5cc3C4(C)C)cc21 ; CC1(C)c2ccccc2-c2ccc(N(c3cccc(-c4ccccc4)c3)c3ccc4c(c3)C(C)(C)c3cc5ccccc5cc3-4)cc21 ; c1ccc(-c2ccc(N(c3ccc(-c4ccccc4)cc3)c3ccc4c(c3)C3(c5ccccc5-c5ccccc53)c3cc(N(c5ccc(-c6ccccc6)cc5)c5ccc(-c6ccccc6)cc5)ccc3-4)cc2)cc1]

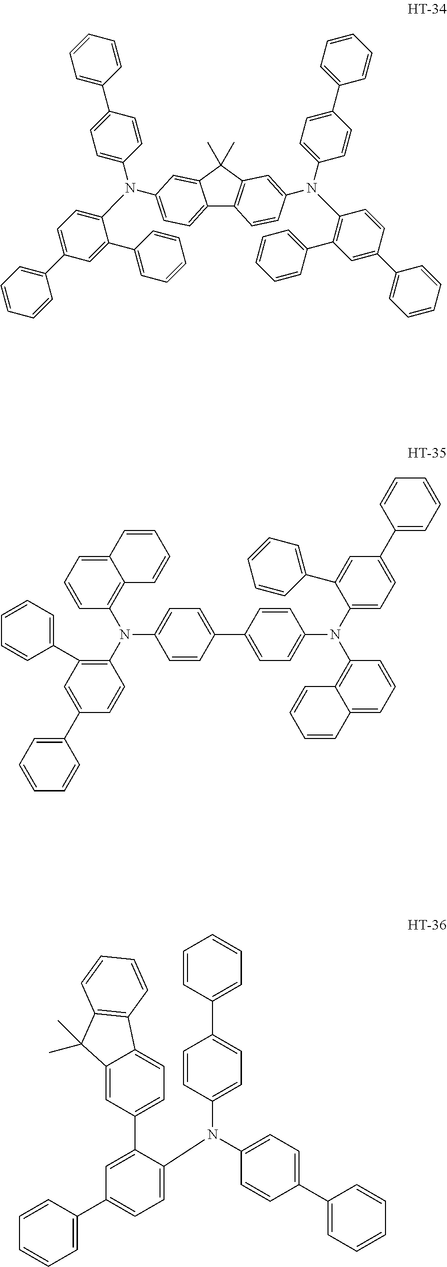 [SMILES: CC1(C)c2cc(N(c3ccc(-c4ccccc4)cc3)c3ccc(-c4ccccc4)cc3-c3ccccc3)ccc2-c2ccc(N(c3ccc(-c4ccccc4)cc3)c3ccc(-c4ccccc4)cc3-c3ccccc3)cc21 ; c1ccc(-c2ccc(N(c3ccc(-c4ccc(N(c5ccc(-c6ccccc6)cc5-c5ccccc5)c5cccc6ccccc56)cc4)cc3)c3cccc4ccccc34)c(-c3ccccc3)c2)cc1 ; CC1(C)c2ccccc2-c2ccc(-c3cc(-c4ccccc4)ccc3N(c3ccc(-c4ccccc4)cc3)c3ccc(-c4ccccc4)cc3)cc21]

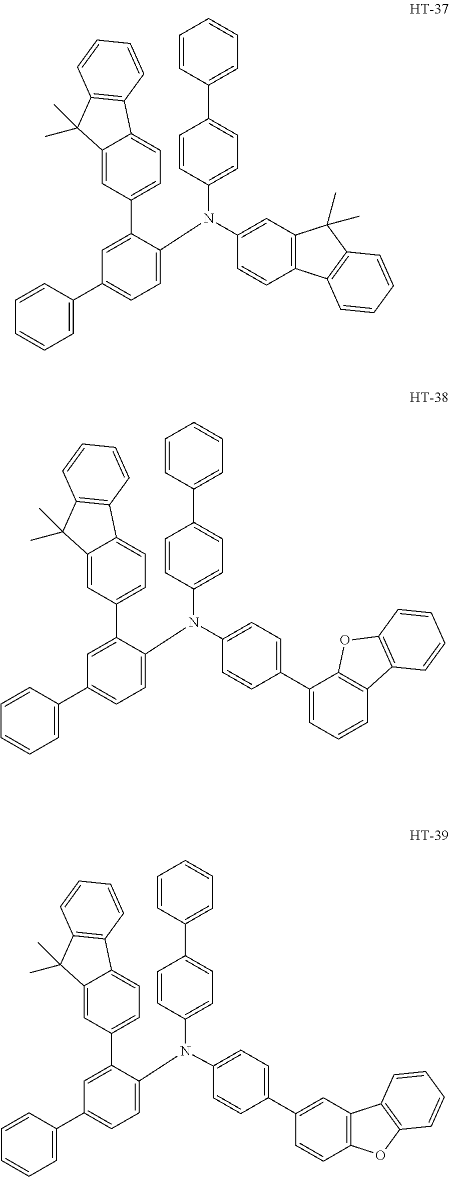 [SMILES: CC1(C)c2ccccc2-c2ccc(-c3cc(-c4ccccc4)ccc3N(c3ccc(-c4ccccc4)cc3)c3ccc4c(c3)C(C)(C)c3ccccc3-4)cc21 ; CC1(C)c2ccccc2-c2ccc(-c3cc(-c4ccccc4)ccc3N(c3ccc(-c4ccccc4)cc3)c3ccc(-c4cccc5c4oc4ccccc45)cc3)cc21 ; CC1(C)c2ccccc2-c2ccc(-c3cc(-c4ccccc4)ccc3N(c3ccc(-c4ccccc4)cc3)c3ccc(-c4ccc5oc6ccccc6c5c4)cc3)cc21]

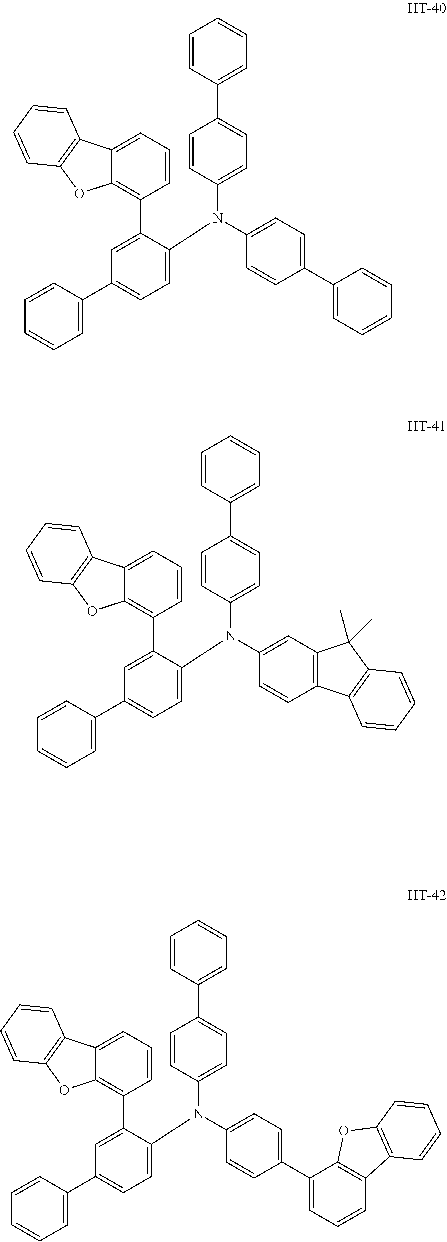 [SMILES: c1ccc(-c2ccc(N(c3ccc(-c4ccccc4)cc3)c3ccc(-c4ccccc4)cc3-c3cccc4c3oc3ccccc34)cc2)cc1 ; CC1(C)c2ccccc2-c2ccc(N(c3ccc(-c4ccccc4)cc3)c3ccc(-c4ccccc4)cc3-c3cccc4c3oc3ccccc34)cc21 ; c1ccc(-c2ccc(N(c3ccc(-c4cccc5c4oc4ccccc45)cc3)c3ccc(-c4ccccc4)cc3-c3cccc4c3oc3ccccc34)cc2)cc1]

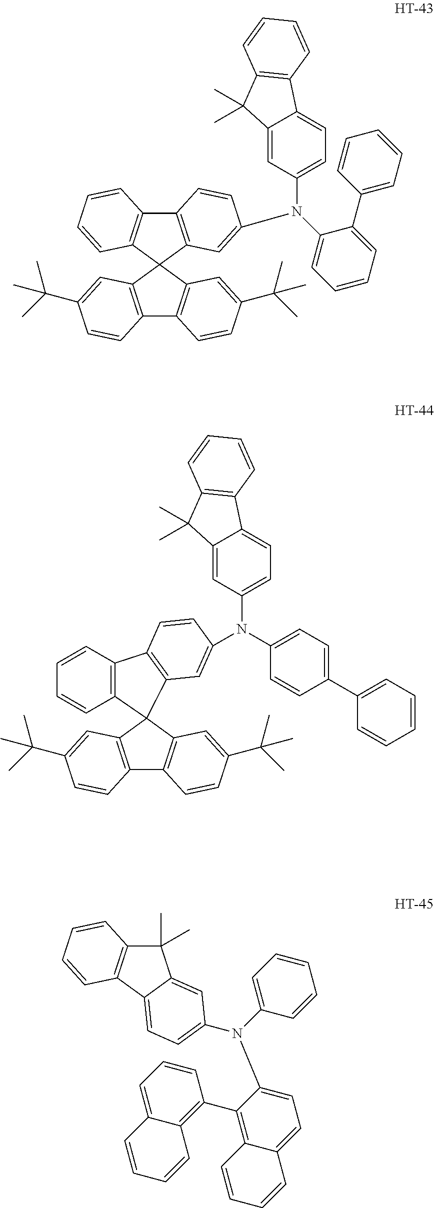 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5ccccc5)cc4)c4ccc5c(c4)C(C)(C)c4ccccc4-5)cc31)c1cc(C(C)(C)C)ccc1-2 ; CC1(C)c2ccccc2-c2ccc(N(c3ccccc3)c3ccc4ccccc4c3-c3cccc4ccccc34)cc21]

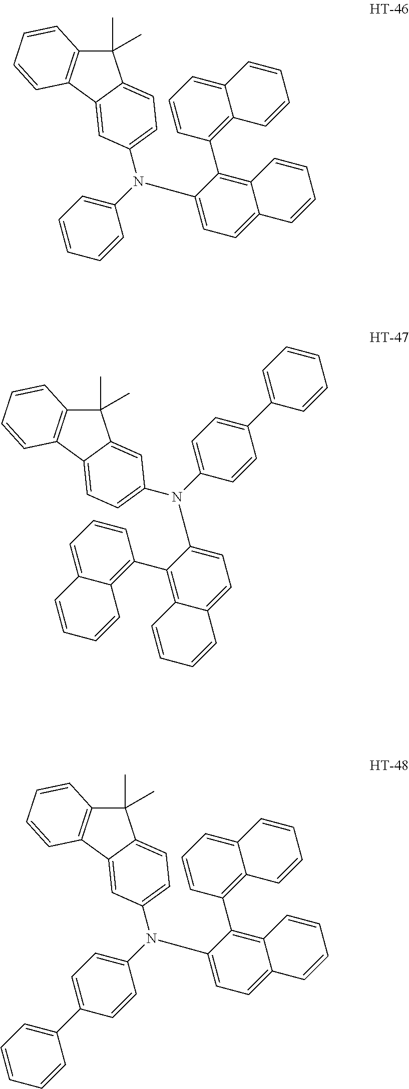 [SMILES: CC1(C)c2ccccc2-c2cc(N(c3ccccc3)c3ccc4ccccc4c3-c3cccc4ccccc34)ccc21 ; CC1(C)c2ccccc2-c2ccc(N(c3ccc(-c4ccccc4)cc3)c3ccc4ccccc4c3-c3cccc4ccccc34)cc21 ; CC1(C)c2ccccc2-c2cc(N(c3ccc(-c4ccccc4)cc3)c3ccc4ccccc4c3-c3cccc4ccccc34)ccc21]

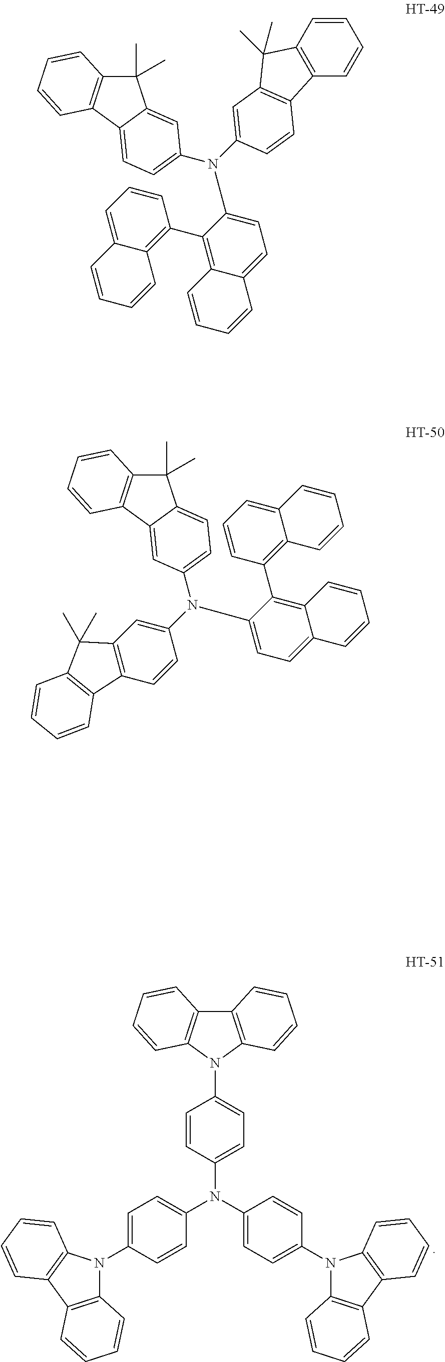 [SMILES: CC1(C)c2ccccc2-c2ccc(N(c3ccc4c(c3)C(C)(C)c3ccccc3-4)c3ccc4ccccc4c3-c3cccc4ccccc34)cc21 ; CC1(C)c2ccccc2-c2cc(N(c3ccc4c(c3)C(C)(C)c3ccccc3-4)c3ccc4ccccc4c3-c3cccc4ccccc34)ccc21 ; c1ccc2c(c1)c1ccccc1n2-c1ccc(N(c2ccc(-n3c4ccccc4c4ccccc43)cc2)c2ccc(-n3c4ccccc4c4ccccc43)cc2)cc1]

In an alternative embodiment, the electron blocking material may also be selected from any one or a combination of at least two of compounds EB-1 to EB-13 (for example, a combination of EB-3 and EB-2 or a combination of EB-6, EB-8 and EB-13):

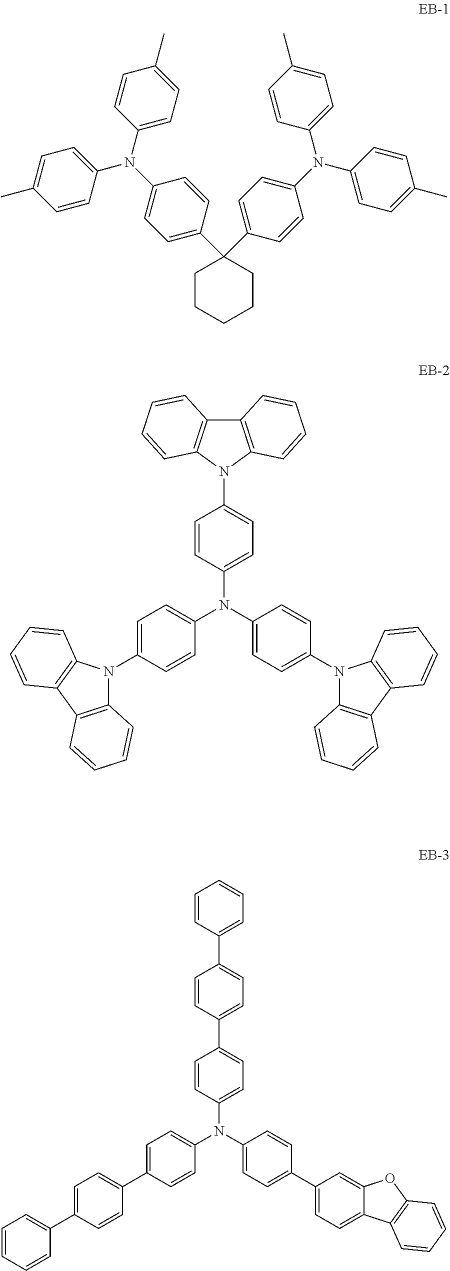

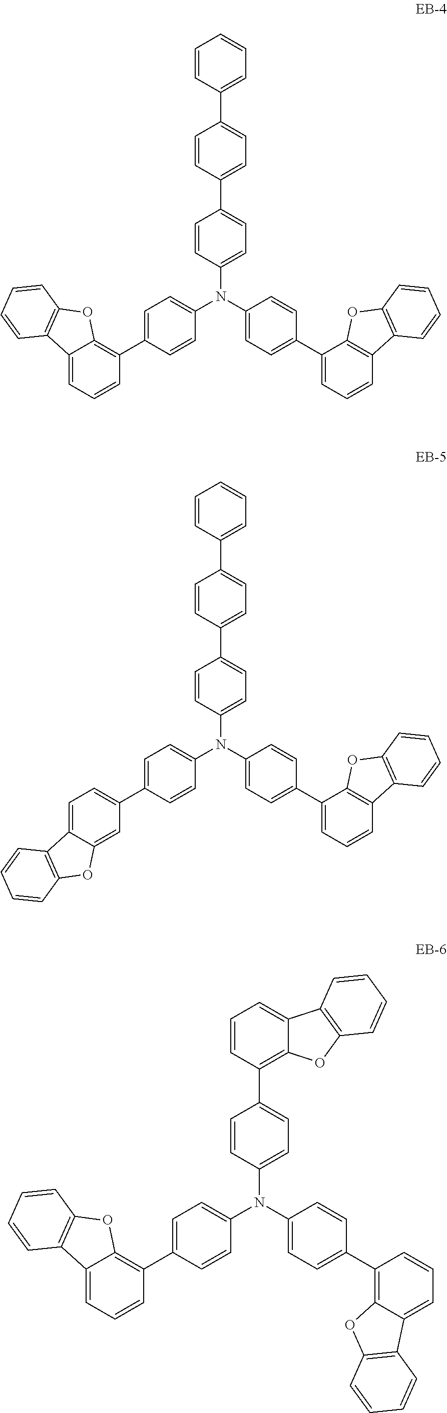 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; c1ccc(-c2ccc(-c3ccc(N(c4ccc(-c5ccc6c(c5)oc5ccccc56)cc4)c4ccc(-c5cccc6c5oc5ccccc56)cc4)cc3)cc2)cc1 ; c1ccc2c(c1)oc1c(-c3ccc(N(c4ccc(-c5cccc6c5oc5ccccc56)cc4)c4ccc(-c5cccc6c5oc5ccccc56)cc4)cc3)cccc12]

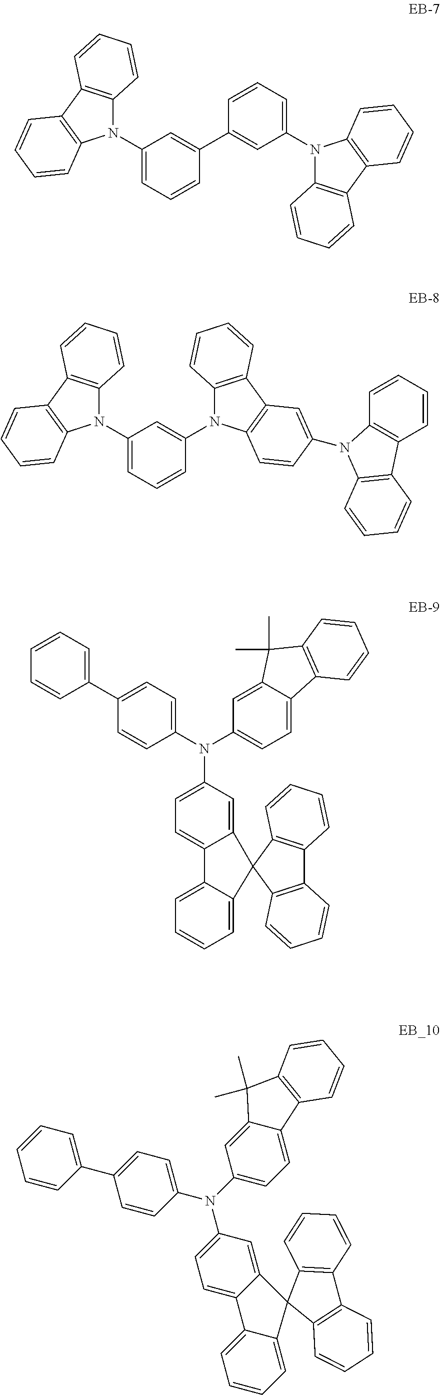 [SMILES: c1cc(-c2cccc(-n3c4ccccc4c4ccccc43)c2)cc(-n2c3ccccc3c3ccccc32)c1 ; c1cc(-n2c3ccccc3c3ccccc32)cc(-n2c3ccccc3c3cc(-n4c5ccccc5c5ccccc54)ccc32)c1 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21]

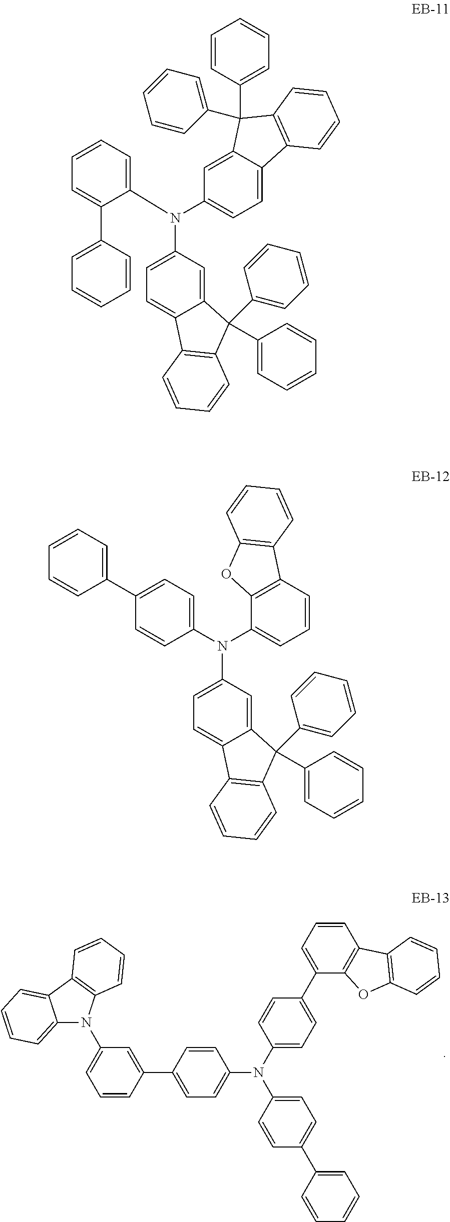 [SMILES: c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1 ; c1ccc(-c2ccc(N(c3ccc4c(c3)C(c3ccccc3)(c3ccccc3)c3ccccc3-4)c3cccc4c3oc3ccccc34)cc2)cc1 ; c1ccc(-c2ccc(N(c3ccc(-c4cccc(-n5c6ccccc6c6ccccc65)c4)cc3)c3ccc(-c4cccc5c4oc4ccccc45)cc3)cc2)cc1]

The hole injection layer is located between the anode and the hole transport layer. The material of the hole injection layer may be a single compound or a combination of multiple compounds. For example, the hole injection layer may use one or more of the compounds HT-1 to HT-34 above, one or a combination of at least two of HI-1 to HI-3 below, or one or a combination of at least two of HT-1 to HT-34 doping one or a combination of at least two of HI-1 to HI-3 (for example, a combination of HI-1 and HI-2) below.

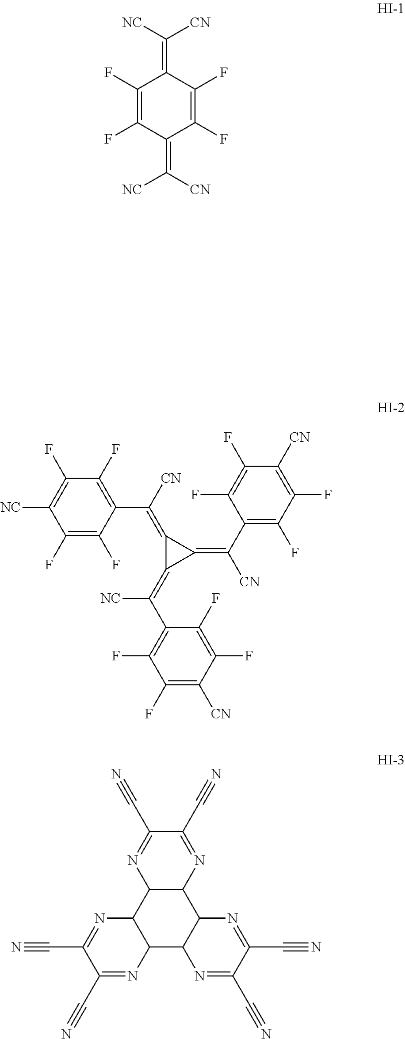 [SMILES: N#CC(C#N)=c1c(F)c(F)c(=C(C#N)C#N)c(F)c1F ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC1=NC2C3N=C(C#N)C(C#N)=NC3C3N=C(C#N)C(C#N)=NC3C2N=C1C#N]

The electron transport region may be an electron transport layer with a single-layer structure and includes a single-layer electron transport layer containing only one compound and a single-layer electron transport layer containing multiple compounds. The electron transport region may also be a multi-layer structure including at least two of an electron injection layer (EIL), an electron transport layer (ETL) and a hole blocking layer (HBL).

In an alternative embodiment, the electron transport material is selected from any one or a combination of at least two of compounds ET-1 to ET-65 (for example, a combination of ET-1 and ET-2, a combination of ET-5, ET-10 and ET-16 or a combination of ET-3, ET-30, ET-27 and ET-57):

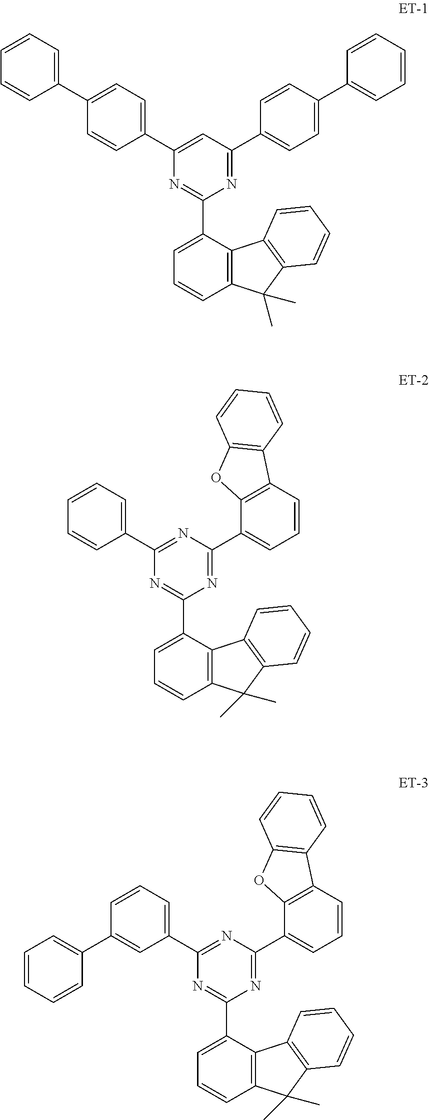 [SMILES: CC1(C)c2ccccc2-c2c(-c3nc(-c4ccc(-c5ccccc5)cc4)cc(-c4ccc(-c5ccccc5)cc4)n3)cccc21 ; CC1(C)c2ccccc2-c2c(-c3nc(-c4ccccc4)nc(-c4cccc5c4oc4ccccc45)n3)cccc21 ; CC1(C)c2ccccc2-c2c(-c3nc(-c4cccc(-c5ccccc5)c4)nc(-c4cccc5c4oc4ccccc45)n3)cccc21]

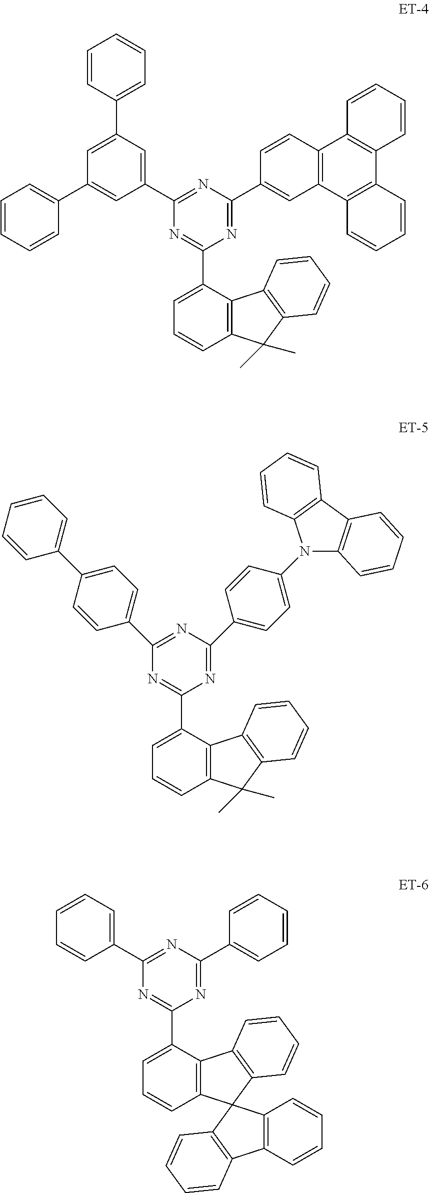 [SMILES: CC1(C)c2ccccc2-c2c(-c3nc(-c4cc(-c5ccccc5)cc(-c5ccccc5)c4)nc(-c4ccc5c6ccccc6c6ccccc6c5c4)n3)cccc21 ; CC1(C)c2ccccc2-c2c(-c3nc(-c4ccc(-c5ccccc5)cc4)nc(-c4ccc(-n5c6ccccc6c6ccccc65)cc4)n3)cccc21 ; c1ccc(-c2nc(-c3ccccc3)nc(-c3cccc4c3-c3ccccc3C43c4ccccc4-c4ccccc43)n2)cc1]

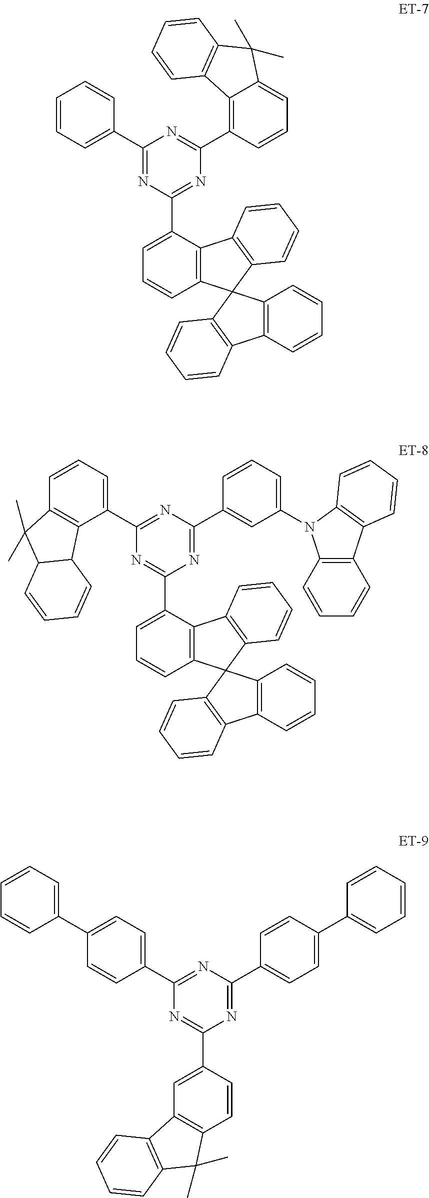 [SMILES: CC1(C)c2ccccc2-c2c(-c3nc(-c4ccccc4)nc(-c4cccc5c4-c4ccccc4C54c5ccccc5-c5ccccc54)n3)cccc21 ; CC1(C)c2cccc(-c3nc(-c4cccc(-n5c6ccccc6c6ccccc65)c4)nc(-c4cccc5c4-c4ccccc4C54c5ccccc5-c5ccccc54)n3)c2C2C=CC=CC21 ; CC1(C)c2ccccc2-c2cc(-c3nc(-c4ccc(-c5ccccc5)cc4)nc(-c4ccc(-c5ccccc5)cc4)n3)ccc21]

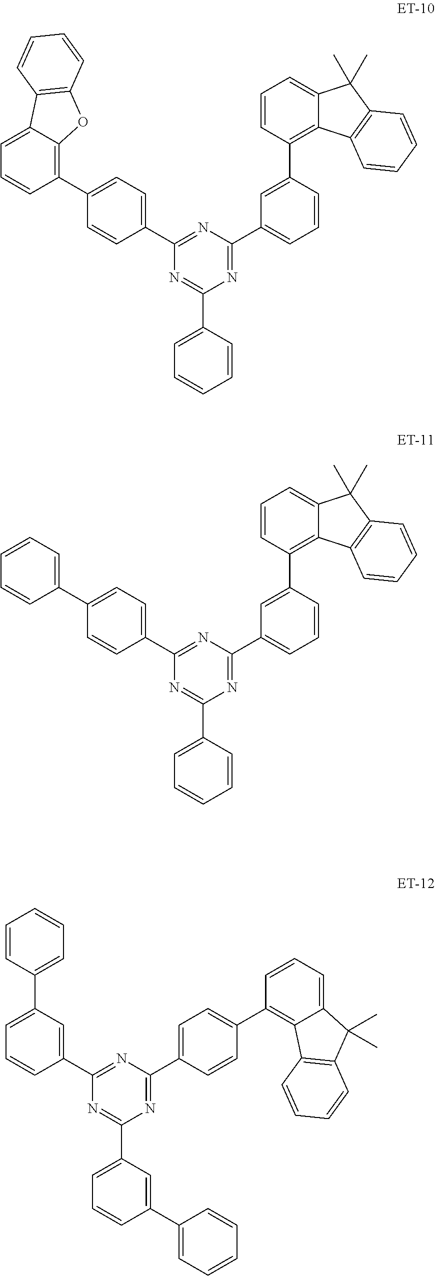 [SMILES: CC1(C)c2ccccc2-c2c(-c3cccc(-c4nc(-c5ccccc5)nc(-c5ccc(-c6cccc7c6oc6ccccc67)cc5)n4)c3)cccc21 ; CC1(C)c2ccccc2-c2c(-c3cccc(-c4nc(-c5ccccc5)nc(-c5ccc(-c6ccccc6)cc5)n4)c3)cccc21 ; CC1(C)c2ccccc2-c2c(-c3ccc(-c4nc(-c5cccc(-c6ccccc6)c5)nc(-c5cccc(-c6ccccc6)c5)n4)cc3)cccc21]

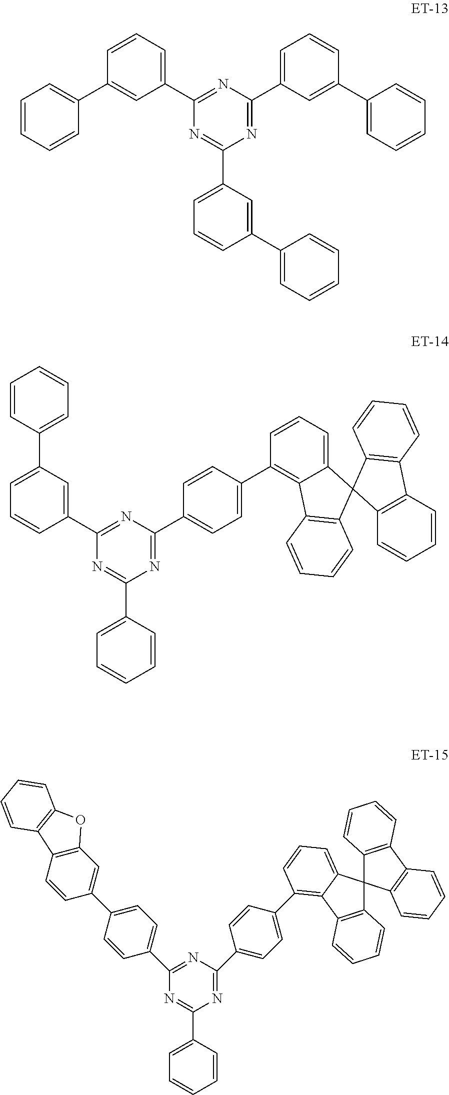 [SMILES: c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4ccccc4)nc(-c4ccc(-c5cccc6c5-c5ccccc5C65c6ccccc6-c6ccccc65)cc4)n3)c2)cc1 ; c1ccc(-c2nc(-c3ccc(-c4ccc5c(c4)oc4ccccc45)cc3)nc(-c3ccc(-c4cccc5c4-c4ccccc4C54c5ccccc5-c5ccccc54)cc3)n2)cc1]

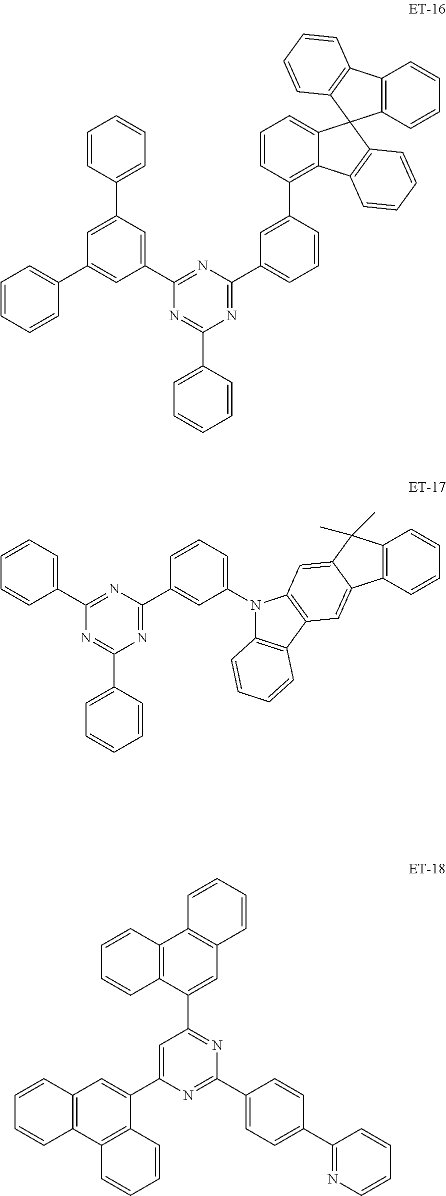 [SMILES: c1ccc(-c2cc(-c3ccccc3)cc(-c3nc(-c4ccccc4)nc(-c4cccc(-c5cccc6c5-c5ccccc5C65c6ccccc6-c6ccccc65)c4)n3)c2)cc1 ; CC1(C)c2ccccc2-c2cc3c4ccccc4n(-c4cccc(-c5nc(-c6ccccc6)nc(-c6ccccc6)n5)c4)c3cc21 ; c1ccc(-c2ccc(-c3nc(-c4cc5ccccc5c5ccccc45)cc(-c4cc5ccccc5c5ccccc45)n3)cc2)nc1]

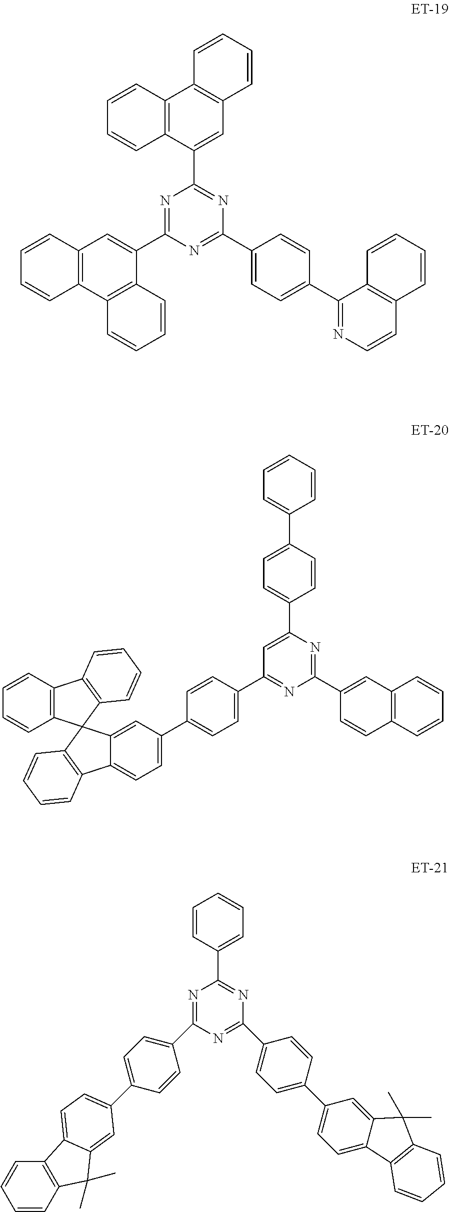 [SMILES: c1ccc2c(-c3ccc(-c4nc(-c5cc6ccccc6c6ccccc56)nc(-c5cc6ccccc6c6ccccc56)n4)cc3)nccc2c1 ; c1ccc(-c2ccc(-c3cc(-c4ccc(-c5ccc6c(c5)C5(c7ccccc7-c7ccccc75)c5ccccc5-6)cc4)nc(-c4ccc5ccccc5c4)n3)cc2)cc1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

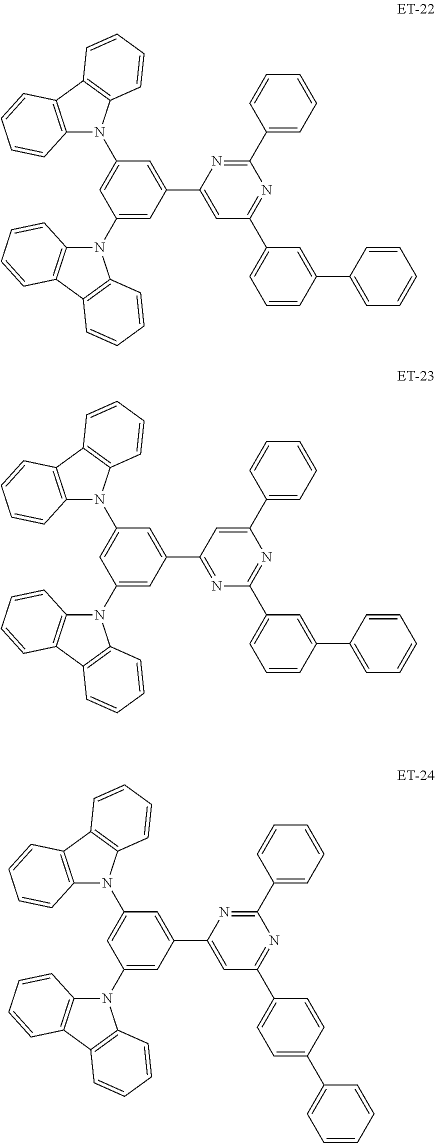 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2cccc(-c3nc(-c4ccccc4)cc(-c4cc(-n5c6ccccc6c6ccccc65)cc(-n5c6ccccc6c6ccccc65)c4)n3)c2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

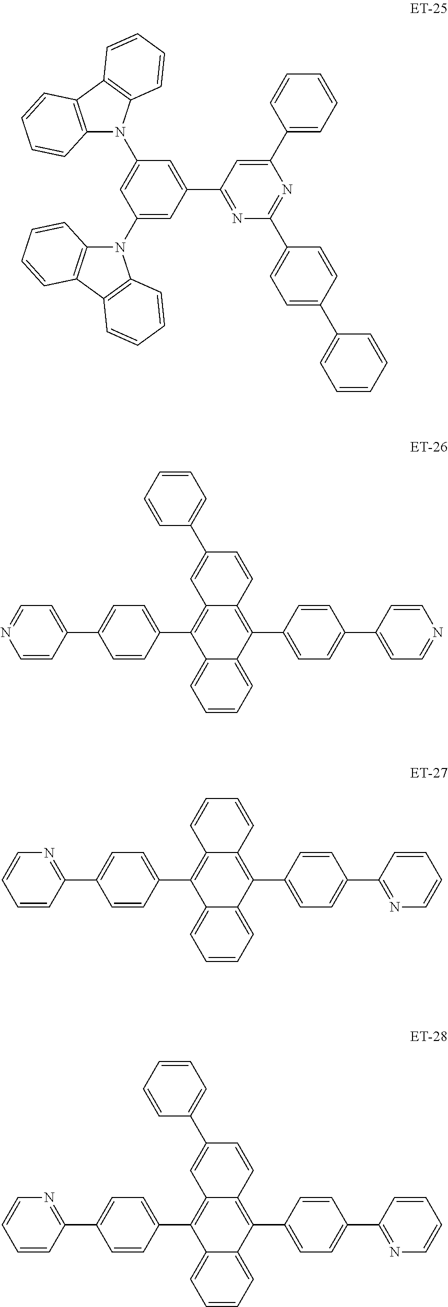 [SMILES: c1ccc(-c2ccc(-c3nc(-c4ccccc4)cc(-c4cc(-n5c6ccccc6c6ccccc65)cc(-n5c6ccccc6c6ccccc65)c4)n3)cc2)cc1 ; c1ccc(-c2ccc3c(-c4ccc(-c5ccncc5)cc4)c4ccccc4c(-c4ccc(-c5ccncc5)cc4)c3c2)cc1 ; c1ccc(-c2ccc(-c3c4ccccc4c(-c4ccc(-c5ccccn5)cc4)c4ccccc34)cc2)nc1 ; c1ccc(-c2ccc3c(-c4ccc(-c5ccccn5)cc4)c4ccccc4c(-c4ccc(-c5ccccn5)cc4)c3c2)cc1]

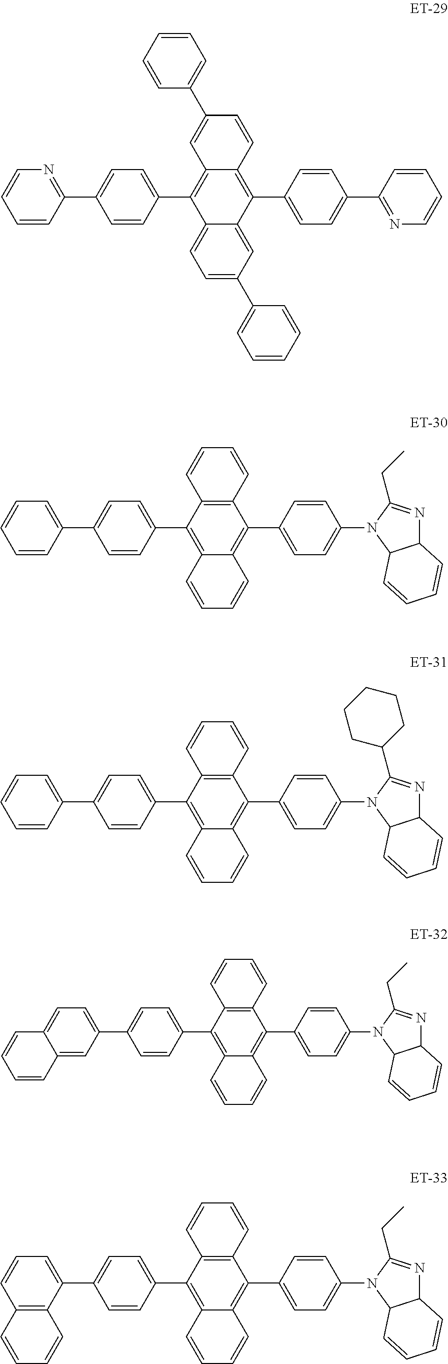 [SMILES: c1ccc(-c2ccc3c(-c4ccc(-c5ccccn5)cc4)c4cc(-c5ccccc5)ccc4c(-c4ccc(-c5ccccn5)cc4)c3c2)cc1 ; CCC1=NC2C=CC=CC2N1c1ccc(-c2c3ccccc3c(-c3ccc(-c4ccccc4)cc3)c3ccccc23)cc1 ; C1=CC2N=C(C3CCCCC3)N(c3ccc(-c4c5ccccc5c(-c5ccc(-c6ccccc6)cc5)c5ccccc45)cc3)C2C=C1 ; CCC1=NC2C=CC=CC2N1c1ccc(-c2c3ccccc3c(-c3ccc(-c4ccc5ccccc5c4)cc3)c3ccccc23)cc1 ; CCC1=NC2C=CC=CC2N1c1ccc(-c2c3ccccc3c(-c3ccc(-c4cccc5ccccc45)cc3)c3ccccc23)cc1]

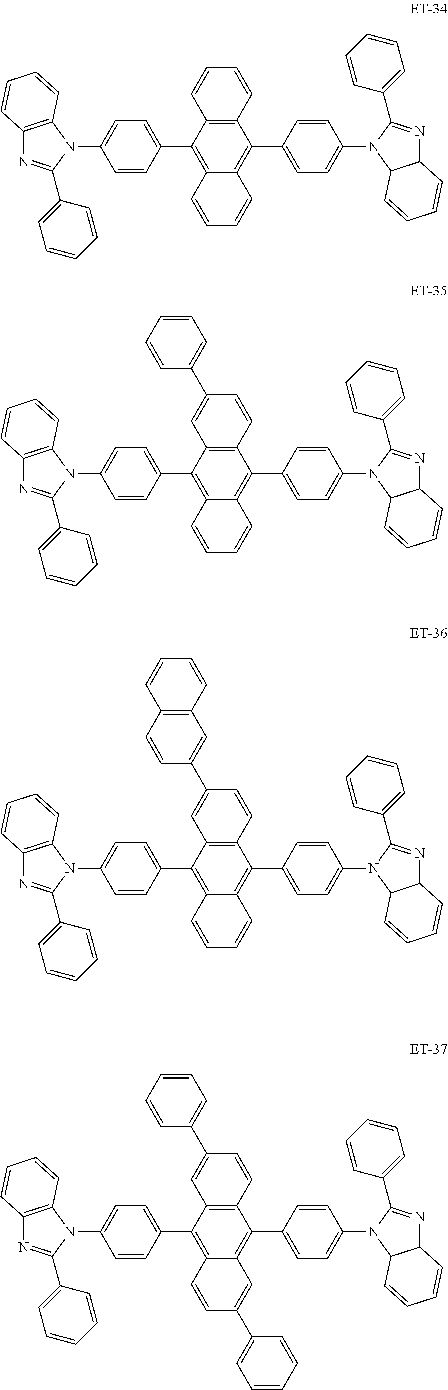 [SMILES: C1=CC2N=C(c3ccccc3)N(c3ccc(-c4c5ccccc5c(-c5ccc(-n6c(-c7ccccc7)nc7ccccc76)cc5)c5ccccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccccc6)ccc45)cc3)C2C=C1 ; C1=CC2N=C(c3ccccc3)N(c3ccc(-c4c5ccccc5c(-c5ccc(-n6c(-c7ccccc7)nc7ccccc76)cc5)c5cc(-c6ccc7ccccc7c6)ccc45)cc3)C2C=C1 ; C1=CC2N=C(c3ccccc3)N(c3ccc(-c4c5ccc(-c6ccccc6)cc5c(-c5ccc(-n6c(-c7ccccc7)nc7ccccc76)cc5)c5ccc(-c6ccccc6)cc45)cc3)C2C=C1]

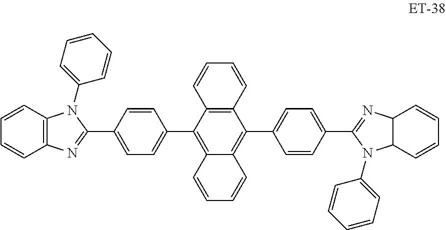 [SMILES: C1=CC2N=C(c3ccc(-c4c5ccccc5c(-c5ccc(-c6nc7ccccc7n6-c6ccccc6)cc5)c5ccccc45)cc3)N(c3ccccc3)C2C=C1]

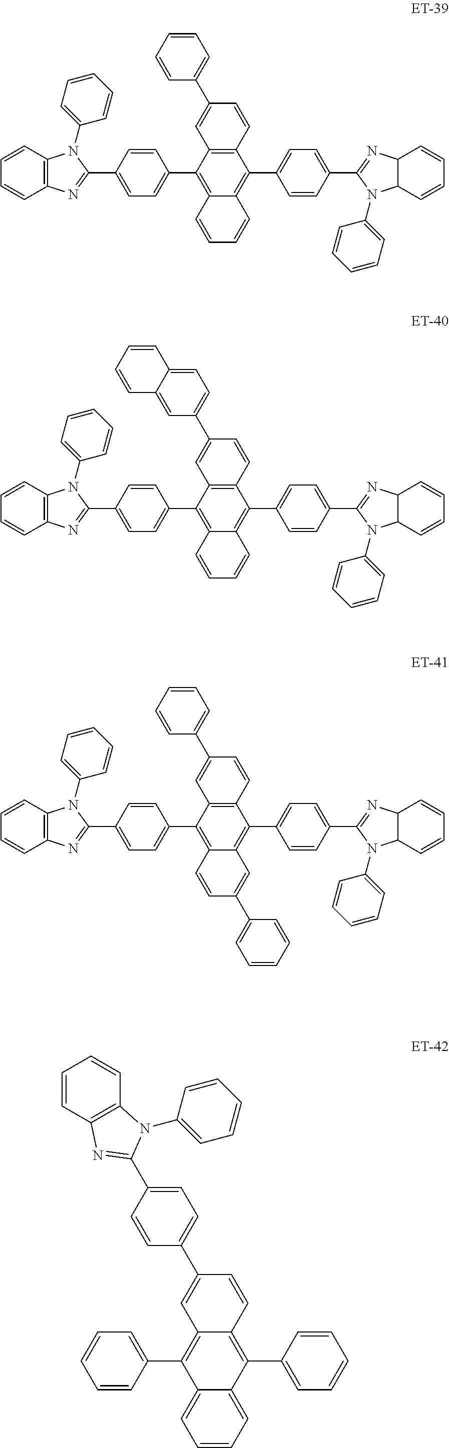 [SMILES: C1=CC2N=C(c3ccc(-c4c5ccccc5c(-c5ccc(-c6nc7ccccc7n6-c6ccccc6)cc5)c5cc(-c6ccccc6)ccc45)cc3)N(c3ccccc3)C2C=C1 ; C1=CC2N=C(c3ccc(-c4c5ccccc5c(-c5ccc(-c6nc7ccccc7n6-c6ccccc6)cc5)c5cc(-c6ccc7ccccc7c6)ccc45)cc3)N(c3ccccc3)C2C=C1 ; C1=CC2N=C(c3ccc(-c4c5ccc(-c6ccccc6)cc5c(-c5ccc(-c6nc7ccccc7n6-c6ccccc6)cc5)c5ccc(-c6ccccc6)cc45)cc3)N(c3ccccc3)C2C=C1 ; c1ccc(-c2c3ccccc3c(-c3ccccc3)c3cc(-c4ccc(-c5nc6ccccc6n5-c5ccccc5)cc4)ccc23)cc1]

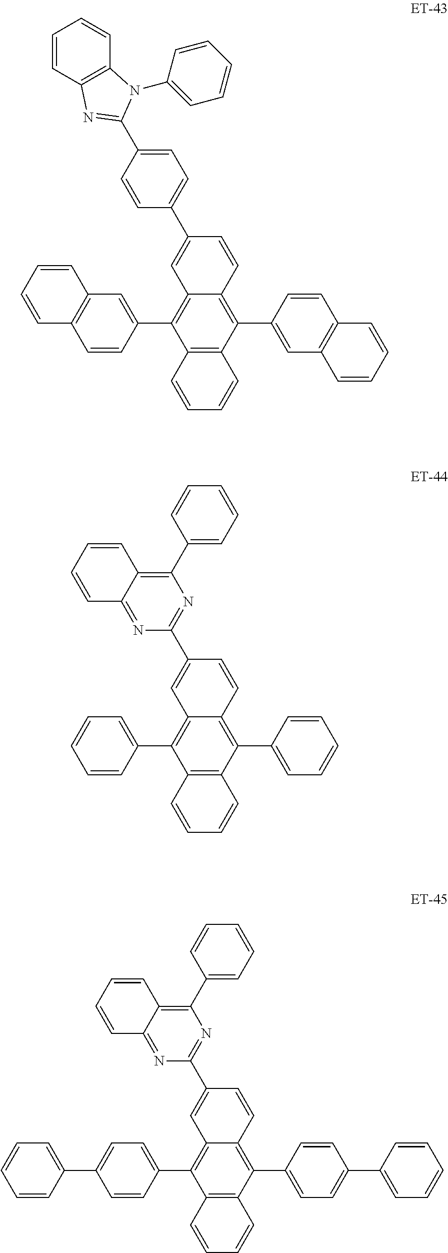 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2nc(-c3ccc4c(-c5ccccc5)c5ccccc5c(-c5ccccc5)c4c3)nc3ccccc23)cc1 ; c1ccc(-c2ccc(-c3c4ccccc4c(-c4ccc(-c5ccccc5)cc4)c4cc(-c5nc(-c6ccccc6)c6ccccc6n5)ccc34)cc2)cc1]

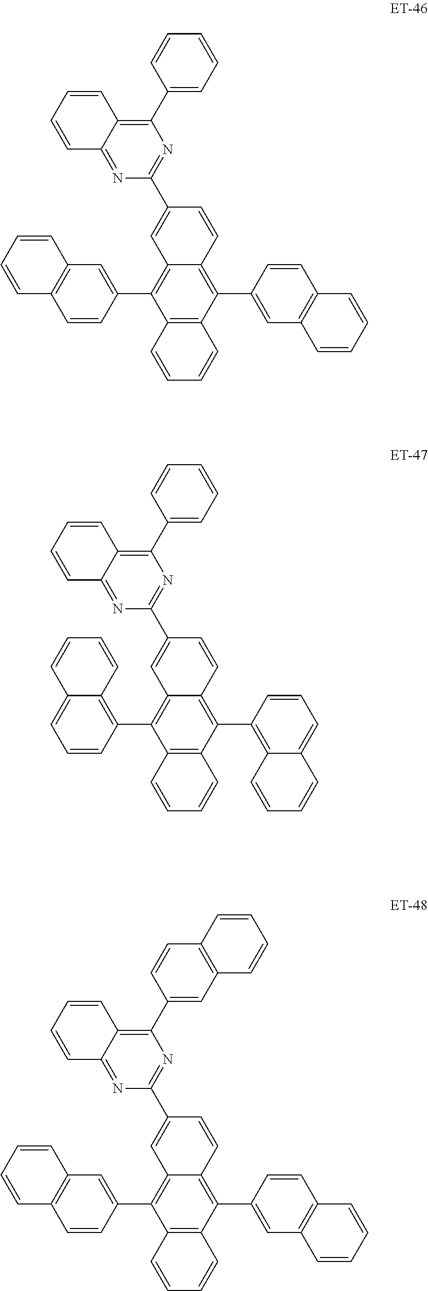 [SMILES: c1ccc(-c2nc(-c3ccc4c(-c5ccc6ccccc6c5)c5ccccc5c(-c5ccc6ccccc6c5)c4c3)nc3ccccc23)cc1 ; c1ccc(-c2nc(-c3ccc4c(-c5cccc6ccccc56)c5ccccc5c(-c5cccc6ccccc56)c4c3)nc3ccccc23)cc1 ; c1ccc2cc(-c3nc(-c4ccc5c(-c6ccc7ccccc7c6)c6ccccc6c(-c6ccc7ccccc7c6)c5c4)nc4ccccc34)ccc2c1]

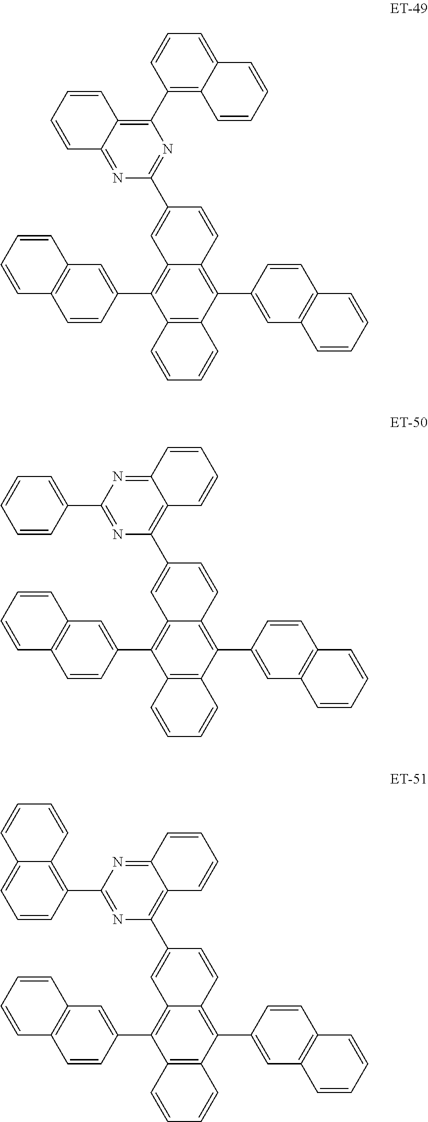 [SMILES: c1ccc2cc(-c3c4ccccc4c(-c4ccc5ccccc5c4)c4cc(-c5nc(-c6cccc7ccccc67)c6ccccc6n5)ccc34)ccc2c1 ; c1ccc(-c2nc(-c3ccc4c(-c5ccc6ccccc6c5)c5ccccc5c(-c5ccc6ccccc6c5)c4c3)c3ccccc3n2)cc1 ; c1ccc2cc(-c3c4ccccc4c(-c4ccc5ccccc5c4)c4cc(-c5nc(-c6cccc7ccccc67)nc6ccccc56)ccc34)ccc2c1]

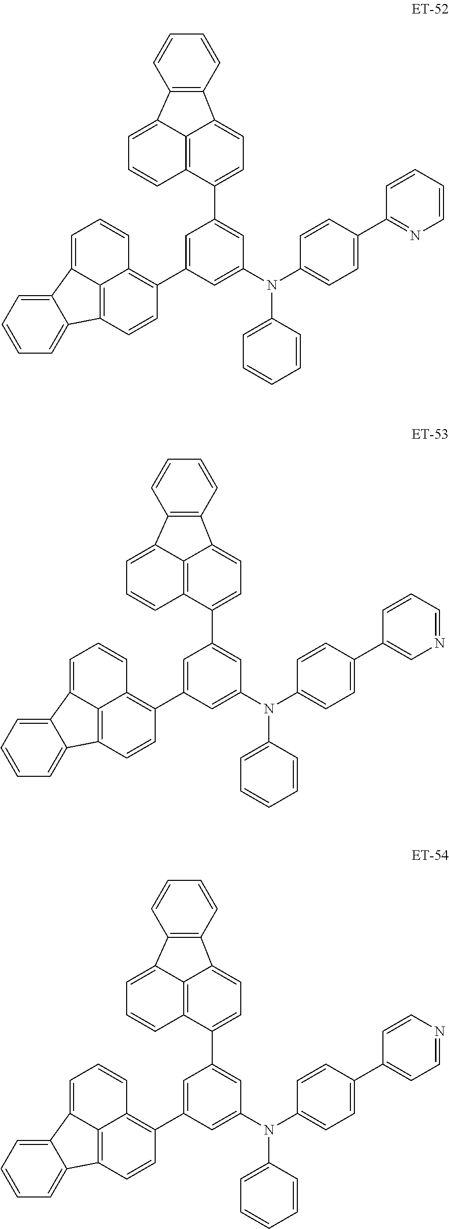 [SMILES: c1ccc(N(c2ccc(-c3ccccn3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3cccnc3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3ccncc3)cc2)c2cc(-c3ccc4c5c(cccc35)-c3ccccc3-4)cc(-c3ccc4c5c(cccc35)-c3ccccc3-4)c2)cc1]

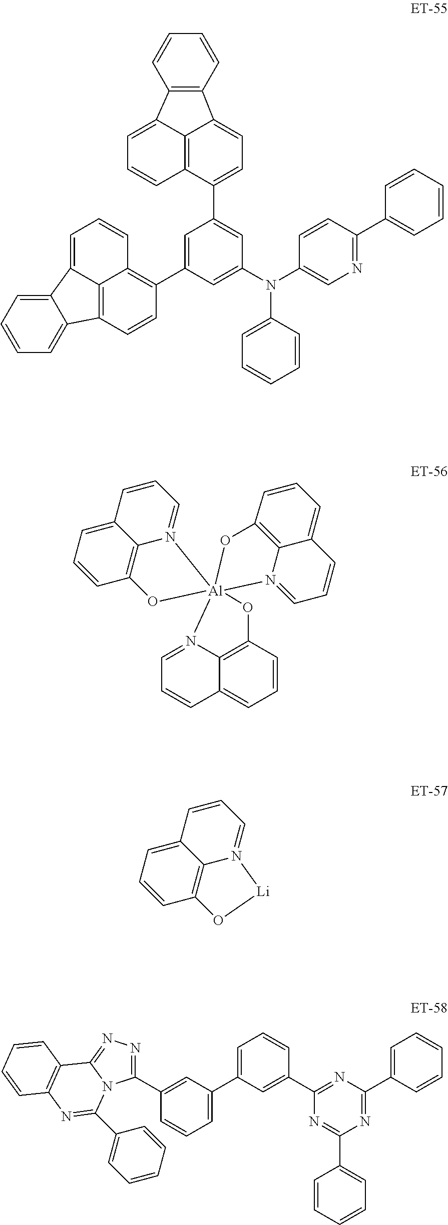

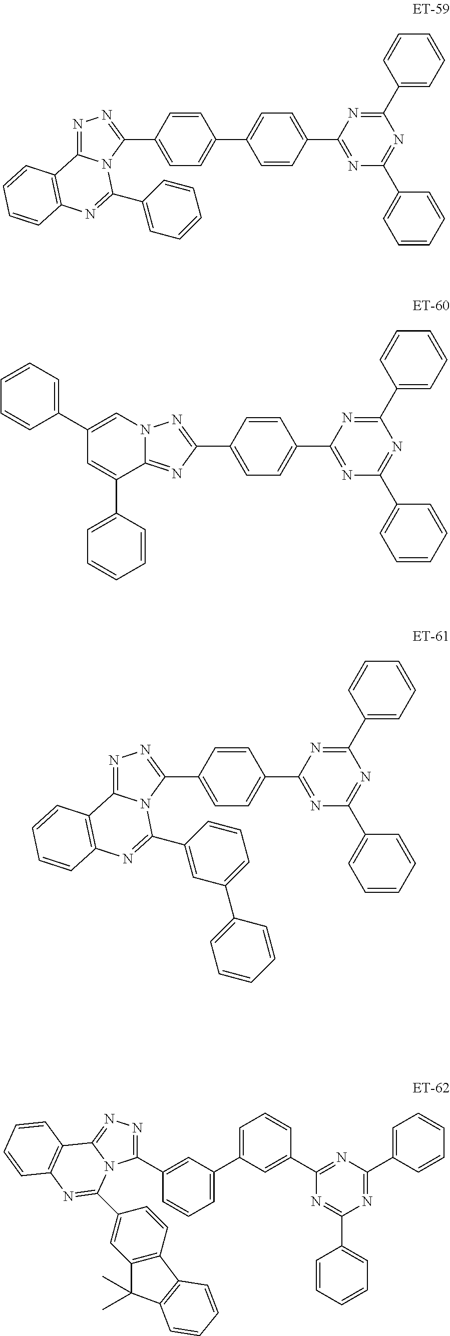 [SMILES: c1ccc(-c2nc(-c3ccccc3)nc(-c3ccc(-c4ccc(-c5nnc6c7ccccc7nc(-c7ccccc7)n56)cc4)cc3)n2)cc1 ; c1ccc(-c2cc(-c3ccccc3)c3nc(-c4ccc(-c5nc(-c6ccccc6)nc(-c6ccccc6)n5)cc4)nn3c2)cc1 ; c1ccc(-c2cccc(-c3nc4ccccc4c4nnc(-c5ccc(-c6nc(-c7ccccc7)nc(-c7ccccc7)n6)cc5)n34)c2)cc1 ; CC1(C)c2ccccc2-c2ccc(-c3nc4ccccc4c4nnc(-c5cccc(-c6cccc(-c7nc(-c8ccccc8)nc(-c8ccccc8)n7)c6)c5)n34)cc21]

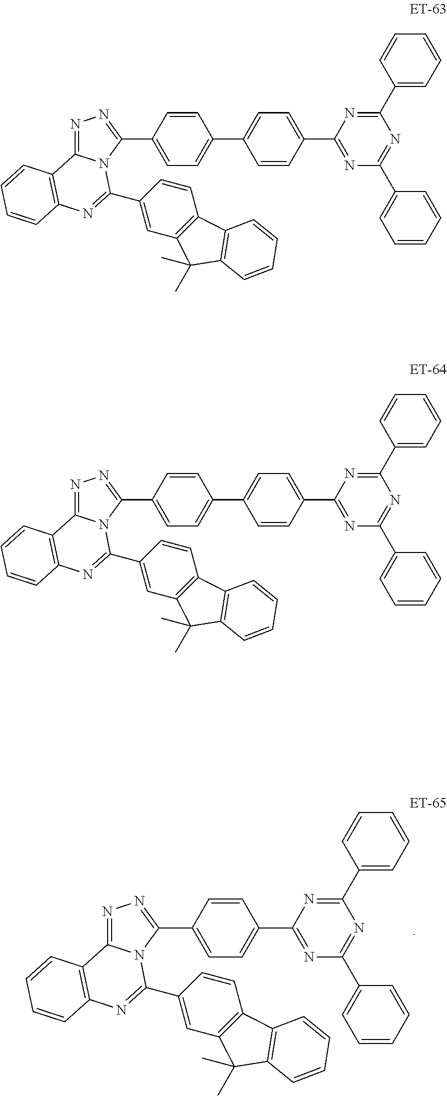 [SMILES: CC1(C)c2ccccc2-c2ccc(-c3nc4ccccc4c4nnc(-c5ccc(-c6ccc(-c7nc(-c8ccccc8)nc(-c8ccccc8)n7)cc6)cc5)n34)cc21 ; CC1(C)c2ccccc2-c2ccc(-c3nc4ccccc4c4nnc(-c5ccc(-c6ccc(-c7nc(-c8ccccc8)nc(-c8ccccc8)n7)cc6)cc5)n34)cc21 ; CC1(C)c2ccccc2-c2ccc(-c3nc4ccccc4c4nnc(-c5ccc(-c6nc(-c7ccccc7)nc(-c7ccccc7)n6)cc5)n34)cc21]

The hole blocking layer (HBL) is located between the electron transport layer and the light-emitting layer. The hole blocking layer may use, but is not limited to, one or more of the compounds ET-1 to ET-65 above (for example, a combination of ET-4 and ET-7, a combination of ET-6, ET-14 and ET-18 and a combination of ET-20, ET-50, ET-3 and ET-59).

In an alternative embodiment, the material of the hole blocking layer may be selected from any one or a combination of at least two of compounds HB-1 to HB-6 (for example, a combination of HB-1 and HB-2, a combination of HB-5, HB-6 and HB-4 and a combination of HB-1, HB-3, HB-4 and HB-6):

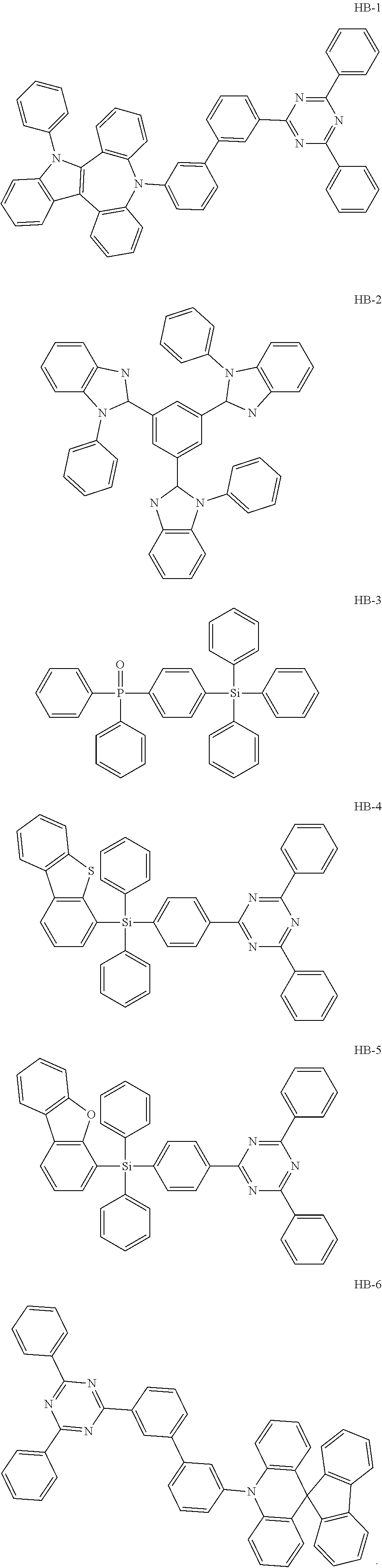

In an alternative embodiment, the electron injection material in the electron injection layer includes any one or a combination of at least two of the following compounds: Liq, LiF, NaCl, CsF, Li₂O, Cs₂CO₃, BaO, Na, Li, Ca, Mg, Ag and Yb.

In an alternative embodiment, a substrate may be used under the first electrode or over the second electrode. The substrate is made of glass or a polymer material having compressive strength, thermostability, waterproof property and excellent transparency. In addition, a thin-film transistor (TFT) may be provided on a substrate for a display.

In an alternative embodiment, the first electrode may be formed by sputtering or depositing a material serving as the first electrode on a substrate. When the first electrode is used as the anode, an oxide transparent conductive material such as indium tin oxygen (ITO), indium zinc oxygen (IZO), tin(IV) oxide (SnO₂), zinc oxide (ZnO) and any combination thereof may be used. When the first electrode is used as the cathode, a metal or alloy such as magnesium (Mg), silver (Ag), aluminum (Al), aluminum-lithium (Al—Li), calcium (Ca), magnesium-indium (Mg—In), magnesium-silver (Mg—Ag) or any combination thereof may be used.

A capping layer (CPL) may be deposited on the cathode of the device to play a role of improving the efficiency of the device, adjusting the optical microcavity and the like.

The thicknesses of the layers above may employ conventional thicknesses of the layers in the art.

An embodiment of the present disclosure provides a method for preparing the organic electroluminescent device. The method includes depositing an anode, a hole transport region, a light-emitting layer, an electron transport region and a cathode on a substrate sequentially and then encapsulating these components. When preparing the light-emitting layer, a multi-component co-deposition method is used. The anode, hole transport region, electron transport region and cathode are deposited in the same manner as is known in the art.

An embodiment of the present disclosure provides a display apparatus. The display apparatus includes the organic electroluminescent device provided above. Specifically, the display apparatus may be a display device such as an OLED display, as well as any product or component with a display function such as a television, a digital camera, a mobile phone or a tablet computer including the display device. The display apparatus has the same advantages as the preceding organic electroluminescent device over the art and is not described herein again.

The organic electroluminescent device of the present disclosure is further described below through embodiments.

### Embodiments One to Eleven and Comparative Embodiment One

The preceding embodiments and the comparative embodiment provide an organic electroluminescent device separately. The preparation method is described below.

(1) A glass plate coated with an ITO transparent conductive layer is sonicated in a commercial abluent, rinsed in deionized water, performed ultrasonic oil removal in an acetone: ethanol mixed solvent, baked in a clean environment to completely remove moisture, washed with ultraviolet and ozone and bombarded the surface with a low-energy cation beam.

(2) The glass substrate with an anode is placed in a vacuum chamber. The vacuum chamber is vacuumized to less than 1×10⁻⁵ Pa. HI-3 is deposited through vacuum evaporation as a hole injection layer on the anode layer film. The deposition rate is 0.1 nm/s, and the thickness of the deposition film is 2 nm.

(3) A hole transport layer HT-28 is deposited through vacuum evaporation on the hole injection layer. The deposition rate is 0.1 nm/s, and the total thickness of the deposition film is 30 nm.

(4) An electron blocking layer EB-12 is deposited through vacuum evaporation on the hole transport layer. The deposition rate is 0.1 nm/s, and the total thickness of the deposition film is 5 nm.

(5) A light-emitting layer is deposited through vacuum evaporation on the electron blocking layer by using the multi-component co-deposition method. The light-emitting layer includes a host material, a sensitizer and a fluorescent dye. The doping concentration of the sensitizer is 30 wt %. The doping concentration of the fluorescent dye is 2 wt %. The deposition rate is 0.1 nm/s, and the thickness of the deposition film is 30 nm.

(6) HB-5 is deposited through vacuum evaporation as a hole blocking layer on the light-emitting layer. The deposition rate is 0.1 nm/s, and the total thickness of the deposition film is 5 nm.

(7) ET-60 and ET-57 are deposited through vacuum evaporation as an electron transport layer on the hole blocking layer. The ratio of ET-60 to ET-57 is 1:1. The deposition rate is 0.1 nm/s, and the total thickness of deposition film is 25 nm.

(8) On the electron transport layer, Liq with a thickness of 1 nm is deposited through vacuum evaporation as an electron injection layer, and an Al layer with a thickness of 150 nm is deposited through vacuum evaporation as a cathode of the device.

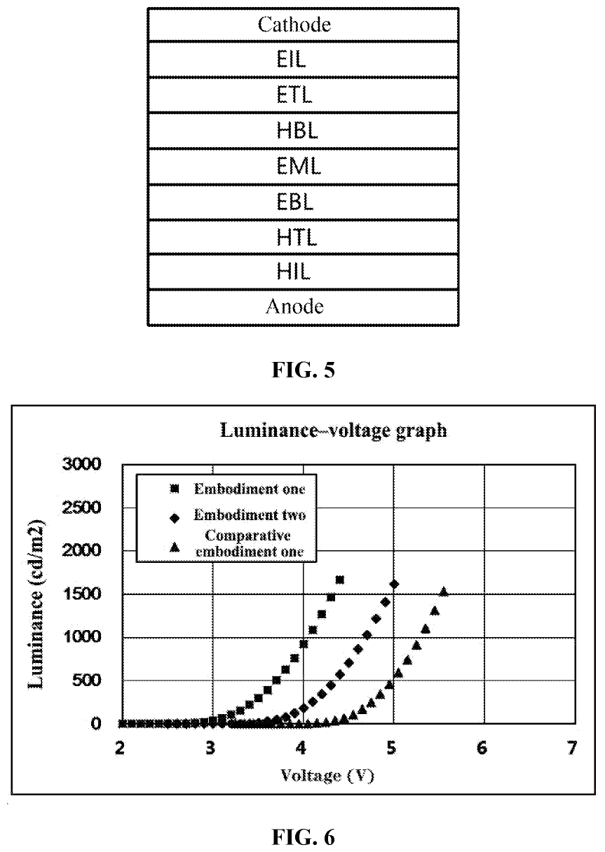

The structure of the organic electroluminescent device provided in the preceding embodiments and the comparative embodiment is as shown in FIG. 5. The device includes an anode, a hole injection layer (HIL), a hole transport layer (HTL), an electron blocking layer (EBL), a light-emitting layer (EML), a hole blocking layer (HBL), an electron transport layer (ETL), an electron injection layer (EIL) and a cathode from bottom to top sequentially.

The preceding embodiments differ from the comparative embodiment only in the types of host materials, sensitizers and dyes, as shown in Table 2 for details.

### Material Performance Test

The HOMO energy levels and LUMO energy levels are tested separately for the host materials, sensitizers and dyes in Table 1. The test method is described below.

The HOMO energy levels and LUMO energy levels of materials are tested by using an electrochemical cyclic voltammetry with a test equipment of Princeton Verstat3.

TABLE 1

| Material | Material | HOMO Energy | LUMO Energy |
|---|---|---|---|
| Type | Name | Level (eV) | Level (eV) |
| Dye | F-2 | −5.36 | −2.19 |
| | F-3 | −4.80 | −2.26 |
| | F-4 | −5.17 | −1.99 |
| | F-5 | −5.37 | −2.21 |
| | F-11 | −5.35 | −2.59 |
| | F-14 | −5.17 | −1.96 |
| | F-23 | −5.41 | −2.56 |
| Sensitizer | TDE6 | −5.51 | −2.33 |
| | TDE23 | −5.52 | −2.44 |
| | TDE26 | −5.68 | −2.6 |
| | TDE28 | −5.67 | −2.81 |
| | TDE32 | −5.54 | −2.37 |
| | TDE39 | −5.30 | −2.47 |
| Host | TDH-1 | −5.65 | −1.70 |
| | TDH-2 | −5.61 | −1.73 |
| | TDH-7 | −5.44 | −1.55 |
| | TDH-13 | −5.71 | −1.95 |
| | TDH-25 | −5.85 | −2.55 |

### Device Performance Test

The operating voltages and current efficiency of the organic electroluminescent devices prepared in the embodiments and comparative embodiment are measured by using the PR 750 crookes radiometer, the ST-86LA luminance meter (photoelectric instrument factory of Beijing Normal University) and the Keithley 4200 test system of Photo Research. Specifically, the voltage is increased at a rate of 0.1 V, and the operating voltage (V) corresponding to the luminance which is the target luminance of the organic electroluminescent device is measured, and the current density at that time is measured. The ratio of luminance to current density is the current efficiency (cd/A) of the device at this luminance

Using the luminance meter at a luminance of 1000 cd/m², a constant current is kept, and the time, in hours, for the luminance of the organic electroluminescent device to drop to 800 cd/m² is measured, and referred to as the LT80 service life of the device.

The results of the preceding test are shown in Table 2.

TABLE 2

| | | | | | | LT80 |
|---|---|---|---|---|---|---|
| | Host | | | Luminance | Operating | service |
| | material | Sensitizer | Dye | (cd/m²) | Voltage (V) | life (h) |
| Embodiment | TDH-2 | TDE23 | F-2 | 1000 | 4.1 | 60 |
| one | | | | | | |
| Embodiment | TDH-2 | TDE23 | F-11 | 1000 | 4.7 | 35 |
| two | | | | | | |
| Embodiment | TDH-2 | TDE32 | F-4 | 1000 | 4.0 | 40 |
| three | | | | | | |
| Embodiment | TDH-1 | TDE39 | F-23 | 1000 | 4.3 | 52 |
| four | | | | | | |
| Embodiment | TDH-2 | TDE6 | F-2 | 1000 | 4.1 | 46 |
| five | | | | | | |
| Embodiment | TDH-1 | TDE23 | F-2 | 1000 | 3.9 | 44 |
| six | | | | | | |
| Embodiment | TDH-2 | TDE32 | F-5 | 1000 | 4 | 42 |
| seven | | | | | | |
| Embodiment | TDH-7 | TDE39 | F-3 | 1000 | 4.2 | 58 |
| eight | | | | | | |
| Embodiment | TDH-13 | TDE23 | F-14 | 1000 | 4.3 | 55 |
| nine | | | | | | |
| Embodiment | TDH-13 | TDE28 | F-4 | 1000 | 4.5 | 60 |
| ten | | | | | | |
| Embodiment | TDH-2 | TDE32 | F-5 | 1000 | 4.6 | 46 |
| eleven | | | | | | |
| Comparative | TDH-2 | TDE26 | F-2 | 1000 | 5.3 | 28 |
| embodiment | | | | | | |
| one | | | | | | |

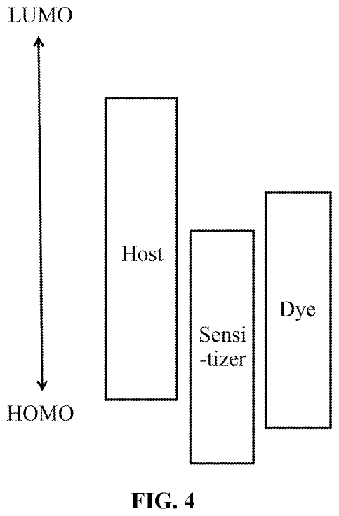

As can be seen from Table 2, in the embodiments of the present disclosure, the energy levels of the host material and the sensitizer are optimized so that the range from the LUMO energy level to the HOMO energy level of the host material completely covers the range from the LUMO energy level to the HOMO energy level of the sensitizer, thereby effectively improving the service life of the device and reducing the operating voltage of the device. The energy level relationship between the host material, the sensitizer and the dye in comparative embodiment one is shown in FIG. 4. The range from the LUMO energy level to the HOMO energy level of the host material is staggered from the range from the LUMO energy level to the HOMO energy level of the sensitizer. The performance of the device in comparative embodiment one is significantly worse than that in the embodiments.

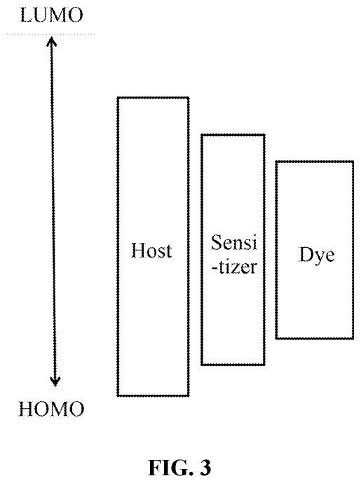

Embodiment two differs from embodiment one only in that the range from the LUMO energy level to the HOMO energy level of the dye is covered by the range from the LUMO energy level to the HOMO energy level of the sensitizer. As shown in FIG. 3, the performance of the device in embodiment two is significantly worse than that in embodiment one. It is proved from this that the performance of the device can be further improved by optimizing the energy level ranges of the dye and the sensitizer to make the range from the LUMO energy level to the HOMO energy level of the dye not be covered by the range from the LUMO energy levels to the HOMO energy levels of the host material and the sensitizer at the same time.

FIG. 6 is a luminance-voltage graph according to embodiment one, embodiment two and comparative embodiment one. As shown in FIG. 6, the voltage value in comparative embodiment one >the voltage value in embodiment two >the voltage value in embodiment five under the same luminance condition, further confirming the preceding conclusions.

Although the detailed method of the present disclosure is described through the embodiments above, the present disclosure is not limited to the detailed method above, that is, the implementation of the present disclosure does not necessarily depend on the detailed method above. It is apparent to those skilled in the art that any improvements made to the present disclosure, equivalent substitutions of various raw materials of the product of the present disclosure, the addition of adjuvant ingredients of the product of the present disclosure, and the selection of specific manners in the present disclosure all fall within the protection scope and the disclosure scope of the present disclosure.

What is claimed is:

1. An organic electroluminescent device, comprising a first electrode, a second electrode and an organic layer located between the first electrode and the second electrode, wherein
the organic layer comprises a light-emitting layer, and the light-emitting layer contains a host material, a thermally activated delayed fluorescence sensitizer and a fluorescent dye; and
an energy level relationship between the host material and the thermally activated delayed fluorescence sensitizer is LUMOₕₒₛₜ ≥LUMO_{sensitizer}>HOMO_{sensitizer}≥HOMOₕₒₛₜ.

2. The organic electroluminescent device according to claim 1, wherein the energy level relationship between the host material and the thermally activated delayed fluorescence sensitizer is LUMOₕₒₛₜ>LUMO_{sensitizer}>HOMO_{sensitizer}>HOMOₕₒₛₜ.

3. The organic electroluminescent device according to claim 2, wherein 1 eV >|LUMOₕₒₛₜ−LUMO_{sensitizer}|>0.1 eV.

4. The organic electroluminescent device according to claim 2, wherein 1 eV >|HOMO_{sensitizer}−HOMOₕₒₛₜ|>0.1 eV.

5. The organic electroluminescent device according to claim 1, wherein an energy level relationship between the thermally activated delayed fluorescence sensitizer and the fluorescent dye is LUMO_{dye}>LUMO_{sensitizer}>HOMO_{dye}>HOMO_{sensitizer}, or LUMO_{sensitizer}>LUMO_{dye}>HOMO_{sensitizer}>HOMO_{dye}.

6. The organic electroluminescent device according to claim 5, wherein the energy level relationship between the thermally activated delayed fluorescence sensitizer and the fluorescent dye is LUMO_{dye}>LUMO_{sensitizer}>HOMO_{dye} >HOMO_{sensitizer}, and 1 eV >LUMO_{sensitizer}−LUMO_{dye}>0.1 eV; or
the energy level relationship between the thermally activated delayed fluorescence sensitizer and the fluorescent dye is LUMO_{sensitizer}>LUMO_{dye}>HOMO_{sensitizer}>HOMO_{dye}, and 1 eV >|HOMO_{dye}−HOMO_{sensitizer}|>0.1 eV.

7. The organic electroluminescent device according to claim 1, wherein an energy level relationship between the host material and the fluorescent dye is LUMO_{dye}>LUMOₕₒₛₜ>HOMO_{dye} >HOMOₕₒₛₜ, or LUMOₕₒₛₜ>LUMO_{dye}>HOMOₕₒₛₜ>HOMO_{dye}.

8. The organic electroluminescent device according to claim 7, wherein the energy level relationship between the host material and the fluorescent dye is LUMO_{dye}>LUMOₕₒₛₜ>HOMO_{dye}>HOMOₕₒₛₜ, and 1 eV >|LUMOₕₒₛₜ−LUMO_{dye}|>0.1 eV; or
the energy level relationship between the host material and the fluorescent dye is LUMOₕₒₛₜ>LUMO_{dye}>HOMOₕₒₛₜ>HOMO_{dye}, and 1 eV >|HOMO_{dye}−HOMOₕₒₛₜ|>0.1 eV.

9. The organic electroluminescent device according to claim 1, wherein the fluorescent dye is selected from any one of compounds F-1 to F-30:

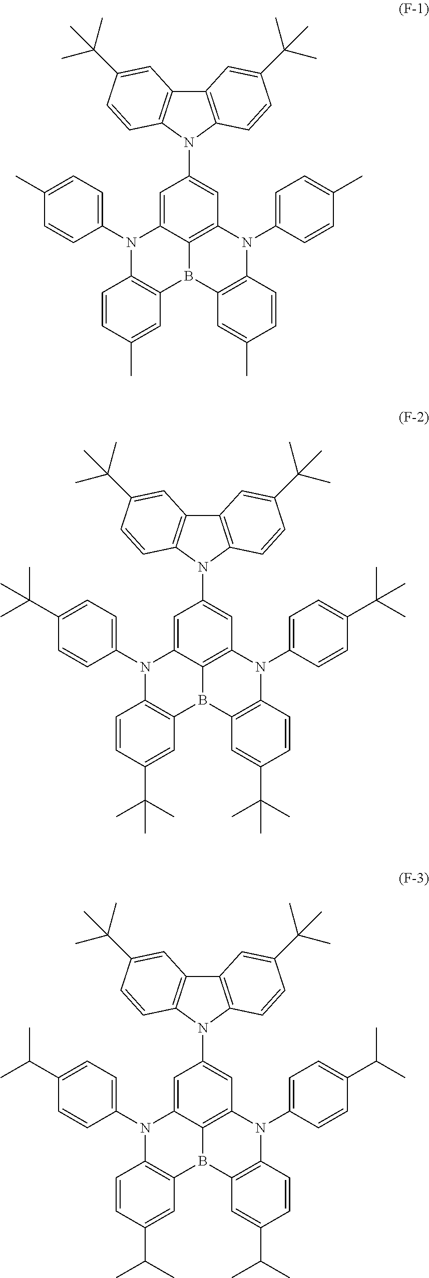

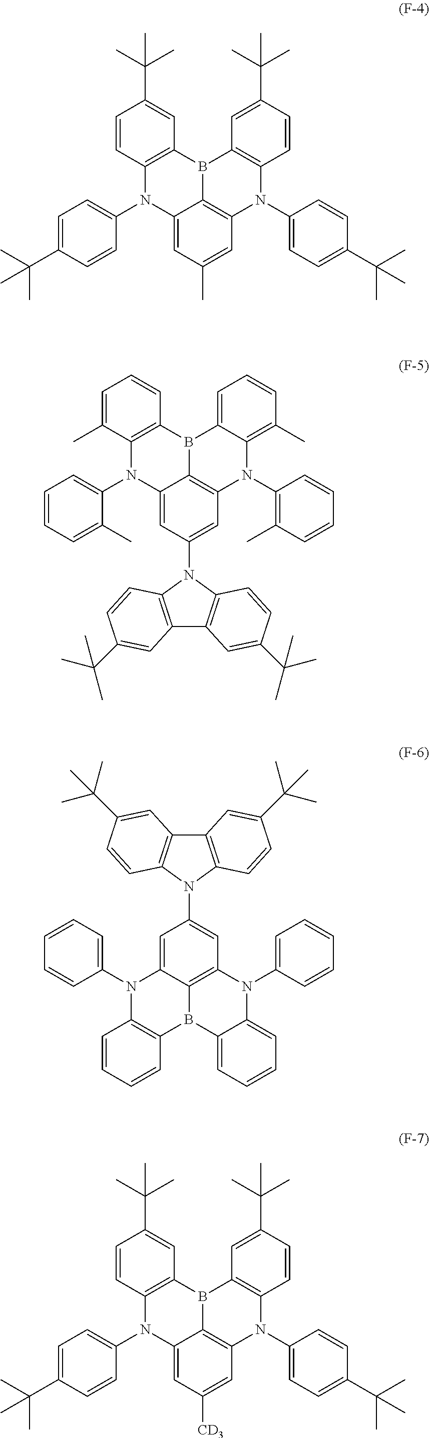

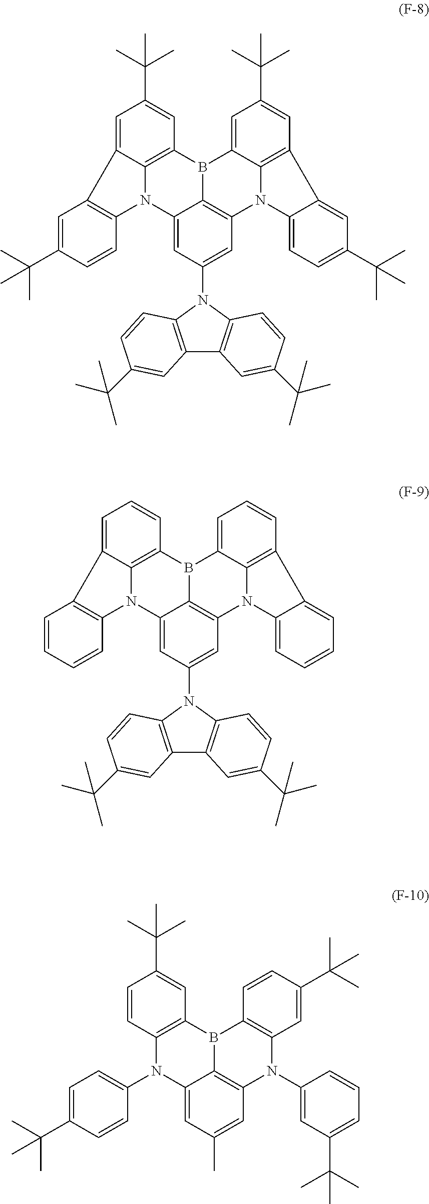

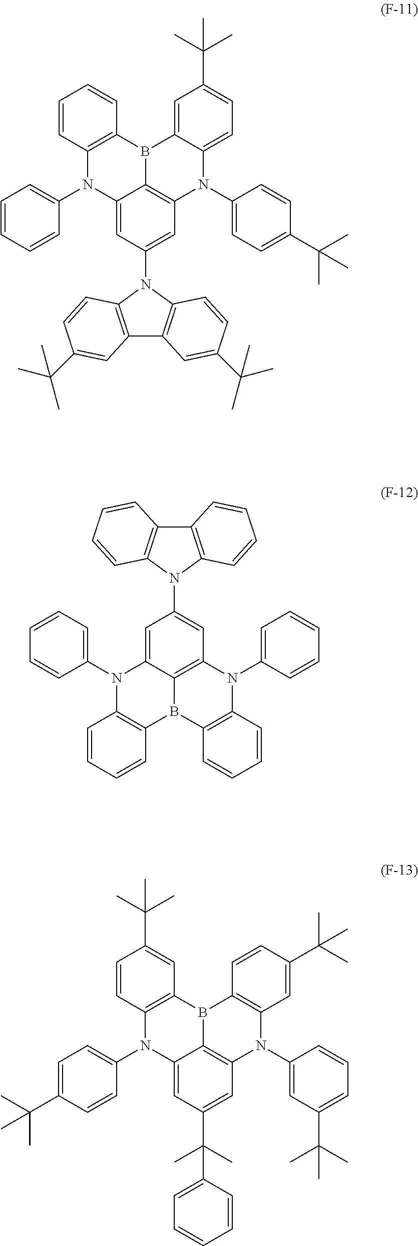

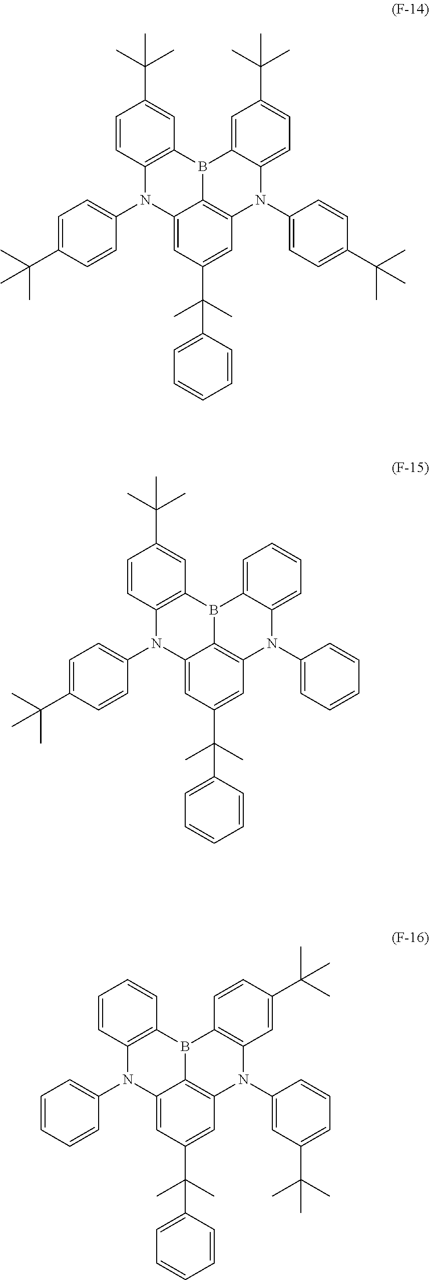

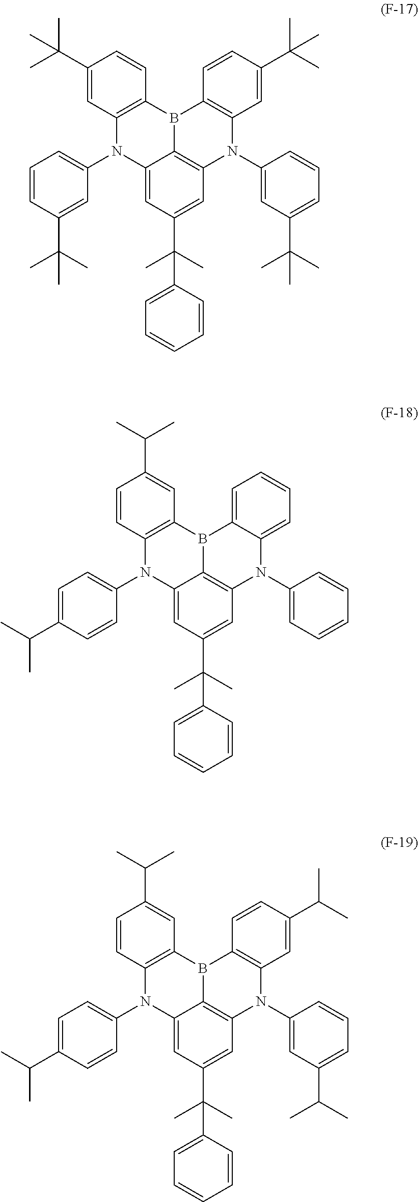

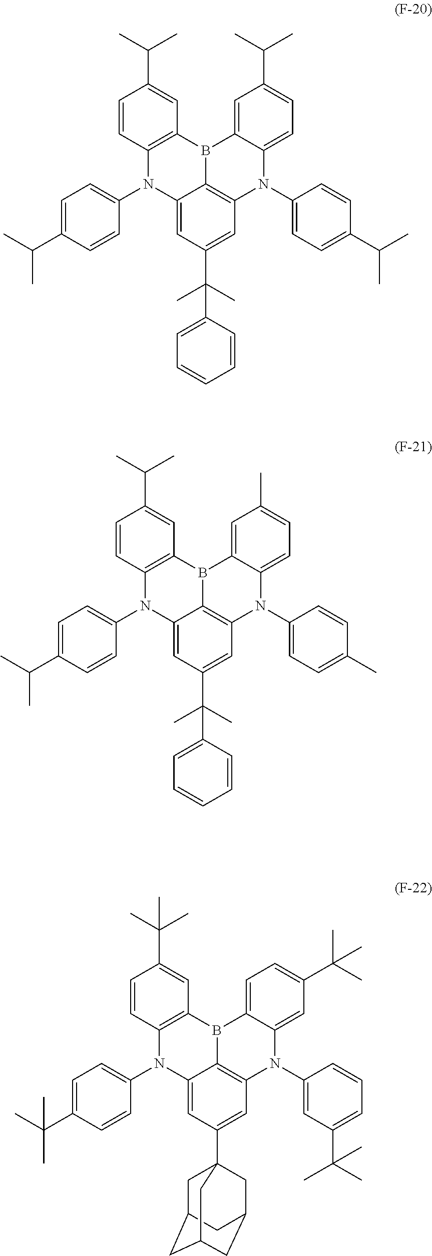

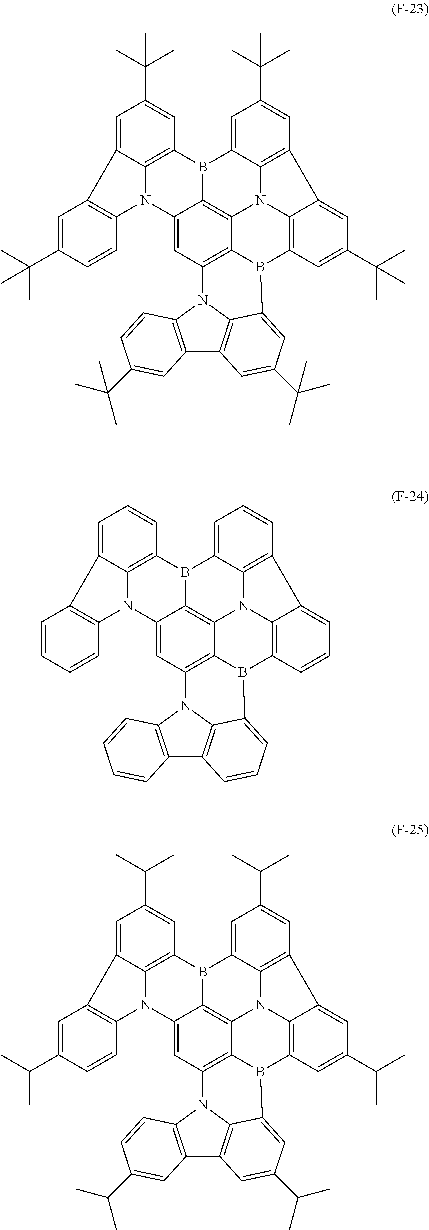

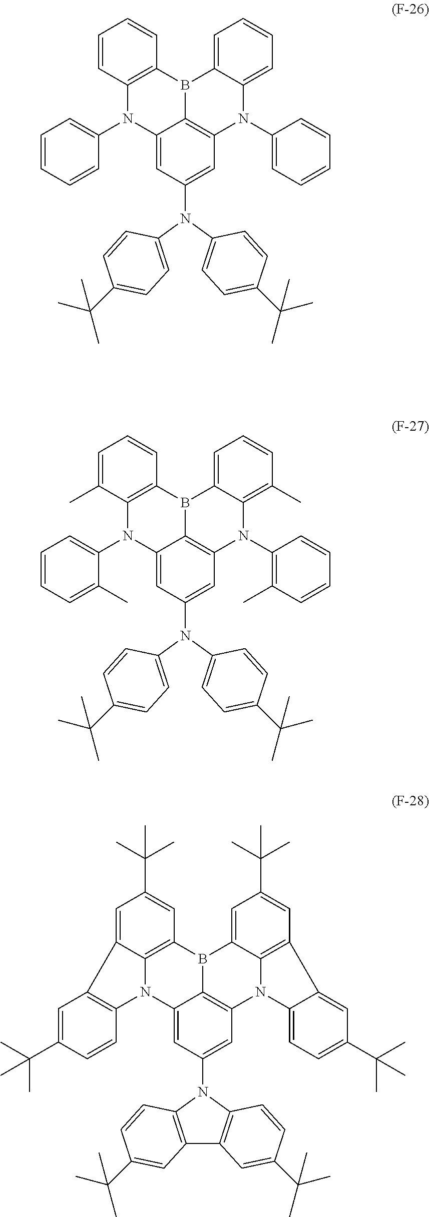 [SMILES: CC(C)(C)c1ccc(N(c2ccc(C(C)(C)C)cc2)c2cc3c4c(c2)N(c2ccccc2)c2ccccc2B4c2ccccc2N3c2ccccc2)cc1 ; Cc1ccccc1N1c2cc(N(c3ccc(C(C)(C)C)cc3)c3ccc(C(C)(C)C)cc3)cc3c2B(c2cccc(C)c21)c1cccc(C)c1N3c1ccccc1C ; CC(C)(C)c1ccc2c(c1)c1cc(C(C)(C)C)ccc1n2-c1cc2c3c(c1)-n1c4ccc(C(C)(C)C)cc4c4cc(C(C)(C)C)cc(c41)B3c1cc(C(C)(C)C)cc3c4cc(C(C)(C)C)ccc4n-2c13]

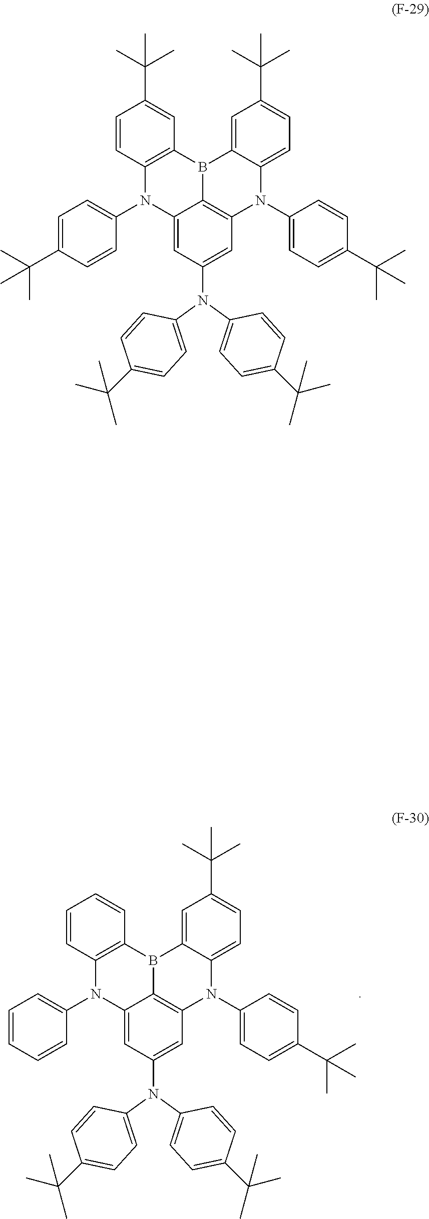 [SMILES: CC(C)(C)c1ccc(N(c2ccc(C(C)(C)C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)cc1 ; CC(C)(C)c1ccc(N(c2ccc(C(C)(C)C)cc2)c2cc3c4c(c2)N(c2ccc(C(C)(C)C)cc2)c2ccc(C(C)(C)C)cc2B4c2ccccc2N3c2ccccc2)cc1]

10. The organic electroluminescent device according to claim 1, wherein the thermally activated delayed fluorescence sensitizer is selected from one or a combination of at least two of compounds TDE1 to TDE45:

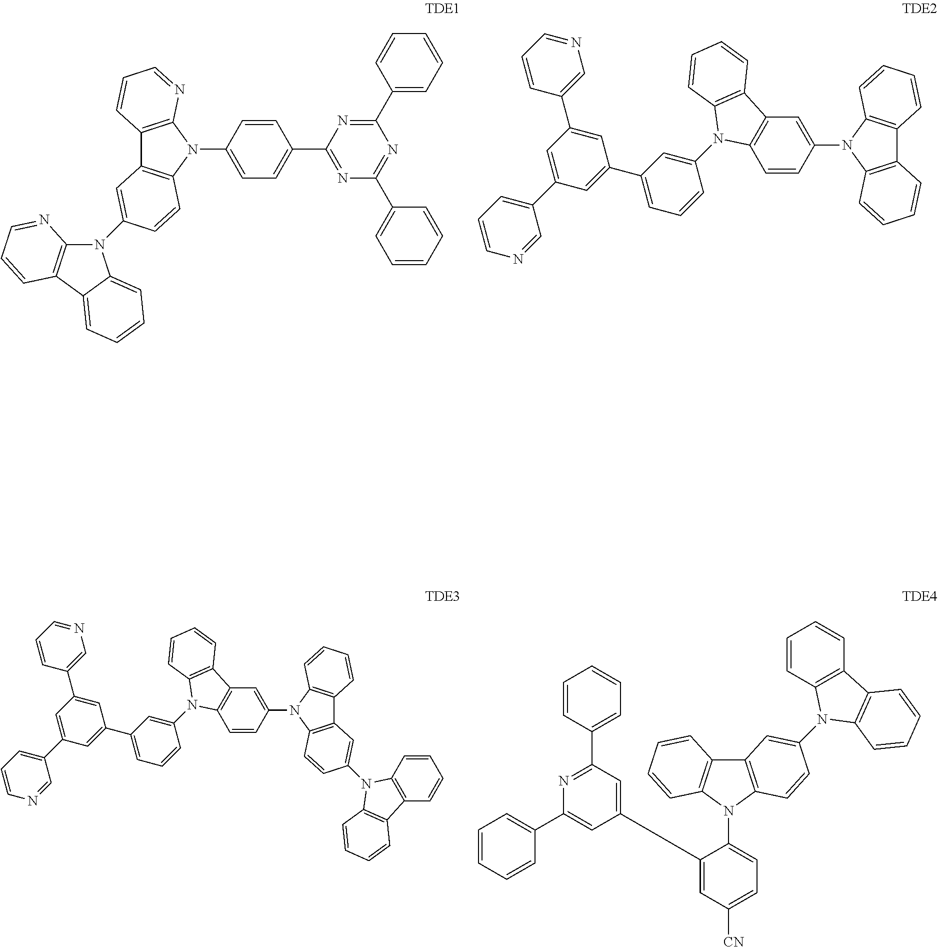

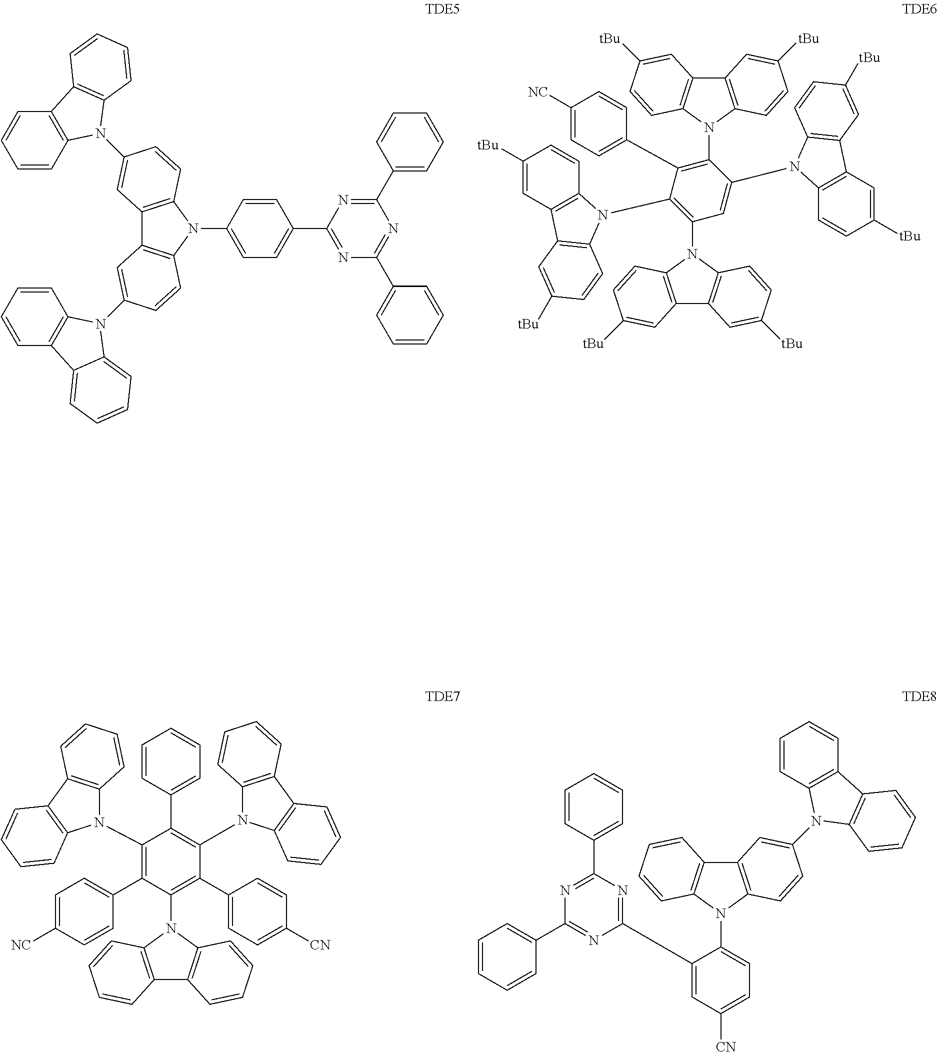

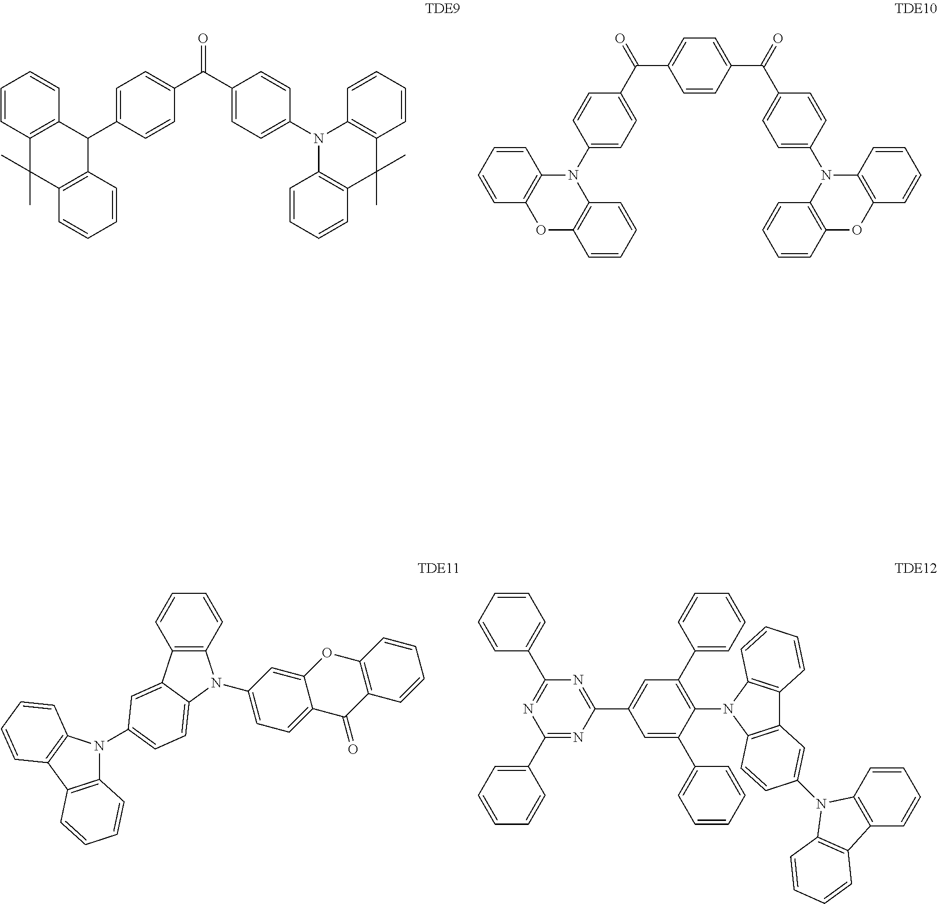 [SMILES: CC1(C)c2ccccc2C(c2ccc(C(=O)c3ccc(N4c5ccccc5C(C)(C)c5ccccc54)cc3)cc2)c2ccccc21 ; O=C(c1ccc(C(=O)c2ccc(N3c4ccccc4Oc4ccccc43)cc2)cc1)c1ccc(N2c3ccccc3Oc3ccccc32)cc1 ; O=c1c2ccccc2oc2cc(-n3c4ccccc4c4cc(-n5c6ccccc6c6ccccc65)ccc43)ccc12 ; c1ccc(-c2nc(-c3ccccc3)nc(-c3cc(-c4ccccc4)c(-n4c5ccccc5c5cc(-n6c7ccccc7c7ccccc76)ccc54)c(-c4ccccc4)c3)n2)cc1]

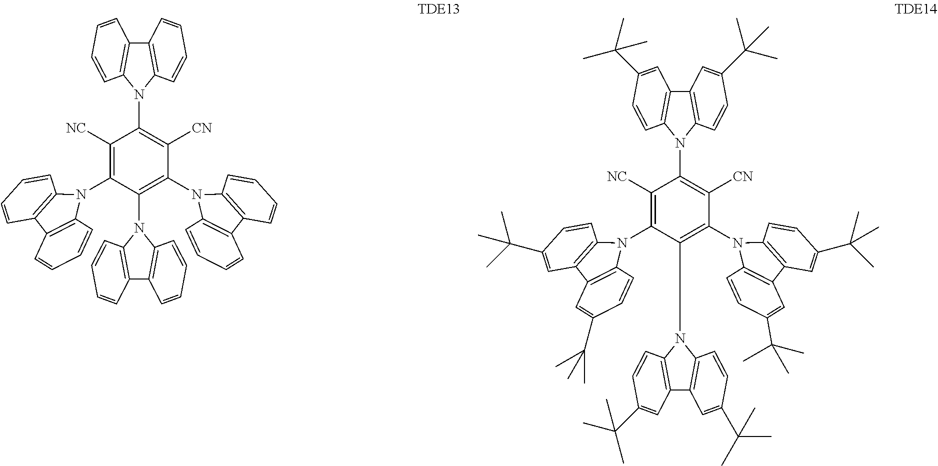 [SMILES: N#Cc1c(-n2c3ccccc3c3ccccc32)c(C#N)c(-n2c3ccccc3c3ccccc32)c(-n2c3ccccc3c3ccccc32)c1-n1c2ccccc2c2ccccc21 ; CC(C)(C)c1ccc2c(c1)c1cc(C(C)(C)C)ccc1n2-c1c(C#N)c(-n2c3ccc(C(C)(C)C)cc3c3cc(C(C)(C)C)ccc32)c(-n2c3ccc(C(C)(C)C)cc3c3cc(C(C)(C)C)ccc32)c(-n2c3ccc(C(C)(C)C)cc3c3cc(C(C)(C)C)ccc32)c1C#N]

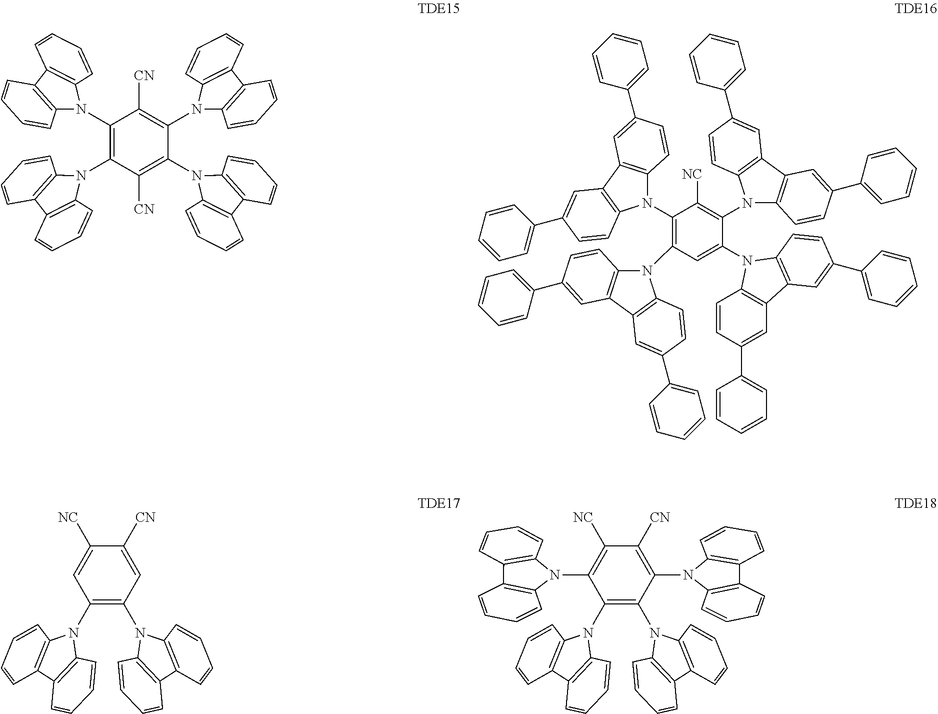 [SMILES: N#Cc1c(-n2c3ccccc3c3ccccc32)c(-n2c3ccccc3c3ccccc32)c(C#N)c(-n2c3ccccc3c3ccccc32)c1-n1c2ccccc2c2ccccc21 ; N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)cc(-n2c3ccc(-c4ccccc4)cc3c3cc(-c4ccccc4)ccc32)c1-n1c2ccc(-c3ccccc3)cc2c2cc(-c3ccccc3)ccc21 ; N#Cc1cc(-n2c3ccccc3c3ccccc32)c(-n2c3ccccc3c3ccccc32)cc1C#N ; N#Cc1c(C#N)c(-n2c3ccccc3c3ccccc32)c(-n2c3ccccc3c3ccccc32)c(-n2c3ccccc3c3ccccc32)c1-n1c2ccccc2c2ccccc21]

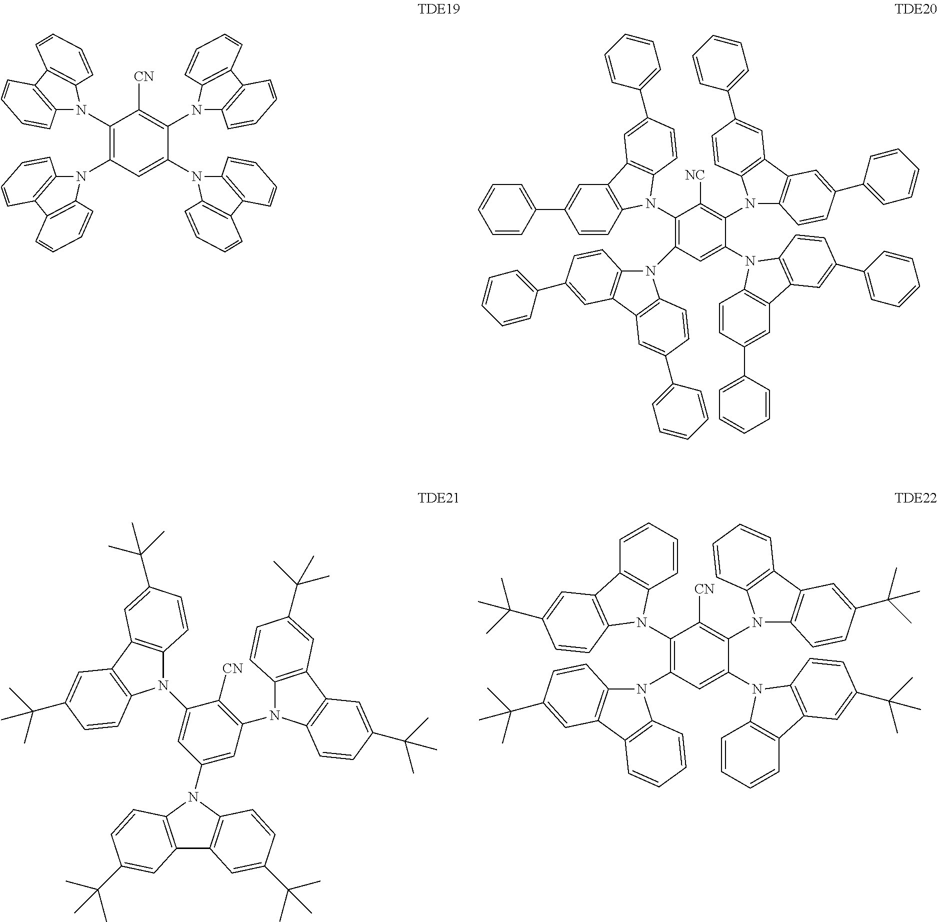

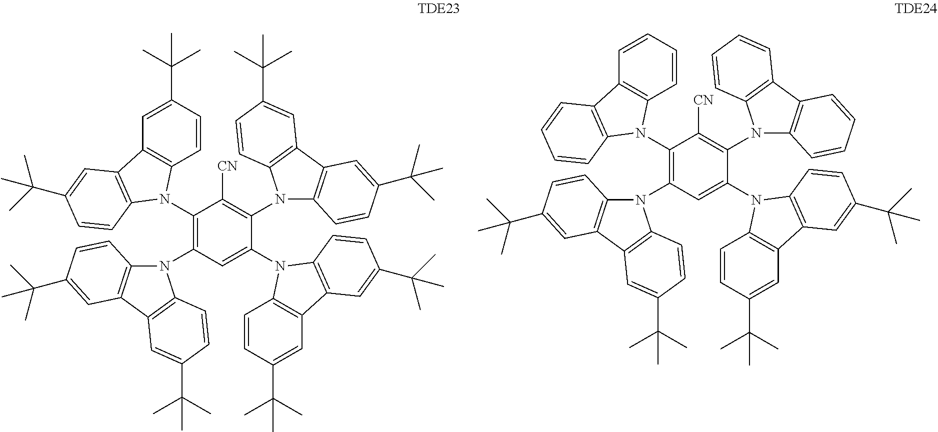 [SMILES: CC(C)(C)c1ccc2c(c1)c1cc(C(C)(C)C)ccc1n2-c1cc(-n2c3ccc(C(C)(C)C)cc3c3cc(C(C)(C)C)ccc32)c(-n2c3ccc(C(C)(C)C)cc3c3cc(C(C)(C)C)ccc32)c(C#N)c1-n1c2ccc(C(C)(C)C)cc2c2cc(C(C)(C)C)ccc21 ; CC(C)(C)c1ccc2c(c1)c1cc(C(C)(C)C)ccc1n2-c1cc(-n2c3ccc(C(C)(C)C)cc3c3cc(C(C)(C)C)ccc32)c(-n2c3ccccc3c3ccccc32)c(C#N)c1-n1c2ccccc2c2ccccc21]

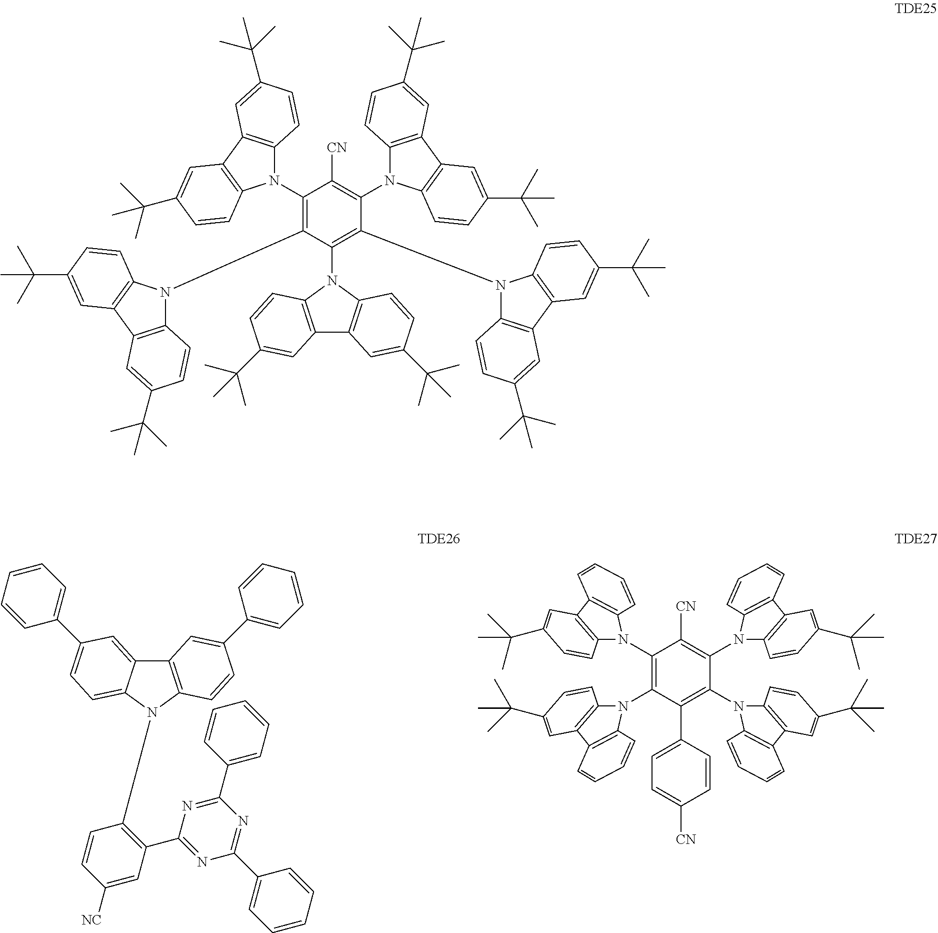

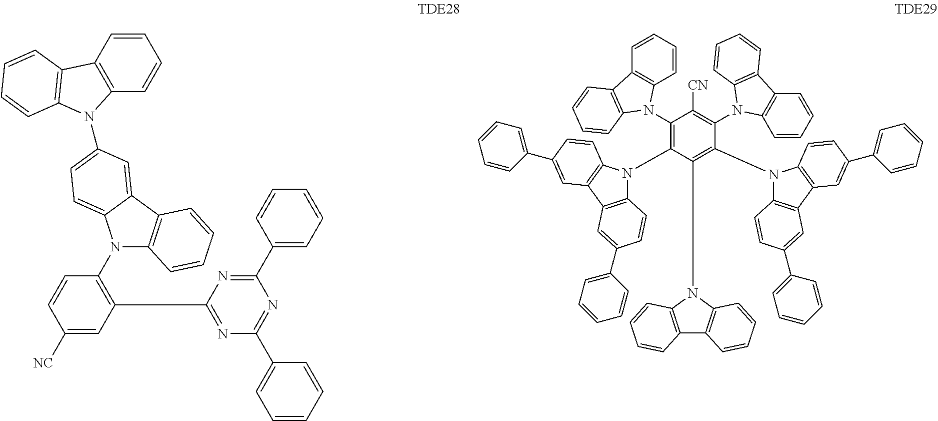 [SMILES: N#Cc1ccc(-n2c3ccccc3c3cc(-n4c5ccccc5c5ccccc54)ccc32)c(-c2nc(-c3ccccc3)nc(-c3ccccc3)n2)c1 ; N#Cc1c(-n2c3ccccc3c3ccccc32)c(-n2c3ccc(-c4ccccc4)cc3c3cc(-c4ccccc4)ccc32)c(-n2c3ccccc3c3ccccc32)c(-n2c3ccc(-c4ccccc4)cc3c3cc(-c4ccccc4)ccc32)c1-n1c2ccccc2c2ccccc21]

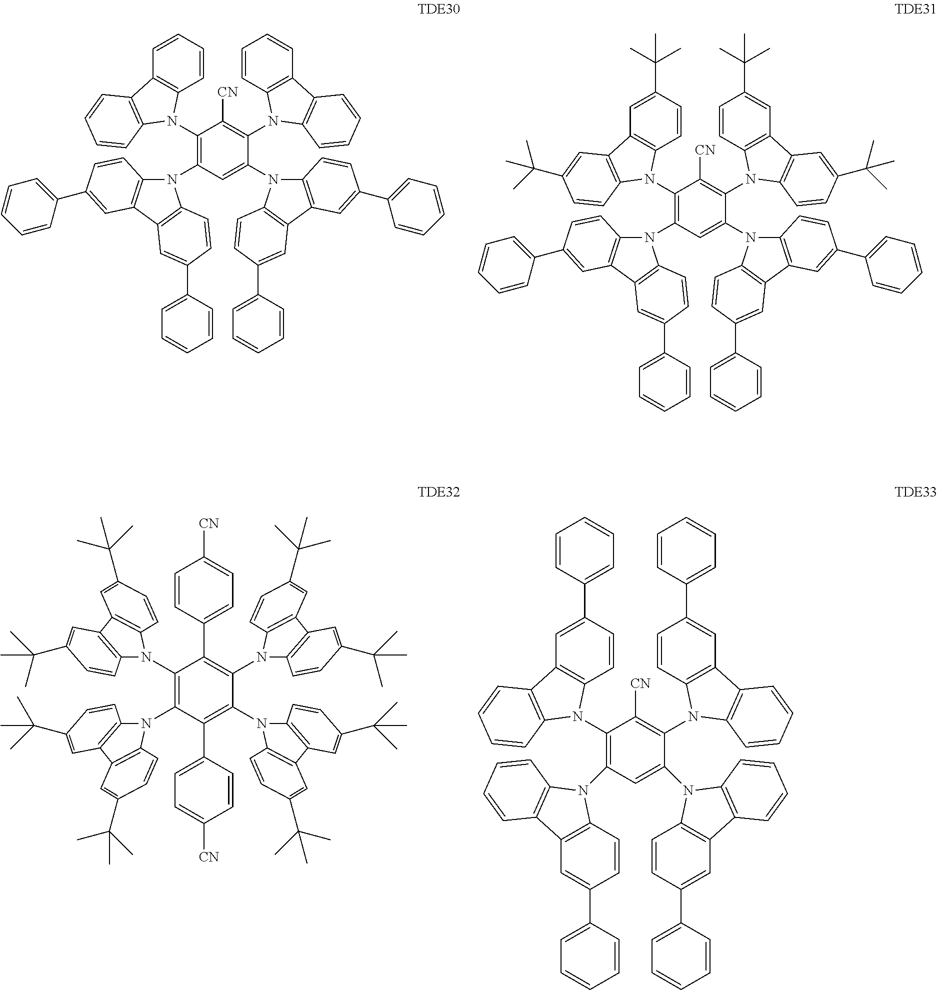

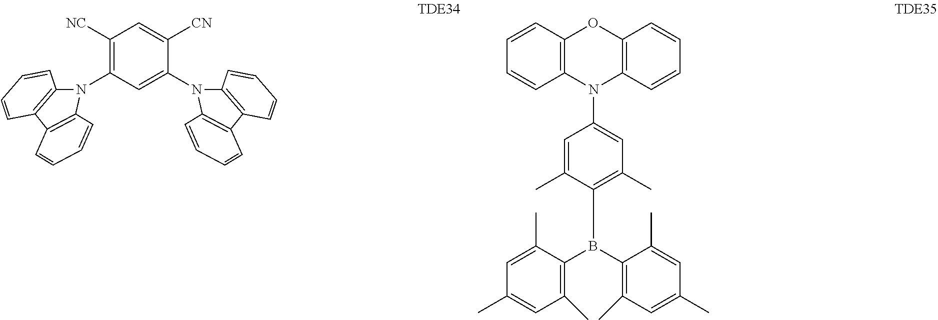

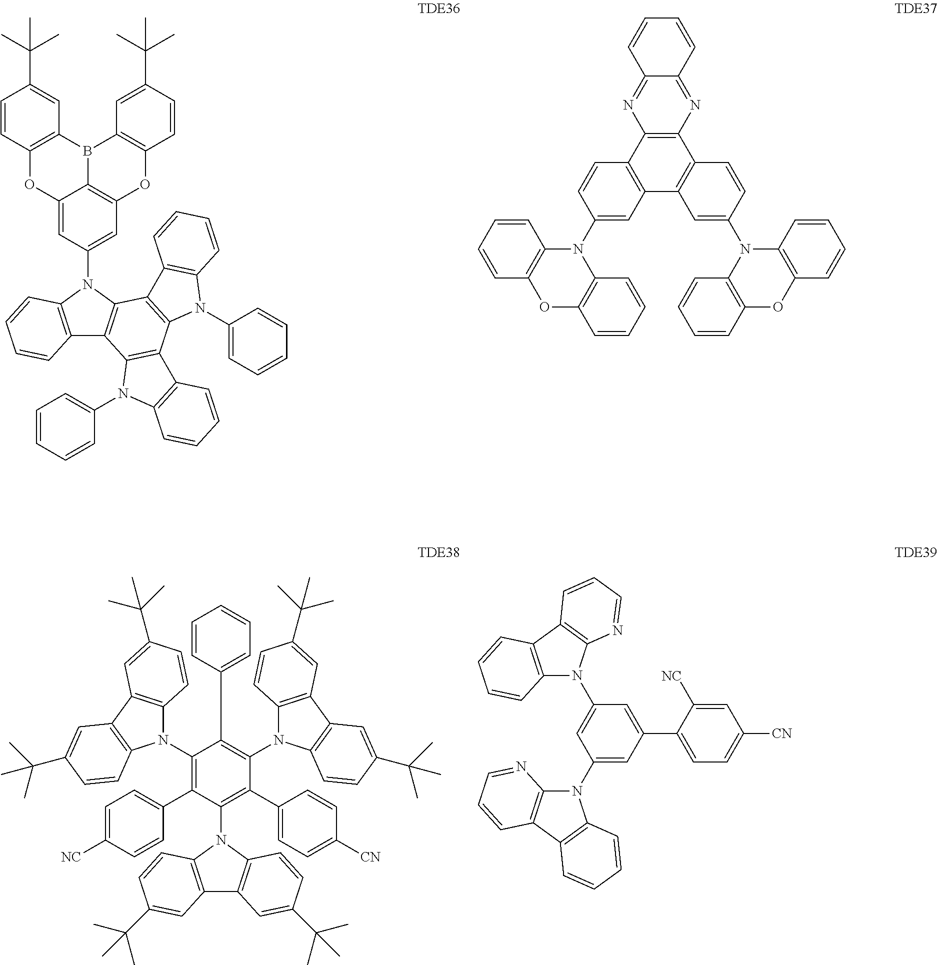 [SMILES: CC(C)(C)c1ccc2c(c1)B1c3cc(C(C)(C)C)ccc3Oc3cc(-n4c5ccccc5c5c6c(c7ccccc7n6-c6ccccc6)c6c(c7ccccc7n6-c6ccccc6)c54)cc(c31)O2 ; c1ccc2c(c1)Oc1ccccc1N2c1ccc2c(c1)c1cc(N3c4ccccc4Oc4ccccc43)ccc1c1nc3ccccc3nc21 ; CC(C)(C)c1ccc2c(c1)c1cc(C(C)(C)C)ccc1n2-c1c(-c2ccccc2)c(-n2c3ccc(C(C)(C)C)cc3c3cc(C(C)(C)C)ccc32)c(-c2ccc(C#N)cc2)c(-n2c3ccc(C(C)(C)C)cc3c3cc(C(C)(C)C)ccc32)c1-c1ccc(C#N)cc1 ; N#Cc1ccc(-c2cc(-n3c4ccccc4c4cccnc43)cc(-n3c4ccccc4c4cccnc43)c2)c(C#N)c1]

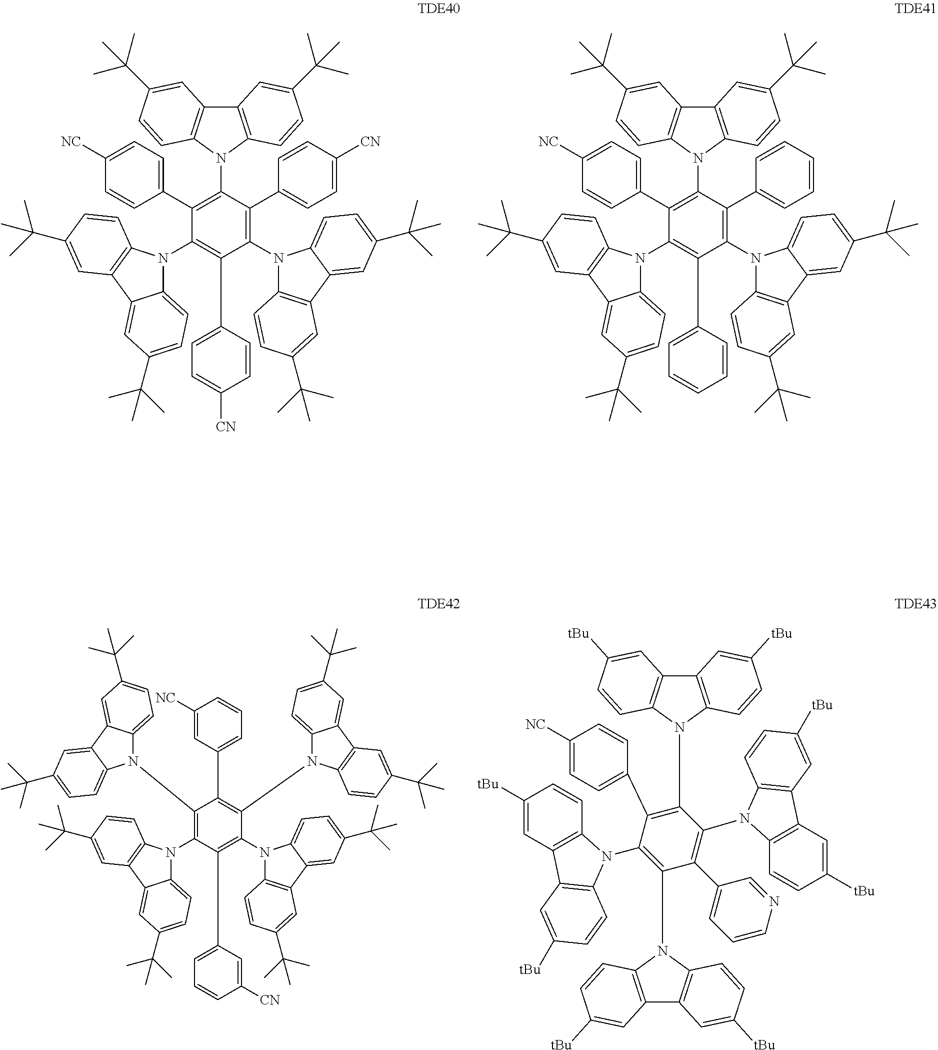

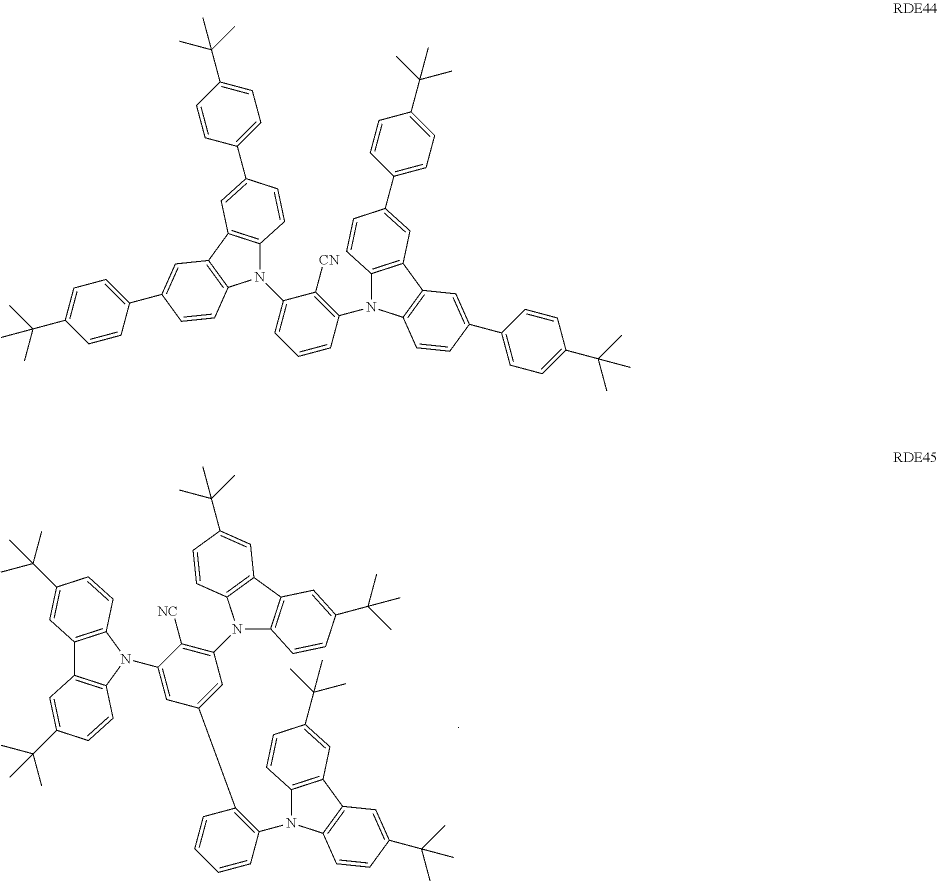

11. The organic electroluminescent device according to claim 1, wherein the host material is selected from any one or a combination of at least two of compounds TDH-1 to TDH-30:

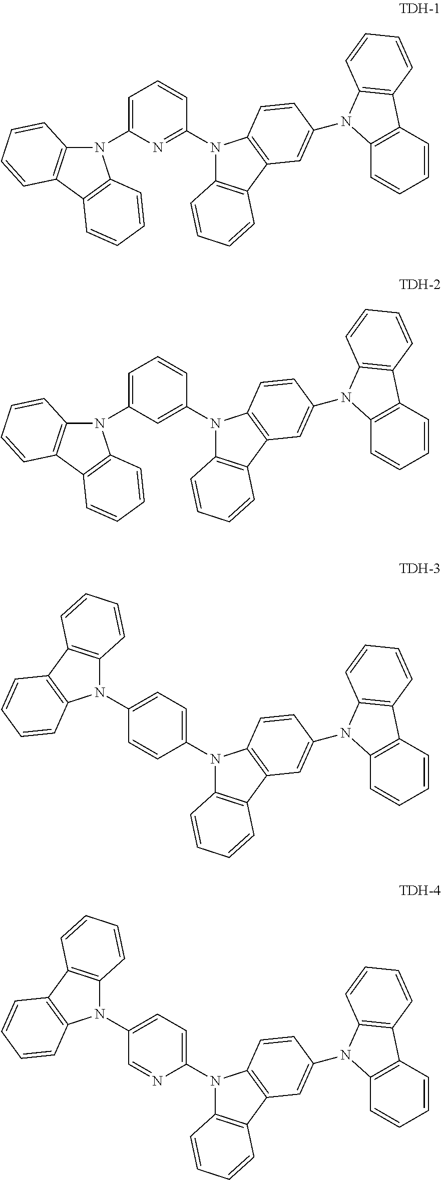 [SMILES: c1cc(-n2c3ccccc3c3ccccc32)nc(-n2c3ccccc3c3cc(-n4c5ccccc5c5ccccc54)ccc32)c1 ; c1cc(-n2c3ccccc3c3ccccc32)cc(-n2c3ccccc3c3cc(-n4c5ccccc5c5ccccc54)ccc32)c1 ; c1ccc2c(c1)c1ccccc1n2-c1ccc(-n2c3ccccc3c3cc(-n4c5ccccc5c5ccccc54)ccc32)cc1 ; c1ccc2c(c1)c1ccccc1n2-c1ccc(-n2c3ccccc3c3cc(-n4c5ccccc5c5ccccc54)ccc32)nc1]

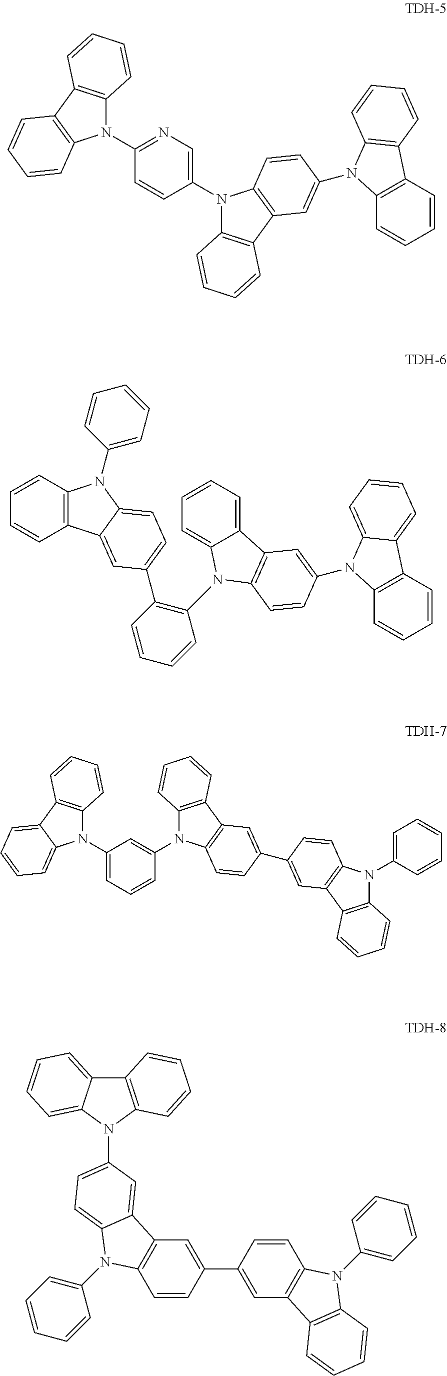 [SMILES: c1ccc2c(c1)c1ccccc1n2-c1ccc2c(c1)c1ccccc1n2-c1ccc(-n2c3ccccc3c3ccccc32)nc1 ; c1ccc(-n2c3ccccc3c3cc(-c4ccccc4-n4c5ccccc5c5cc(-n6c7ccccc7c7ccccc76)ccc54)ccc32)cc1 ; c1ccc(-n2c3ccccc3c3cc(-c4ccc5c(c4)c4ccccc4n5-c4cccc(-n5c6ccccc6c6ccccc65)c4)ccc32)cc1 ; c1ccc(-n2c3ccccc3c3cc(-c4ccc5c(c4)c4cc(-n6c7ccccc7c7ccccc76)ccc4n5-c4ccccc4)ccc32)cc1]

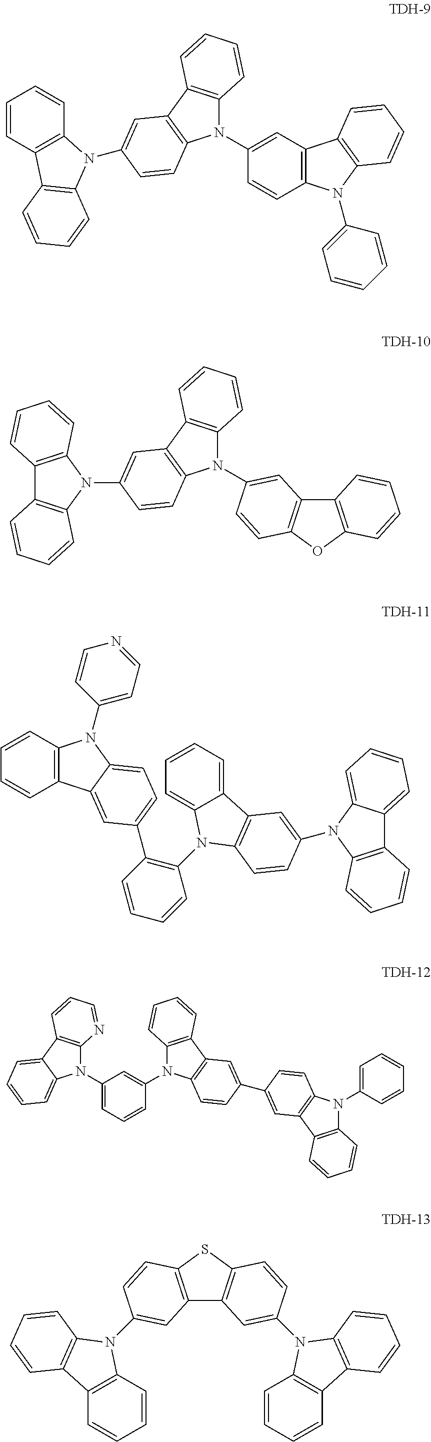 [SMILES: c1ccc(-n2c3ccccc3c3cc(-n4c5ccccc5c5cc(-n6c7ccccc7c7ccccc76)ccc54)ccc32)cc1 ; c1ccc2c(c1)oc1ccc(-n3c4ccccc4c4cc(-n5c6ccccc6c6ccccc65)ccc43)cc12 ; c1ccc(-n2c3ccccc3c3cc(-n4c5ccccc5c5ccccc54)ccc32)c(-c2ccc3c(c2)c2ccccc2n3-c2ccncc2)c1 ; c1ccc(-n2c3ccccc3c3cc(-c4ccc5c(c4)c4ccccc4n5-c4cccc(-n5c6ccccc6c6cccnc65)c4)ccc32)cc1 ; c1ccc2c(c1)c1ccccc1n2-c1ccc2sc3ccc(-n4c5ccccc5c5ccccc54)cc3c2c1]

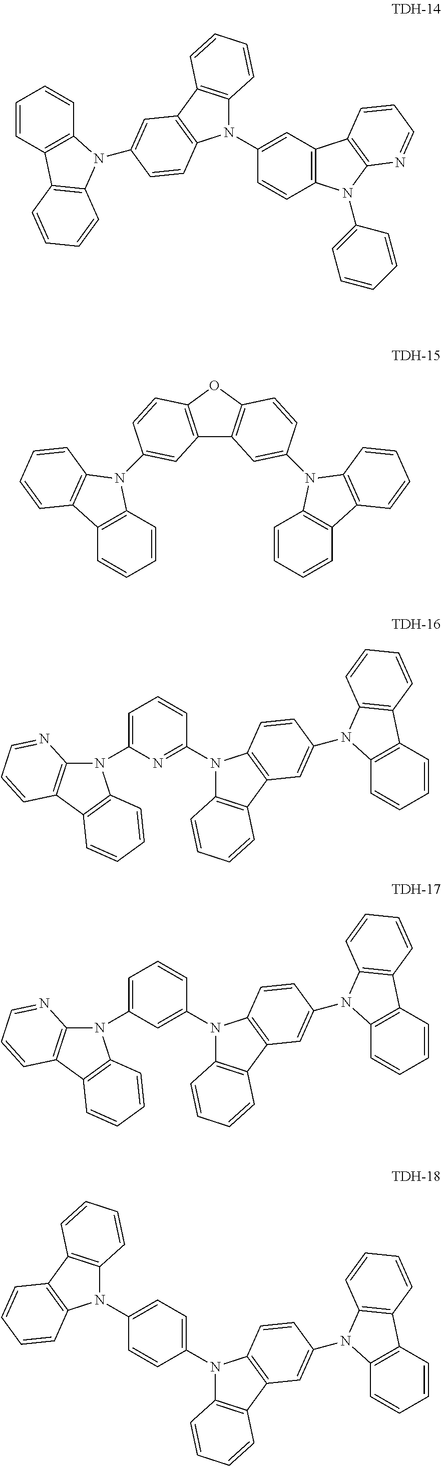 [SMILES: c1ccc(-n2c3ccc(-n4c5ccccc5c5cc(-n6c7ccccc7c7ccccc76)ccc54)cc3c3cccnc32)cc1 ; c1ccc2c(c1)c1ccccc1n2-c1ccc2oc3ccc(-n4c5ccccc5c5ccccc54)cc3c2c1 ; c1cc(-n2c3ccccc3c3cc(-n4c5ccccc5c5ccccc54)ccc32)nc(-n2c3ccccc3c3cccnc32)c1 ; c1cc(-n2c3ccccc3c3cc(-n4c5ccccc5c5ccccc54)ccc32)cc(-n2c3ccccc3c3cccnc32)c1 ; c1ccc2c(c1)c1ccccc1n2-c1ccc(-n2c3ccccc3c3cc(-n4c5ccccc5c5ccccc54)ccc32)cc1]

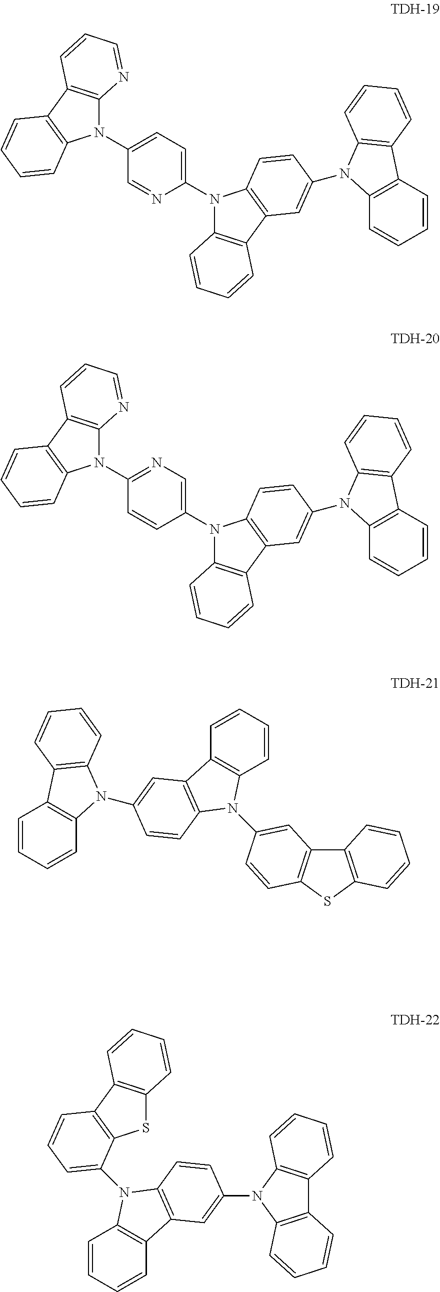 [SMILES: c1ccc2c(c1)c1ccccc1n2-c1ccc2c(c1)c1ccccc1n2-c1ccc(-n2c3ccccc3c3cccnc32)cn1 ; c1ccc2c(c1)c1ccccc1n2-c1ccc2c(c1)c1ccccc1n2-c1ccc(-n2c3ccccc3c3cccnc32)nc1 ; c1ccc2c(c1)sc1ccc(-n3c4ccccc4c4cc(-n5c6ccccc6c6ccccc65)ccc43)cc12 ; c1ccc2c(c1)sc1c(-n3c4ccccc4c4cc(-n5c6ccccc6c6ccccc65)ccc43)cccc12]

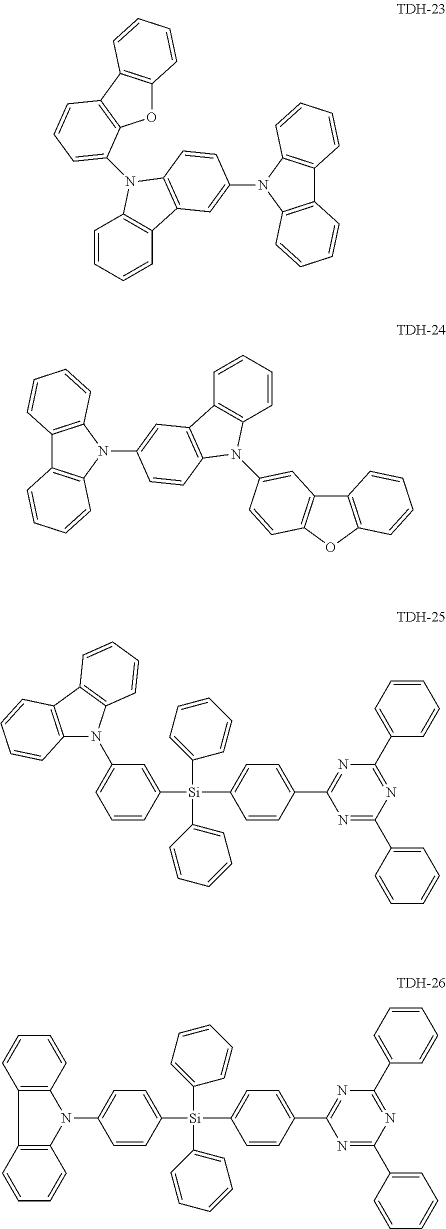 [SMILES: c1ccc2c(c1)oc1c(-n3c4ccccc4c4cc(-n5c6ccccc6c6ccccc65)ccc43)cccc12 ; c1ccc2c(c1)oc1ccc(-n3c4ccccc4c4cc(-n5c6ccccc6c6ccccc65)ccc43)cc12 ; c1ccc(-c2nc(-c3ccccc3)nc(-c3ccc([Si](c4ccccc4)(c4ccccc4)c4cccc(-n5c6ccccc6c6ccccc65)c4)cc3)n2)cc1 ; c1ccc(-c2nc(-c3ccccc3)nc(-c3ccc([Si](c4ccccc4)(c4ccccc4)c4ccc(-n5c6ccccc6c6ccccc65)cc4)cc3)n2)cc1]

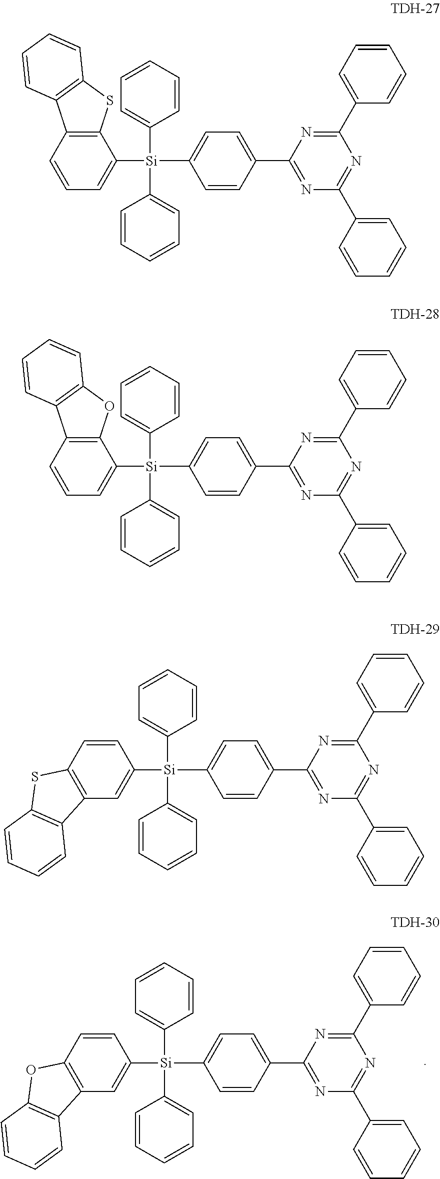 [SMILES: c1ccc(-c2nc(-c3ccccc3)nc(-c3ccc([Si](c4ccccc4)(c4ccccc4)c4cccc5c4sc4ccccc45)cc3)n2)cc1 ; c1ccc(-c2nc(-c3ccccc3)nc(-c3ccc([Si](c4ccccc4)(c4ccccc4)c4cccc5c4oc4ccccc45)cc3)n2)cc1 ; c1ccc(-c2nc(-c3ccccc3)nc(-c3ccc([Si](c4ccccc4)(c4ccccc4)c4ccc5sc6ccccc6c5c4)cc3)n2)cc1 ; c1ccc(-c2nc(-c3ccccc3)nc(-c3ccc([Si](c4ccccc4)(c4ccccc4)c4ccc5oc6ccccc6c5c4)cc3)n2)cc1]

12. A display apparatus, comprising the organic electroluminescent device according to claim 1.

13. The organic electroluminescent device according to claim 3, wherein 1 eV >|HOMO_{sensitizer}−HOMOₕₒₛₜ|>0.1 eV.

14. The organic electroluminescent device according to claim 2, wherein an energy level relationship between the thermally activated delayed fluorescence sensitizer and the fluorescent dye is LUMO_{dye}>LUMO_{sensitizer}>HOMO_{dye}>HOMO_{sensitizer}, or LUMO_{sensitizer}>LUMO_{dye}>HOMO_{sensitizer}>HOMO_{dye}.

15. The organic electroluminescent device according to claim 3, wherein an energy level relationship between the thermally activated delayed fluorescence sensitizer and the fluorescent dye is LUMO_{dye}>LUMO_{sensitizer}>HOMO_{dye} >HOMO_{sensitizer}, or LUMO_{sensitizer}>LUMO_{dye}>HOMO_{sensitizer}>HOMO_{dye}.

16. The organic electroluminescent device according to claim 4, wherein an energy level relationship between the thermally activated delayed fluorescence sensitizer and the fluorescent dye is LUMO_{dye}>LUMO_{sensitizer}>HOMO_{dye}>HOMO_{sensitizer}, or LUMO_{sensitizer}>LUMO_{dye}>HOMO_{sensitizer}>HOMO_{dye}.

17. The organic electroluminescent device according to claim 2, wherein an energy level relationship between the host material and the fluorescent dye is LUMO_{dye}>LUMOₕₒₛₜ>HOMO_{dye}>HOMOₕₒₛₜ, or LUMOₕₒₛₜ>LUMO_{dye}>HOMOₕₒₛₜ>HOMO_{dye}.

18. The organic electroluminescent device according to claim 3, wherein an energy level relationship between the host material and the fluorescent dye is LUMO_{dye}>LUMOₕₒₛₜ>HOMO_{dye}>HOMOₕₒₛₜ, or LUMOₕₒₛₜ>LUMO_{dye}>HOMOₕₒₛₜ>HOMO_{dye}.

19. The organic electroluminescent device according to claim 4, wherein an energy level relationship between the host material and the fluorescent dye is LUMO_{dye}>LUMOₕₒₛₜ>HOMO_{dye}>HOMOₕₒₛₜ, or LUMOₕₒₛₜ>LUMO_{dye}>HOMOₕₒₛₜ>HOMO_{dye}.

20. The organic electroluminescent device according to claim 5, wherein an energy level relationship between the host material and the fluorescent dye is LUMO_{dye}>LUMOₕₒₛₜ>HOMO_{dye} >HOMOₕₒₛₜ, or LUMOₕₒₛₜ>LUMO_{dye}>HOMOₕₒₛₜ>HOMO_{dye}.
